(19) United States
(12) Patent Application Publication
(10) Pub. No.: US 2023/0213628 A1
(43) Pub. Date: Jul. 6, 2023

(54) LIDAR SYSTEM WITH DETECTOR ARRAY

(71) Applicant: Luminar, LLC, Orlando, FL (US)

(72) Inventors: Joseph G. LaChapelle, Philomath, OR (US); Jason M. Eichenholz, Orlando, FL (US); Roger S. Cannon, Oviedo, FL (US); Stephen D. Gaalema, Colorado Springs, CO (US); William R. Clark, Chelmsford, MA (US); Alex Michael Sincore, Orlando, FL (US)

(21) Appl. No.: 18/093,041

(22) Filed: Jan. 4, 2023

Related U.S. Application Data
(60) Provisional application No. 63/296,560, filed on Jan. 5, 2022.

(51) Int. Cl. G01S 7/4865; G01S 7/481; G01S 17/894

(52) U.S. Cl. CPC G01S 7/4865; G01S 7/4817; G01S 7/4816; G01S 17/894; G01S 7/4814

(57) ABSTRACT

In one embodiment, a lidar system includes a light source configured to emit pulses of light and a scanner configured to scan the emitted pulses of light across a field of regard of the lidar system. The scanner includes (i) a beam deflector configured to direct each emitted pulse of light along a first scan axis and (ii) a scan mirror configured to scan the emitted pulses of light along a second scan axis different from the first scan axis. The lidar system also includes a receiver that includes a one-dimensional detector array that includes multiple detector elements arranged along a direction corresponding to the first scan axis. The receiver is configured to (i) detect a received pulse of light that includes a portion of one of the emitted pulses of light scattered by a target and (ii) determine a time of arrival of the received pulse of light.

### CROSS-REFERENCE TO RELATED APPLICATIONS

This application claims priority to U.S. Provisional Patent Application No. 63/296,560, filed 5 Jan. 2022, which is incorporated by reference herein in its entirety.

### TECHNICAL FIELD

This disclosure generally relates to lidar systems.

### BACKGROUND

Light detection and ranging (lidar) is a technology that can be used to measure distances to remote targets. Typically, a lidar system includes a light source and an optical receiver. The light source can include, for example, a laser which emits light having a particular operating wavelength. The operating wavelength of a lidar system may lie, for example, in the infrared, visible, or ultraviolet portions of the electromagnetic spectrum. The light source emits light toward a target which scatters the light, and some of the scattered light is received back at the receiver. The system determines the distance to the target based on one or more characteristics associated with the received light. For example, the lidar system may determine the distance to the target based on the time of flight for a pulse of light emitted by the light source to travel to the target and back to the lidar system.

### BRIEF DESCRIPTION OF THE DRAWINGS

FIG. 1 illustrates an example light detection and ranging (lidar) system.

FIG. 2 illustrates an example scan pattern produced by a lidar system.

FIG. 3 illustrates an example lidar system with an example rotating polygon mirror.

FIG. 4 illustrates an example light-source field of view (FOV_{L}) and receiver field of view (FOV_{R}) for a lidar system.

FIG. 5 illustrates an example unidirectioal scan pattern that includes multiple pixels and multiple scan lines.

FIG. 6 illustrates an example receiver that includes a detector, electronic amplifier, and pulse-detection circuit.

FIG. 7 illustrates an example receiver with a pulse-detection circuit that includes multiple comparators and multiple time-to-digital converters (TDCs).

FIG. 8 illustrates an example receiver with an electronic amplifier that includes three voltage amplifiers.

FIG. 9 illustrates an example lidar system with a receiver that includes a one-dimensional detector array.

FIG. 10 illustrates a top view of an example one-dimensional detector array.

FIGS. 11-12 each illustrate a side view of an example one-dimensional detector array.

FIG. 13 illustrates a side view of an example one-dimensional detector array with a variable optical filter.

FIG. 14 illustrates an example receiver that includes a one-dimensional detector array and a multiplexer.

FIG. 15 illustrates an example detector array that includes four one-dimensional detector arrays.

FIG. 16 illustrates an example lidar system with a scanner that includes a beam deflector.

FIG. 17 illustrates the example lidar system of FIG. 16 with the output beam directed by a beam deflector in three different directions.

FIG. 18 illustrates an example lidar system with the output beam directed by the beam deflector in five different directions.

FIG. 19 illustrates an example lidar system with a scanner that includes a reflective beam deflector.

FIGS. 20-27 each illustrate an example scanner that includes a beam deflector.

FIGS. 28-29 each illustrate an example MEMS beam deflector.

FIG. 30 illustrates an example lidar system with a scanner that includes a polygon mirror beam deflector.

FIG. 31 illustrates an example lidar system with a receiver that includes a two-dimensional detector array.

FIG. 32 illustrates an example lidar system that scans a field of regard that includes four regions.

FIG. 33 illustrates the four-region field of regard of FIG. 32 with an example scan pattern.

FIGS. 34-37 illustrate an example scanner that includes a polygon mirror with angled faces configured to scan the four regions of the field of regard of FIGS. 32-33.

FIG. 38 illustrates an example bidirectional scan of a region of a field of regard.

FIG. 39 illustrates an example unidirectional scan of a region of a field of regard.

FIG. 40 illustrates an example lidar system that scans a field of regard that includes three regions.

FIG. 41 illustrates the three-region field of regard of FIG. 40 with an example scan pattern.

FIGS. 42-45 illustrate an example scanner that includes a polygon mirror with angled faces configured to scan the three regions of the field of regard of FIGS. 40-41.

FIG. 46 illustrates an example light source that includes a seed laser and an optical amplifier.

FIG. 47 illustrates an example light source that includes a seed laser and a semiconductor optical amplifier (SOA).

FIG. 48 illustrates an example light source that includes a seed laser and a fiber-optic amplifier.

FIG. 49 illustrates an example light source that includes a seed laser, a semiconductor optical amplifier (SOA), and a fiber-optic amplifier.

FIG. 50 illustrates an example light source that includes a seed laser diode integrated with a semiconductor optical amplifier (SOA).

FIG. 51 illustrates an example fiber-optic amplifier.

FIG. 52 illustrates an example light source that includes a sampled-grating distributed Bragg reflector (SG-DBR) laser.

FIG. 53 illustrates an example lidar system with a tunable light source and a diffractive beam deflector.

FIG. 54 illustrates an example scan pattern produced by the lidar system of FIG. 53.

FIGS. 55-59 each illustrate an example light source and scanner that produces pulses of light with different wavelengths that are directed in different directions along the y-axis.

FIG. 60 illustrates an example scene of a road.

FIG. 61 illustrates an example lidar-system scan of the road scene of FIG. 60.

FIGS. 62-64 each illustrate an example focused lidar-system scan of the road scene of FIG. 60.

FIG. 65 illustrates an example method for manufacturing a one-dimensional detector array.

FIG. 66 illustrates an example computer system.

### DESCRIPTION OF EXAMPLE EMBODIMENTS

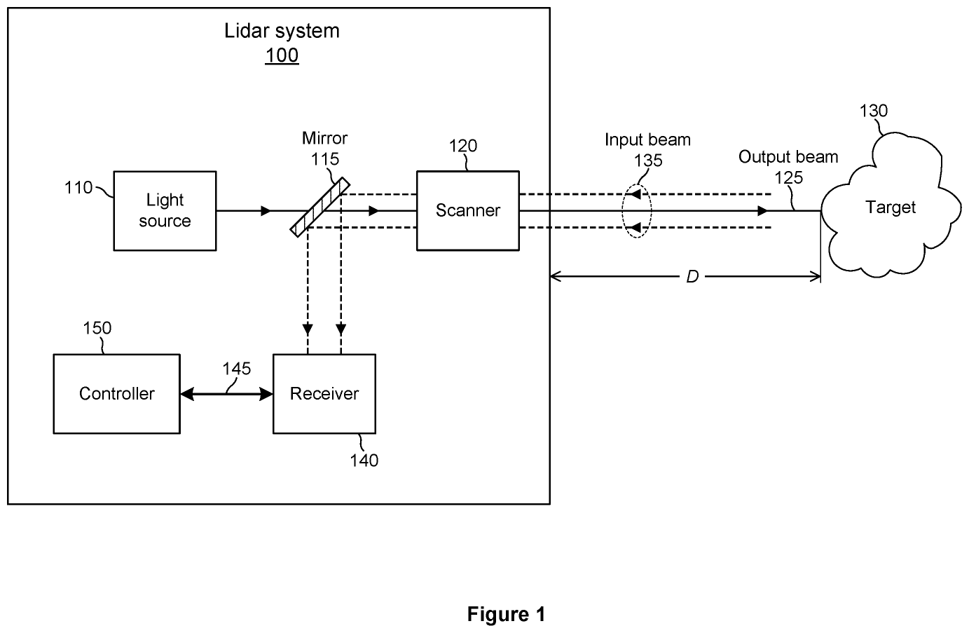

FIG. 1 illustrates an example light detection and ranging (lidar) system 100. A lidar system 100 may be referred to as a laser ranging system, a laser radar system, a LIDAR system, a lidar sensor, or a laser detection and ranging (LADAR or ladar) system. A lidar system 100 may include a light source 110, mirror 115, scanner 120, receiver 140, or controller 150 (which may be referred to as a processor). The light source 110 may include, for example, a laser which emits light having a particular operating wavelength in the infrared, visible, or ultraviolet portions of the electromagnetic spectrum. As an example, light source 110 may include a laser with one or more operating wavelengths between approximately 900 nanometers (nm) and 2000 nm. The light source 110 emits an output beam of light 125 which may be continuous wave (CW), pulsed, or modulated in any suitable manner for a given application. The output beam of light 125 is directed downrange toward a remote target 130. As an example, the remote target 130 may be located a distance D of approximately 1 m to 1 km from the lidar system 100.

Once the output beam 125 reaches the downrange target 130, the target may scatter or reflect at least a portion of light from the output beam 125, and some of the scattered or reflected light may return toward the lidar system 100. In the example of FIG. 1, the scattered or reflected light is represented by input beam 135, which passes through scanner 120 and is reflected by mirror 115 and directed to receiver 140. A relatively small fraction of the light from output beam 125 may return to the lidar system 100 as input beam 135. As an example, the ratio of input beam 135 average power, peak power, or pulse energy to output beam 125 average power, peak power, or pulse energy may be approximately 10⁻¹, 10⁻², 10⁻³, 10⁻⁴, 10⁻⁵, 10⁻⁶, 10⁻⁷, 10⁻⁸, 10⁻⁹, 10⁻¹⁰, 10⁻¹¹, or 10⁻¹². As another example, if a pulse of light of output beam 125 has a pulse energy of 1 microjoule (μJ), then the pulse energy of a corresponding pulse of input beam 135 may have a pulse energy of approximately 10 nanojoules (nJ), 1 nJ, 100 picojoules (pJ), 10 pJ, 1 pJ, 100 femtojoules (fJ), 10 fJ, 1 fJ, 100 attojoules (aJ), 10 aJ, 1 aJ, or 0.1 aJ.

The output beam 125 may include or may be referred to as an optical signal, output optical signal, emitted optical signal, output light, emitted pulse of light, laser beam, light beam, optical beam, emitted beam, transmitted beam of light, emitted light, or beam. The input beam 135 may include or may be referred to as a received optical signal, received pulse of light, input pulse of light, input optical signal, return beam, received beam, received beam of light, return light, received light, input light, scattered light, or reflected light. As used herein, scattered light may refer to light that is scattered or reflected by a target 130. As an example, an input beam 135 may include: light from the output beam 125 that is scattered by target 130; light from the output beam 125 that is reflected by target 130; or a combination of scattered and reflected light from target 130.

A receiver 140 may receive or detect photons from input beam 135 and produce one or more representative electrical signals. For example, the receiver 140 may produce an output electrical signal 145 that is representative of the input beam 135, and the electrical signal 145 may be sent to controller 150. A receiver 140 or controller 150 may include a processor, a computer system, an ASIC, an FPGA, or other suitable computing circuitry. A controller 150 may be configured to analyze one or more characteristics of the electrical signal 145 from the receiver 140 to determine one or more characteristics of the target 130, such as its distance downrange from the lidar system 100. This may be done, for example, by analyzing a time of flight or a frequency or phase of a transmitted beam of light 125 or a received beam of light 135. If lidar system 100 measures a time of flight of T (e.g., T may represent a round-trip time of flight for an emitted pulse of light to travel from the lidar system 100 to the target 130 and back to the lidar system 100), then the distance D from the target 130 to the lidar system 100 may be expressed as D=c·T/2, where c is the speed of light (approximately 3.0×10⁸ m/s). As an example, if a time of flight is measured to be T=300 ns, then the distance from the target 130 to the lidar system 100 may be determined to be approximately D=45.0 m. As another example, if a time of flight is measured to be T=1.33 μs, then the distance from the target 130 to the lidar system 100 may be determined to be approximately D=199.5 m. A distance D from lidar system 100 to a target 130 may be referred to as a distance, depth, or range of target 130. As used herein, the speed of light c refers to the speed of light in any suitable medium, such as for example in air, water, or vacuum. As an example, the speed of light in vacuum is approximately 2.9979×10⁸ m/s, and the speed of light in air (which has a refractive index of approximately 1.0003) is approximately 2.9970×10⁸ m/s.

A light source 110 may include a pulsed or CW laser. As an example, light source 110 may be a pulsed laser configured to produce or emit pulses of light with a pulse duration or pulse width of approximately 10 picoseconds (ps) to 100 nanoseconds (ns). The pulses may have a pulse duration of approximately 100 ps, 200 ps, 400 ps, 1 ns, 2 ns, 5 ns, 10 ns, 20 ns, 50 ns, 100 ns, or any other suitable pulse duration. As another example, light source 110 may be a pulsed laser that produces pulses of light with a pulse duration of approximately 1-5 ns. As another example, light source 110 may be a pulsed laser that produces pulses of light at a pulse repetition frequency of approximately 100 kHz to 10 MHz or a pulse period (e.g., a time between consecutive pulses of light) of approximately 100 ns to 10 μs. The pulse period T may be related to the pulse repetition frequency (PRF) by the expression T=1/PRF. For example, a pulse period of 1.33 μs corresponds to a PRF of approximately 752 kHz. Light source 110 may have a substantially constant pulse repetition frequency, or light source 110 may have a variable or adjustable pulse repetition frequency. As an example, light source 110 may be a pulsed laser that produces pulses at a substantially constant pulse repetition frequency of approximately 640 kHz (e.g., 640,000 pulses per second), corresponding to a pulse period of approximately 1.56 μs. As another example, light source 110 may have a pulse repetition frequency (which may be referred to as a repetition rate) that can be varied from approximately 200 kHz to 3 MHz. As used herein, a pulse of light may be referred to as an optical pulse, a light pulse, or a pulse.

A light source 110 may include a pulsed or CW laser that produces a free-space output beam 125 having any suitable average optical power. As an example, output beam 125 may have an average power of approximately 1 milliwatt (mW), 10 mW, 100 mW, 1 watt (W), 10 W, or any other suitable average power. An output beam 125 may include optical pulses with any suitable pulse energy or peak optical power. As an example, output beam 125 may include pulses with a pulse energy of approximately 0.01 μJ, 0.1 μJ, 0.5 μJ, 1 μJ, 2 μJ, 10 μJ, or 100 μJ, or any other suitable pulse energy. As another example, output beam 125 may include pulses with a peak power of approximately 10 W, 100 W, 1 kW, 5 kW, 10 kW, or any other suitable peak power. The peak power (Pₚₑₐₖ) of a pulse of light can be related to the pulse energy (E) by the expression E=Pₚₑₐₖ·Δt, where Δt is the duration of the pulse, and the duration of a pulse may be defined as the full width at half maximum duration of the pulse. For example, an optical pulse with a duration of 1 ns and a pulse energy of 1 μJ has a peak power of approximately 1 kW. The average power (Pay) of an output beam 125 can be related to the pulse repetition frequency (PRF) and pulse energy by the expression Pₐᵥ=PRF·E. For example, if the pulse repetition frequency is 500 kHz, then the average power of an output beam 125 with 1-0 pulses is approximately 0.5 W.

A light source 110 may include a laser diode, such as for example, a Fabry-Perot laser diode, a quantum well laser, a distributed Bragg reflector (DBR) laser, a distributed feedback (DFB) laser, a vertical-cavity surface-emitting laser (VCSEL), a quantum dot laser diode, a grating-coupled surface-emitting laser (GCSEL), a slab-coupled optical waveguide laser (SCOWL), a single-transverse-mode laser diode, a multi-mode broad area laser diode, a laser-diode bar, a laser-diode stack, or a tapered-stripe laser diode. As an example, light source 110 may include an aluminum-gallium-arsenide (AlGaAs) laser diode, an indium-gallium-arsenide (InGaAs) laser diode, an indium-gallium-arsenide-phosphide (InGaAsP) laser diode, or a laser diode that includes any suitable combination of aluminum (Al), indium (In), gallium (Ga), arsenic (As), phosphorous (P), or any other suitable material. A light source 110 may include a pulsed or CW laser diode with a peak emission wavelength between 1200 nm and 1600 nm. As an example, light source 110 may include a current-modulated InGaAsP DFB laser diode that produces optical pulses at a wavelength of approximately 1550 nm. As another example, light source 110 may include a laser diode that emits light at a wavelength between 1500 nm and 1510 nm.

A light source 110 may include a pulsed or CW laser diode followed by one or more optical-amplification stages. For example, a seed laser diode may produce a seed optical signal, and an optical amplifier may amplify the seed optical signal to produce an amplified optical signal that is emitted by the light source 110. An optical amplifier may include a fiber-optic amplifier or a semiconductor optical amplifier (SOA). For example, a pulsed laser diode may produce relatively low-power optical seed pulses which are amplified by a fiber-optic amplifier. As another example, a light source 110 may include a fiber-laser module that includes a current-modulated laser diode with an operating wavelength of approximately 1550 nm followed by a single-stage or a multi-stage erbium-doped fiber amplifier (EDFA) or erbium-ytterbium-doped fiber amplifier (EYDFA) that amplifies the seed pulses from the laser diode. As another example, light source 110 may include a continuous-wave (CW) or quasi-CW laser diode followed by an external optical modulator (e.g., an electro-optic amplitude modulator). The optical modulator may modulate the CW light from the laser diode to produce optical pulses which are sent to a fiber-optic amplifier or SOA. As another example, light source 110 may include a pulsed or CW seed laser diode followed by a semiconductor optical amplifier (SOA). The SOA may include an active optical waveguide configured to receive light from the seed laser diode and amplify the light as it propagates through the waveguide. The optical gain of the SOA may be provided by pulsed or direct-current (DC) electrical current supplied to the SOA. The SOA may be integrated on the same chip as the seed laser diode, or the SOA may be a separate device with an anti-reflection coating on its input facet or output facet. As another example, light source 110 may include a seed laser diode followed by a SOA, which in turn is followed by a fiber-optic amplifier. For example, the seed laser diode may produce relatively low-power seed pulses which are amplified by the SOA, and the fiber-optic amplifier may further amplify the optical pulses.

A light source 110 may include a direct-emitter laser diode. A direct-emitter laser diode (which may be referred to as a direct emitter) may include a laser diode which produces light that is not subsequently amplified by an optical amplifier. A light source 110 that includes a direct-emitter laser diode may not include an optical amplifier, and the output light produced by a direct emitter may not be amplified after it is emitted by the laser diode. The light produced by a direct-emitter laser diode (e.g., optical pulses, CW light, or frequency-modulated light) may be emitted directly as a free-space output beam 125 without being amplified. A direct-emitter laser diode may be driven by an electrical power source that supplies current pulses to the laser diode, and each current pulse may result in the emission of an output optical pulse.

A light source 110 may include a diode-pumped solid-state (DPSS) laser. A DPSS laser (which may be referred to as a solid-state laser) may refer to a laser that includes a solid-state, glass, ceramic, or crystal-based gain medium that is pumped by one or more pump laser diodes. The gain medium may include a host material that is doped with rare-earth ions (e.g., neodymium, erbium, ytterbium, or praseodymium). For example, a gain medium may include a yttrium aluminum garnet (YAG) crystal that is doped with neodymium (Nd) ions, and the gain medium may be referred to as a Nd:YAG crystal. A DPSS laser with a Nd:YAG gain medium may produce light at a wavelength between approximately 1300 nm and approximately 1400 nm, and the Nd:YAG gain medium may be pumped by one or more pump laser diodes with an operating wavelength between approximately 730 nm and approximately 900 nm. A DPSS laser may be a passively Q-switched laser that includes a saturable absorber (e.g., a vanadium-doped crystal that acts as a saturable absorber). Alternatively, a DPSS laser may be an actively Q-switched laser that includes an active Q-switch (e.g., an acousto-optic modulator or an electro-optic modulator). A passively or actively Q-switched DPSS laser may produce output optical pulses that form an output beam 125 of a lidar system 100.

An output beam of light 125 emitted by light source 110 may be unpolarized or randomly polarized, may have no specific or fixed polarization (e.g., the polarization may vary with time), or may have a particular polarization (e.g., output beam 125 may be linearly polarized, elliptically polarized, or circularly polarized). As an example, light source 110 may produce light with no specific polarization or may produce light that is linearly polarized.

A lidar system 100 may include one or more optical components configured to reflect, focus, filter, shape, modify, steer, or direct light within the lidar system 100 or light produced or received by the lidar system 100 (e.g., output beam 125 or input beam 135). As an example, lidar system 100 may include one or more lenses, mirrors, filters (e.g., band-pass or interference filters), beam splitters, optical splitters, polarizers, polarizing beam splitters, wave plates (e.g., half-wave or quarter-wave plates), diffractive elements, holographic elements, isolators, couplers, detectors, beam combiners, or collimators. The optical components in a lidar system 100 may be free-space optical components, fiber-coupled optical components, or a combination of free-space and fiber-coupled optical components.

A lidar system 100 may include a telescope, one or more lenses, or one or more mirrors configured to expand, focus, collimate, or steer the output beam 125 or the input beam 135 to a desired beam diameter or divergence. As an example, the lidar system 100 may include one or more lenses to focus the input beam 135 onto a photodetector of receiver 140. As another example, the lidar system 100 may include one or more flat mirrors or curved mirrors (e.g., concave, convex, or parabolic mirrors) to steer or focus the output beam 125 or the input beam 135. For example, the lidar system 100 may include an off-axis parabolic mirror to focus the input beam 135 onto a photodetector of receiver 140. As illustrated in FIG. 1, the lidar system 100 may include mirror 115 (which may be a metallic or dielectric mirror), and mirror 115 may be configured so that light beam 125 passes through the mirror 115 or passes along an edge or side of the mirror 115 and input beam 135 is reflected toward the receiver 140. As an example, mirror 115 (which may be referred to as an overlap mirror, superposition mirror, beam-combiner mirror, steering mirror, turning mirror, or pickoff mirror) may include a hole, slot, or aperture which output light beam 125 passes through. As another example, rather than passing through the mirror 115, the output beam 125 may be directed to pass alongside the mirror 115 with a gap (e.g., a gap of width approximately 0.1 mm, 0.5 mm, 1 mm, 2 mm, 5 mm, or 10 mm) between the output beam 125 and an edge of the mirror 115.

The mirror 115 may provide for output beam 125 and input beam 135 to be substantially coaxial so that the two beams travel along approximately the same optical path (albeit in opposite directions). The input and output beams being substantially coaxial may refer to the beams being at least partially overlapped or sharing a common propagation axis so that input beam 135 and output beam 125 travel along substantially the same optical path (albeit in opposite directions). As an example, output beam 125 and input beam 135 may be parallel to each other to within less than 10 mrad, 5 mrad, 2 mrad, 1 mrad, 0.5 mrad, or 0.1 mrad. As output beam 125 is scanned across a field of regard, the input beam 135 may follow along with the output beam 125 so that the coaxial relationship between the two beams is maintained.

A lidar system 100 may include a scanner 120 configured to scan an output beam 125 across a field of regard of the lidar system 100. As an example, scanner 120 may include one or more scan mirrors configured to pivot, rotate, oscillate, or move in an angular manner about one or more rotation axes. The output beam 125 may be reflected by a scan mirror, and as the scan mirror pivots or rotates, the reflected output beam 125 may be scanned in a corresponding angular manner. As an example, a scan mirror may be configured to periodically pivot back and forth over a 30-degree range, which results in the output beam 125 scanning back and forth across a 60-degree range (e.g., a 0-degree rotation by a scan mirror results in a 20-degree angular scan of output beam 125).

A scan mirror (which may be referred to as a scanning mirror) may be attached to or mechanically driven by a scanner actuator or mechanism which pivots or rotates the mirror over a particular angular range (e.g., over a 5° angular range, 30° angular range, 60° angular range, 120° angular range, 360° angular range, or any other suitable angular range). A scanner actuator or mechanism configured to pivot or rotate a mirror may include a galvanometer scanner, a resonant scanner, a piezoelectric actuator, a voice coil motor, an electric motor (e.g., a DC motor, a brushless DC motor, a synchronous electric motor, or a stepper motor), a microelectromechanical systems (MEMS) device, or any other suitable actuator or mechanism. As an example, a scanner 120 may include a scan mirror attached to a galvanometer scanner configured to pivot back and forth over a 1° to 30° angular range. As another example, a scanner 120 may include a scan mirror that is attached to or is part of a MEMS device configured to scan over a 1° to 30° angular range. As another example, a scanner 120 may include a polygon mirror configured to rotate continuously in the same direction (e.g., rather than pivoting back and forth, the polygon mirror continuously rotates 360 degrees in a clockwise or counter-clockwise direction). The polygon mirror may be coupled or attached to a synchronous motor configured to rotate the polygon mirror at a substantially fixed rotational frequency (e.g., a rotational frequency of approximately 1 Hz, 10 Hz, 50 Hz, 100 Hz, 500 Hz, or 1,000 Hz).

A scanner 120 may be configured to scan an output beam 125 (which may include at least a portion of the light emitted by light source 110) across a field of regard of a lidar system 100. A field of regard (FOR) of a lidar system 100 may refer to an area, region, or angular range over which the lidar system 100 may be configured to scan or capture distance information. As an example, a lidar system 100 with an output beam 125 with a 30-degree scanning range may be referred to as having a 30-degree angular field of regard. As another example, a lidar system 100 with a scan mirror that rotates over a 30-degree range may produce an output beam 125 that scans across a 60-degree range (e.g., a 60-degree FOR). A lidar system 100 may have a FOR of approximately 10°, 20°, 40°, 60°, 120°, 360°, or any other suitable FOR.

A scanner 120 may be configured to scan an output beam 125 horizontally and vertically, and lidar system 100 may have a particular FOR along the horizontal direction and another particular FOR along the vertical direction. As an example, lidar system 100 may have a horizontal FOR of 10° to 120° and a vertical FOR of 2° to 45°. A scanner 120 may include a first scan mirror and a second scan mirror, where the first scan mirror directs the output beam 125 toward the second scan mirror, and the second scan mirror directs the output beam 125 downrange from the lidar system 100. As an example, the first scan mirror may scan the output beam 125 along a first direction, and the second scan mirror may scan the output beam 125 along a second direction that is different from the first direction (e.g., the first and second scan directions may be approximately orthogonal to one another, or the second scan direction may be oriented at any suitable non-zero angle with respect to the first scan direction). As another example, the first scan mirror may scan the output beam 125 along a substantially horizontal direction, and the second scan mirror may scan the output beam 125 along a substantially vertical direction (or vice versa). As another example, the first and second scan mirrors may each be driven by galvanometer scanners. As another example, the first or second scan mirror may include a polygon mirror driven by an electric motor. A scanner 120 may be referred to as a beam scanner, optical scanner, or laser scanner. A scan direction may be referred to as a scan axis.

One or more scan mirrors may be communicatively coupled to a controller 150 which may control the scan mirror(s) so as to guide the output beam 125 in a desired direction downrange or along a desired scan pattern. A scan pattern may refer to a pattern or path along which the output beam 125 is directed. As an example, scanner 120 may include two scan mirrors configured to scan the output beam 125 across a 60° horizontal FOR and a 20° vertical FOR. The two scan mirrors may be controlled to follow a scan path that substantially covers the 60°×20° FOR. As an example, the scan path may result in a point cloud with pixels that substantially cover the 60°×20° FOR. The pixels may be approximately evenly distributed across the 60°×20° FOR. Alternatively, the pixels may have a particular nonuniform distribution (e.g., the pixels may be distributed across all or a portion of the 60°×20° FOR, and the pixels may have a higher density in one or more particular regions of the 60°×20° FOR).

A lidar system 100 may include a scanner 120 with a solid-state scanning device. A solid-state scanning device may refer to a scanner 120 that scans an output beam 125 without the use of moving parts (e.g., without the use of a mechanical scanner, such as a mirror that rotates or pivots). For example, a solid-state scanner 120 may include one or more of the following: an optical phased array scanning device; a liquid-crystal scanning device; or a liquid lens scanning device. A solid-state scanner 120 may be an electrically addressable device that scans an output beam 125 along one axis (e.g., horizontally) or along two axes (e.g., horizontally and vertically). A scanner 120 may include a solid-state scanner and a mechanical scanner. For example, a scanner 120 may include an optical phased array scanner configured to scan an output beam 125 in one direction and a galvanometer scanner that scans the output beam 125 in an approximately orthogonal direction. The optical phased array scanner may scan the output beam relatively rapidly in a horizontal direction across the field of regard (e.g., at a scan rate of 50 to 1,000 scan lines per second), and the galvanometer may pivot a mirror at a rate of 1-30 Hz to scan the output beam 125 vertically.

A lidar system 100 may include a light source 110 configured to emit pulses of light and a scanner 120 configured to scan at least a portion of the emitted pulses of light across a field of regard of the lidar system 100. One or more of the emitted pulses of light may be scattered by a target 130 located downrange from the lidar system 100, and a receiver 140 may detect at least a portion of the pulses of light scattered by the target 130. A receiver 140 may include or may be referred to as a photoreceiver, optical receiver, optical sensor, detector, photodetector, or optical detector. A lidar system 100 may include a receiver 140 that receives or detects at least a portion of input beam 135 and produces an electrical signal that corresponds to input beam 135. As an example, if input beam 135 includes an optical pulse, then receiver 140 may produce an electrical current or voltage pulse that corresponds to the optical pulse detected by receiver 140. As another example, receiver 140 may include one or more avalanche photodiodes (APDs) or one or more single-photon avalanche diodes (SPADs). As another example, receiver 140 may include one or more PN photodiodes (e.g., a photodiode structure formed by a p-type semiconductor and a n-type semiconductor, where the PN acronym refers to the structure having p-doped and n-doped regions) or one or more PIN photodiodes (e.g., a photodiode structure formed by an undoped intrinsic semiconductor region located between p-type and n-type regions, where the PIN acronym refers to the structure having p-doped, intrinsic, and n-doped regions). As another example, receiver 140 may include one or more quantum dot (QD) photodetectors (e.g., a QD photodetector may include lead sulfide (PbS) quantum dots having a diameter of approximately 2-20 nm and configured to detect light in the 1400-1600-nm wavelength range). An APD, SPAD, PN photodiode, PIN photodiode, or QD photodetector may each be referred to as a detector, photodetector, or photodiode. A detector may receive an input beam 135 that includes an optical pulse, and the detector may produce a pulse of electrical current that corresponds to the received optical pulse. A detector may have an active region or an avalanche-multiplication region that includes silicon (Si), germanium (Ge), silicon germanium (SiGe), silicon germanium tin (SiGeSn), indium gallium arsenide (InGaAs), indium aluminum arsenide (InAlAs), lead sulfide (PbS), indium arsenide antimonide (InAsSb), aluminum arsenide antimonide (AlAsSb), aluminum indium arsenide antimonide (AlInAsSb), or any other suitable detector material. The active region may refer to an area over which a detector may receive or detect input light. An active region may have any suitable size or diameter, such as for example, a diameter of approximately 10 μm, 25 μm, 50 μm, 80 μm, 100 μm, 200 μm, 500 μm, 1 mm, 2 mm, or 5 mm.

A receiver 140 may include electronic circuitry that performs signal amplification, sampling, filtering, signal conditioning, analog-to-digital conversion, time-to-digital conversion, pulse detection, threshold detection, rising-edge detection, or falling-edge detection. As an example, receiver 140 may include a transimpedance amplifier that converts a photocurrent (e.g., a pulse of current produced by an APD in response to a received optical pulse) into a voltage signal. The voltage signal may be sent to pulse-detection circuitry that produces an analog or digital output signal 145 that corresponds to one or more optical characteristics (e.g., time of arrival, rising edge, falling edge, amplitude, duration, or energy) of a received optical pulse. As an example, the pulse-detection circuitry may perform a time-to-digital conversion to produce a digital output signal 145. The electrical output signal 145 may be sent to controller 150 for processing or analysis (e.g., to determine a time-of-flight value corresponding to a received optical pulse).

A controller 150 (which may include or may be referred to as a processor, an FPGA, an ASIC, a computer, or a computing system) may be located within a lidar system 100 or outside of a lidar system 100. Alternatively, one or more parts of a controller 150 may be located within a lidar system 100, and one or more other parts of a controller 150 may be located outside a lidar system 100. One or more parts of a controller 150 may be located within a receiver 140 of a lidar system 100, and one or more other parts of a controller 150 may be located in other parts of the lidar system 100. For example, a receiver 140 may include an FPGA or ASIC configured to process an output electrical signal from the receiver 140, and the processed signal may be sent to another computing system located elsewhere within the lidar system 100 or outside the lidar system 100. A controller 150 may include any suitable arrangement or combination of logic circuitry, analog circuitry, or digital circuitry.

A controller 150 may be electrically coupled or communicatively coupled to light source 110, scanner 120, or receiver 140. As an example, controller 150 may receive electrical trigger pulses or edges from light source 110, where each pulse or edge corresponds to the emission of an optical pulse by light source 110. As another example, controller 150 may provide instructions, a control signal, or a trigger signal to light source 110 indicating when light source 110 should produce optical pulses. Controller 150 may send an electrical trigger signal that includes electrical pulses, where each electrical pulse results in the emission of an optical pulse by light source 110. The frequency, period, duration, pulse energy, peak power, average power, or wavelength of the optical pulses produced by light source 110 may be adjusted based on instructions, a control signal, or trigger pulses provided by controller 150. A controller 150 may be coupled to light source 110 and receiver 140, and the controller 150 may determine a time-of-flight value for an optical pulse based on timing information associated with a time when the pulse was emitted by light source 110 and a time when a portion of the pulse (e.g., input beam 135) was detected or received by receiver 140. A controller 150 may include circuitry that performs signal amplification, sampling, filtering, signal conditioning, analog-to-digital conversion, time-to-digital conversion, pulse detection, threshold detection, rising-edge detection, or falling-edge detection.

A lidar system 100 may include one or more processors (e.g., a controller 150) configured to determine a distance D from the lidar system 100 to a target 130 based at least in part on a round-trip time of flight for an emitted pulse of light to travel from the lidar system 100 to the target 130 and back to the lidar system 100. The target 130 may be at least partially contained within a field of regard of the lidar system 100 and located a distance D from the lidar system 100 that is less than or equal to an operating range (R_{OP}) of the lidar system 100. An operating range (which may be referred to as an operating distance) of a lidar system 100 may refer to a distance over which the lidar system 100 is configured to sense or identify targets 130 located within a field of regard of the lidar system 100. The operating range of lidar system 100 may be any suitable distance, such as for example, 25 m, 50 m, 100 m, 200 m, 250 m, 500 m, or 1 km. As an example, a lidar system 100 with a 200-m operating range may be configured to sense or identify various targets 130 located up to 200 m away from the lidar system 100.

A lidar system 100 may be used to determine the distance to one or more downrange targets 130. By scanning the lidar system 100 across a field of regard, the system may be used to map the distance to a number of points within the field of regard. Each of these depth-mapped points may be referred to as a pixel or a voxel. A collection of pixels captured in succession (which may be referred to as a depth map, a point cloud, or a frame) may be rendered as an image or may be analyzed to identify or detect objects or to determine a shape or distance of objects within the FOR. As an example, a point cloud may cover a field of regard that extends 60° horizontally and 15° vertically, and the point cloud may include a frame of 100-2000 pixels in the horizontal direction by 4-400 pixels in the vertical direction.

A lidar system 100 may be configured to repeatedly capture or generate point clouds of a field of regard at any suitable frame rate between approximately 0.1 frames per second (FPS) and approximately 1,000 FPS. As an example, lidar system 100 may generate point clouds at a frame rate of approximately 0.1 FPS, 0.5 FPS, 1 FPS, 2 FPS, 5 FPS, 10 FPS, 20 FPS, 100 FPS, 500 FPS, or 1,000 FPS. As another example, lidar system 100 may be configured to produce optical pulses at a rate of 5×10⁵ pulses/second (e.g., the system may determine 500,000 pixel distances per second) and scan a frame of 1000×50 pixels (e.g., 50,000 pixels/frame), which corresponds to a point-cloud frame rate of 10 frames per second (e.g., 10 point clouds per second). A point-cloud frame rate may be substantially fixed, or a point-cloud frame rate may be dynamically adjustable. As an example, a lidar system 100 may capture one or more point clouds at a particular frame rate (e.g., 1 Hz) and then switch to capture one or more point clouds at a different frame rate (e.g., 10 Hz). A slower frame rate (e.g., 1 Hz) may be used to capture one or more high-resolution point clouds, and a faster frame rate (e.g., 10 Hz) may be used to rapidly capture multiple lower-resolution point clouds.

A lidar system 100 may be configured to sense, identify, or determine distances to one or more targets 130 within a field of regard. As an example, a lidar system 100 may determine a distance to a target 130, where all or part of the target 130 is contained within a field of regard of the lidar system 100. All or part of a target 130 being contained within a FOR of the lidar system 100 may refer to the FOR overlapping, encompassing, or enclosing at least a portion of the target 130. A target 130 may include all or part of an object that is moving or stationary relative to lidar system 100. As an example, target 130 may include all or a portion of a person, vehicle, motorcycle, truck, train, bicycle, wheelchair, pedestrian, animal, road sign, traffic light, lane marking, road-surface marking, parking space, pylon, guard rail, traffic barrier, pothole, railroad crossing, obstacle in or near a road, curb, stopped vehicle on or beside a road, utility pole, house, building, trash can, mailbox, tree, any other suitable object, or any suitable combination of all or part of two or more objects. A target may be referred to as an object.

A lidar system 100 may include a light source 110, scanner 120, and receiver 140 that are packaged together within a single housing, where a housing may refer to a box, case, or enclosure that holds or contains all or part of a lidar system 100. As an example, a lidar-system enclosure may contain a light source 110, mirror 115, scanner 120, and receiver 140 of a lidar system 100. Additionally, the lidar-system enclosure may include a controller 150. The lidar-system enclosure may also include one or more electrical connections for conveying electrical power or electrical signals to or from the enclosure. One or more components of a lidar system 100 may be located remotely from a lidar-system enclosure. As an example, all or part of light source 110 may be located remotely from a lidar-system enclosure, and pulses of light produced by the light source 110 may be conveyed to the enclosure via optical fiber. As another example, all or part of a controller 150 may be located remotely from a lidar-system enclosure.

A light source 110 may include an eye-safe laser, or lidar system 100 may be classified as an eye-safe laser system or laser product. An eye-safe laser, laser system, or laser product may refer to a system that includes a laser with an emission wavelength, average power, peak power, peak intensity, pulse energy, beam size, beam divergence, exposure time, or scanned output beam such that emitted light from the system presents little or no possibility of causing damage to a person's eyes. As an example, light source 110 or lidar system 100 may be classified as a Class 1 laser product (as specified by the 60825-1:2014 standard of the International Electrotechnical Commission (IEC)) or a Class I laser product (as specified by Title 21, Section 1040.10 of the United States Code of Federal Regulations (CFR)) that is safe under all conditions of normal use. A lidar system 100 may be an eye-safe laser product (e.g., with a Class 1 or Class I classification) configured to operate at any suitable wavelength between approximately 900 nm and approximately 2100 nm. As an example, lidar system 100 may include a laser with an operating wavelength between approximately 1200 nm and approximately 1400 nm or between approximately 1400 nm and approximately 1600 nm, and the laser or the lidar system 100 may be operated in an eye-safe manner. As another example, lidar system 100 may be an eye-safe laser product that includes a scanned laser with an operating wavelength between approximately 900 nm and approximately 1700 nm. As another example, lidar system 100 may be a Class 1 or Class I laser product that includes a laser diode, fiber laser, or solid-state laser with an operating wavelength between approximately 1200 nm and approximately 1600 nm. As another example, lidar system 100 may have an operating wavelength between approximately 1500 nm and approximately 1510 nm.

One or more lidar systems 100 may be integrated into a vehicle. As an example, a truck may include a single lidar system 100 with a 60-degree to 180-degree horizontal FOR directed towards the front of the truck. As another example, multiple lidar systems 100 may be integrated into a car to provide a complete 360-degree horizontal FOR around the car. As another example, 2-10 lidar systems 100, each system having a 45-degree to 180-degree horizontal FOR, may be combined together to form a sensing system that provides a point cloud covering a 360-degree horizontal FOR. The lidar systems 100 may be oriented so that adjacent FORs have an amount of spatial or angular overlap to allow data from the multiple lidar systems 100 to be combined or stitched together to form a single or continuous 360-degree point cloud. As an example, the FOR of each lidar system 100 may have approximately 1-30 degrees of overlap with an adjacent FOR. A vehicle may refer to a mobile machine configured to transport people or cargo. For example, a vehicle may include a car used for work, commuting, running errands, or transporting people. As another example, a vehicle may include a truck used to transport commercial goods to a store, warehouse, or residence. A vehicle may include, may take the form of, or may be referred to as a car, automobile, motor vehicle, truck, bus, van, trailer, off-road vehicle, farm vehicle, lawn mower, construction equipment, forklift, robot, golf cart, motorhome, taxi, motorcycle, scooter, bicycle, skateboard, train, snowmobile, watercraft (e.g., a ship or boat), aircraft (e.g., a fixed-wing aircraft, helicopter, or dirigible), unmanned aerial vehicle (e.g., a drone), or spacecraft. A vehicle may include an internal combustion engine or an electric motor that provides propulsion for the vehicle.

One or more lidar systems 100 may be included in a vehicle as part of an advanced driver assistance system (ADAS) to assist a driver of the vehicle in operating the vehicle. For example, a lidar system 100 may be part of an ADAS that provides information (e.g., about the surrounding environment) or feedback to a driver (e.g., to alert the driver to potential problems or hazards) or that automatically takes control of part of a vehicle (e.g., a braking system or a steering system) to avoid collisions or accidents. A lidar system 100 may be part of a vehicle ADAS that provides adaptive cruise control, automated braking, automated parking, collision avoidance, alerts the driver to hazards or other vehicles, maintains the vehicle in the correct lane, or provides a warning if an object or another vehicle is located in a blind spot.

One or more lidar systems 100 may be integrated into a vehicle as part of an autonomous-vehicle driving system. As an example, a lidar system 100 may provide information about the surrounding environment to a driving system of an autonomous vehicle. An autonomous-vehicle driving system may be configured to guide the autonomous vehicle through an environment surrounding the vehicle and toward a destination. An autonomous-vehicle driving system may include one or more computing systems that receive information from a lidar system 100 about the surrounding environment, analyze the received information, and provide control signals to the vehicle's driving systems (e.g., steering mechanism, accelerator, brakes, lights, or turn signals). As an example, a lidar system 100 integrated into an autonomous vehicle may provide an autonomous-vehicle driving system with a point cloud every 0.1 seconds (e.g., the point cloud has a 10 Hz update rate, representing 10 frames per second). The autonomous-vehicle driving system may analyze the received point clouds to sense or identify targets 130 and their respective locations, distances, or speeds, and the autonomous-vehicle driving system may update control signals based on this information. As an example, if lidar system 100 detects a vehicle ahead that is slowing down or stopping, the autonomous-vehicle driving system may send instructions to release the accelerator and apply the brakes.

An autonomous vehicle may be referred to as an autonomous car, driverless car, self-driving car, robotic car, or unmanned vehicle. An autonomous vehicle may refer to a vehicle configured to sense its environment and navigate or drive with little or no human input. As an example, an autonomous vehicle may be configured to drive to any suitable location and control or perform all safety-critical functions (e.g., driving, steering, braking, parking) for the entire trip, with the driver not expected to control the vehicle at any time. As another example, an autonomous vehicle may allow a driver to safely turn their attention away from driving tasks in particular environments (e.g., on freeways), or an autonomous vehicle may provide control of a vehicle in all but a few environments, requiring little or no input or attention from the driver.

An autonomous vehicle may be configured to drive with a driver present in the vehicle, or an autonomous vehicle may be configured to operate the vehicle with no driver present. As an example, an autonomous vehicle may include a driver's seat with associated controls (e.g., steering wheel, accelerator pedal, and brake pedal), and the vehicle may be configured to drive with no one seated in the driver's seat or with little or no input from a person seated in the driver's seat. As another example, an autonomous vehicle may not include any driver's seat or associated driver's controls, and the vehicle may perform substantially all driving functions (e.g., driving, steering, braking, parking, and navigating) without human input. As another example, an autonomous vehicle may be configured to operate without a driver (e.g., the vehicle may be configured to transport human passengers or cargo without a driver present in the vehicle). As another example, an autonomous vehicle may be configured to operate without any human passengers (e.g., the vehicle may be configured for transportation of cargo without having any human passengers onboard the vehicle).

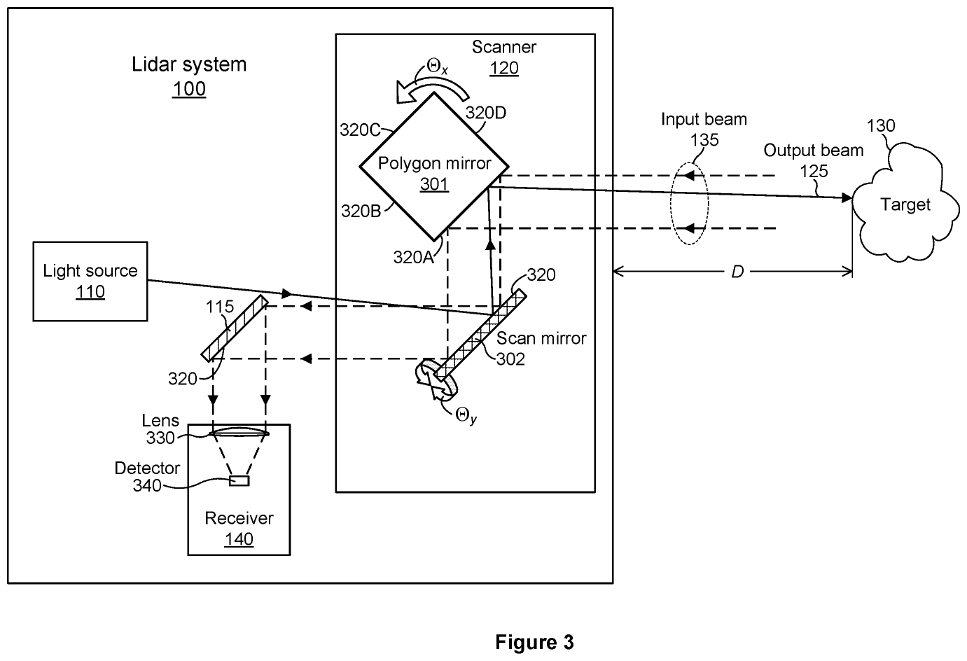

An optical signal (which may be referred to as a light signal, a light waveform, an optical waveform, an output beam, an emitted optical signal, or emitted light) may include pulses of light, CW light, amplitude-modulated light, frequency-modulated (FM) light, or any suitable combination thereof. Although this disclosure describes or illustrates example embodiments of lidar systems 100 or light sources 110 that produce optical signals that include pulses of light, the embodiments described or illustrated herein may also be applied, where appropriate, to other types of optical signals, including continuous-wave (CW) light, amplitude-modulated optical signals, or frequency-modulated optical signals. For example, a lidar system 100 as described or illustrated herein may be a pulsed lidar system and may include a light source 110 that produces pulses of light. The distance to a remote target 130 may be determined based on the round-trip time of flight for a pulse of light to travel to the target 130 and back. Alternatively, a lidar system 100 may be configured to operate as a frequency-modulated continuous-wave (FMCW) lidar system and may include a light source 110 that produces a frequency-modulated optical signal. For example, output beam 125 in FIG. 1 or FIG. 3 may include FM light. Additionally, the light source may also produce local-oscillator (LO) light that is frequency modulated. A FMCW lidar system may use frequency-modulated light to determine the distance to a remote target 130 based on a frequency of received light (which includes emitted light scattered by the remote target) relative to a frequency of the LO light. A round-trip time for the emitted light to travel to a target 130 and back to the lidar system may correspond to a frequency difference between the received scattered light and the LO light. A larger frequency difference may correspond to a longer round-trip time and a greater distance to the target 130. The frequency difference between the received scattered light and the LO light may be referred to as a beat frequency.

A light source 110 for a FMCW lidar system may include (i) a direct-emitter laser diode, (ii) a seed laser diode followed by a SOA, (iii) a seed laser diode followed by a fiber-optic amplifier, or (iv) a seed laser diode followed by a SOA and then a fiber-optic amplifier. A seed laser diode or a direct-emitter laser diode may be operated in a CW manner (e.g., by driving the laser diode with a substantially constant DC current), and a frequency modulation may be provided by an external modulator (e.g., an electro-optic phase modulator may apply a frequency modulation to seed-laser light). Alternatively, a frequency modulation may be produced by applying a current modulation to a seed laser diode or a direct-emitter laser diode. The current modulation (which may be provided along with a DC bias current) may produce a corresponding refractive-index modulation in the laser diode, which results in a frequency modulation of the light emitted by the laser diode. The current-modulation component (and the corresponding frequency modulation) may have any suitable frequency or shape (e.g., piecewise linear, sinusoidal, triangle-wave, or sawtooth). For example, the current-modulation component (and the resulting frequency modulation of the emitted light) may increase or decrease monotonically over a particular time interval. As another example, the current-modulation component may include a triangle or sawtooth wave with an electrical current that increases or decreases linearly over a particular time interval, and the light emitted by the laser diode may include a corresponding frequency modulation in which the optical frequency increases or decreases approximately linearly over the particular time interval. For example, a light source 110 that emits light with a linear frequency change of 200 MHz over a 2-μs time interval may be referred to as having a frequency modulation m of 10¹⁴ Hz/s (or, 100 MHz/μs).

In addition to producing frequency-modulated emitted light, a light source 110 may also produce frequency-modulated local-oscillator (LO) light. The LO light may be coherent with the emitted light, and the frequency modulation of the LO light may match that of the emitted light. The LO light may be produced by splitting off a portion of the emitted light prior to the emitted light exiting the lidar system. Alternatively, the LO light may be produced by a seed laser diode or a direct-emitter laser diode that is part of the light source 110. For example, the LO light may be emitted from the back facet of a seed laser diode or a direct-emitter laser diode, or the LO light may be split off from the seed light emitted from the front facet of a seed laser diode. The received light (e.g., emitted light that is scattered by a target 130) and the LO light may each be frequency modulated, with a frequency difference or offset that corresponds to the distance to the target 130. For a linearly chirped light source (e.g., a frequency modulation that produces a linear change in frequency with time), the larger the frequency difference is between the received light and the LO light, the farther away the target 130 is located.

A frequency difference between received light and LO light may be determined by mixing the received light with the LO light (e.g., by coupling the two beams onto a detector so they are coherently mixed together at the detector) and determining the resulting beat frequency. For example, a photocurrent signal produced by an APD may include a beat signal resulting from the coherent mixing of the received light and the LO light, and a frequency of the beat signal may correspond to the frequency difference between the received light and the LO light. The photocurrent signal from an APD (or a voltage signal that corresponds to the photocurrent signal) may be analyzed to determine the frequency of the beat signal. If a linear frequency modulation m (e.g., in units of Hz/s) is applied to a CW laser, then the round-trip time T may be related to the frequency difference Δf between the received scattered light and the LO light by the expression T=Δf/m. Additionally, the distance D from the target 130 to the lidar system 100 may be expressed as D=(Δf/m)·c/2, where cis the speed of light. For example, for a light source 110 with a linear frequency modulation of 10¹⁴ Hz/s, if a frequency difference (between the received scattered light and the LO light) of 33 MHz is measured, then this corresponds to a round-trip time of approximately 330 ns and a distance to the target of approximately 50 meters. As another example, a frequency difference of 133 MHz corresponds to a round-trip time of approximately 1.33 μs and a distance to the target of approximately 200 meters. A receiver or processor of a FMCW lidar system may determine a frequency difference between received scattered light and LO light, and the distance to a target may be determined based on the frequency difference. The frequency difference Δf between received scattered light and LO light corresponds to the round-trip time T (e.g., through the relationship T=Δf/m), and determining the frequency difference may correspond to or may be referred to as determining the round-trip time.

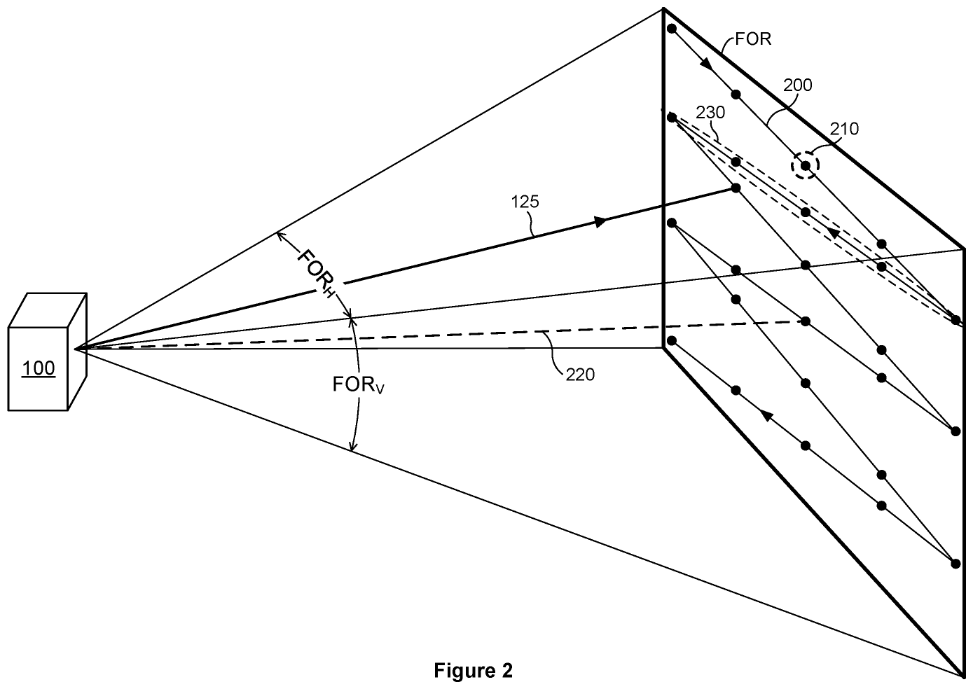

FIG. 2 illustrates an example scan pattern 200 produced by a lidar system 100. A scanner 120 of the lidar system 100 may scan the output beam 125 (which may include multiple emitted optical signals) along a scan pattern 200 that is contained within a field of regard (FOR) of the lidar system 100. A scan pattern 200 (which may be referred to as an optical scan pattern, optical scan path, scan path, or scan) may represent a path or course followed by output beam 125 as it is scanned across all or part of a FOR. Each traversal of a scan pattern 200 by the output beam 125 may correspond to the capture of a single frame or a single point cloud. A scan pattern 200 may scan across any suitable field of regard (FOR) having any suitable horizontal FOR (FOR_{H}) and any suitable vertical FOR (FOR_{V}). For example, a scan pattern 200 may have a field of regard represented by angular dimensions (e.g., FOR_{H}×FOR_{V}) 40°×30°, 90°×40°, or 120°×20°. As another example, a scan pattern 200 may have a FOR_{H} greater than or equal to 10°, 25°, 30°, 40°, 60°, 90°, or 120°. As another example, a scan pattern 200 may have a FOR_{V} greater than or equal to 2°, 5°, 10°, 15°, 20°, 30°, or 45°.

In the example of FIG. 2, reference line 220 represents a center of the field of regard of scan pattern 200. A reference line 220 may have any suitable orientation, such as for example, a horizontal angle of 0° (e.g., reference line 220 may be oriented straight ahead) and a vertical angle of 0° (e.g., reference line 220 may have an inclination of 0°), or reference line 220 may have a non-zero horizontal angle or a non-zero inclination (e.g., a vertical angle of +10° or) −10°. In FIG. 2, if the scan pattern 200 has a 60°×15° field of regard, then scan pattern 200 covers a ±30° horizontal range with respect to reference line 220 and a ±7.5° vertical range with respect to reference line 220. Additionally, optical beam 125 in FIG. 2 has an orientation of approximately −15° horizontal and +3° vertical with respect to reference line 220. Optical beam 125 may be referred to as having an azimuth of −15° and an altitude of +3° relative to reference line 220. An azimuth (which may be referred to as an azimuth angle) may represent a horizontal angle with respect to reference line 220, and an altitude (which may be referred to as an altitude angle, elevation, or elevation angle) may represent a vertical angle with respect to reference line 220.

A scan pattern 200 may include multiple pixels 210, and each pixel 210 may be associated with one or more optical pulses or one or more distance measurements. Additionally, a scan pattern 200 may include multiple scan lines 230, where each scan line represents one scan across at least part of a field of regard, and each scan line 230 may include multiple pixels 210. In FIG. 2, scan line 230 includes five pixels 210 and corresponds to an approximately horizontal scan across the FOR from right to left, as viewed from the lidar system 100. A complete cycle or traversal of a scan pattern 200 may include a total of Pₓ×P_{y} pixels 210 (e.g., a two-dimensional distribution of Pₓ by P_{y} pixels). As an example, scan pattern 200 may include a distribution with dimensions of approximately 100-2,000 pixels 210 along a horizontal direction and approximately 4-400 pixels 210 along a vertical direction. As another example, scan pattern 200 may include a distribution of 1,000 pixels 210 along the horizontal direction by 64 pixels 210 along the vertical direction (e.g., the frame size is 1000×64 pixels) for a total of 64,000 pixels per cycle of scan pattern 200.

A pixel 210 may refer to a data element that includes (i) distance information (e.g., a distance from a lidar system 100 to a target 130 from which an associated pulse of light was scattered) or (ii) an elevation angle and an azimuth angle associated with the pixel (e.g., the elevation and azimuth angles along which the associated pulse of light was emitted). Each pixel 210 may be associated with a distance (e.g., a distance to a portion of a target 130 from which an associated pulse of light was scattered) or one or more angular values. As an example, a pixel 210 may be associated with a distance value and two angular values (e.g., an azimuth and altitude) that represent the angular location of the pixel 210 with respect to the lidar system 100. A distance to a portion of target 130 may be determined based at least in part on a time-of-flight measurement for a corresponding pulse. An angular value (e.g., an azimuth or altitude) may correspond to an angle (e.g., relative to reference line 220) of output beam 125 (e.g., when a corresponding pulse is emitted from lidar system 100) or an angle of input beam 135 (e.g., when an input signal is received by lidar system 100). An angular value may be determined based at least in part on a position of a component of a scanner 120. As an example, an azimuth or altitude value associated with a pixel 210 may be determined from an angular position of one or more corresponding scan mirrors of the scanner 120.

FIG. 3 illustrates an example lidar system 100 with an example rotating polygon mirror 301. A scanner 120 may include a polygon mirror 301 configured to scan output beam 125 along a first direction and a scan mirror 302 configured to scan output beam 125 along a second direction different from the first direction (e.g., the first and second directions may be approximately orthogonal to one another, or the second direction may be oriented at any suitable non-zero angle with respect to the first direction). In the example of FIG. 3, scanner 120 includes two scan mirrors: (1) a polygon mirror 301 that rotates along the Θₓ direction and (2) a scan mirror 302 that oscillates back and forth along the Θ_{y} direction. The output beam 125 from light source 110, which passes alongside mirror 115, is reflected by reflecting surface 320 of scan mirror 302 and is then reflected by a reflecting surface (e.g., surface 320A, 320B, 320C, or 320D) of polygon mirror 301. Scattered light from a target 130 returns to the lidar system 100 as input beam 135. The input beam 135 reflects from polygon mirror 301, scan mirror 302, and mirror 115, which directs input beam 135 through focusing lens 330 and to the detector 340 of receiver 140. The detector 340 may be a PN photodiode, a PIN photodiode, an APD, a SPAD, a QD photodetector, or any other suitable detector. A reflecting surface 320 (which may be referred to as a reflective surface) may include a reflective metallic coating (e.g., gold, silver, or aluminum) or a reflective dielectric coating, and the reflecting surface 320 may have any suitable reflectivity at an operating wavelength of the light source 110 (e.g., the reflectivity may be greater than or equal to 70%, 80%, 90%, 95%, 98%, or 99%).

A polygon mirror 301 may be configured to scan output beam 125 along any suitable direction. As an example, a polygon mirror 301 may scan output beam 125 at any suitable angle with respect to a horizontal or vertical direction, such as for example, at an angle of approximately 0°, 10°, 20°, 30°, 45°, 60°, 70°, 80°, or 90° with respect to a horizontal or vertical direction. As another example, a polygon mirror 301 may be configured to rotate along a Θₓ or Θ_{y} direction and scan output beam 125 along a substantially horizontal or vertical direction, respectively. A rotation along a Θₓ direction may refer to a rotational motion of mirror 301 that results in output beam 125 scanning along an x-direction (e.g., a substantially horizontal direction). Similarly, a rotation along a Θ_{y} direction may refer to a rotational motion that results in output beam 125 scanning along a y-direction (e.g., a substantially vertical direction). In FIG. 3, mirror 301 is a polygon mirror that rotates along the Θₓ direction and scans output beam 125 along a substantially horizontal direction, and mirror 302 pivots along the Θ_{y} direction and scans output beam 125 along a substantially vertical direction.

A polygon mirror 301 may refer to a multi-sided object having reflective surfaces 320 on two or more of its sides or faces. For example, a polygon mirror 301 may have multiple reflective surfaces 320 that are angularly offset from one another along a periphery of the polygon mirror. As another example, a polygon mirror may include any suitable number of reflective faces (e.g., 2, 3, 4, 5, 6, 7, 8, or 10 faces), where each face includes a reflective surface 320. A polygon mirror 301 may have a cross-sectional shape of any suitable polygon, such as for example, a triangle (with three reflecting surfaces 320), square (with four reflecting surfaces 320), pentagon (with five reflecting surfaces 320), hexagon (with six reflecting surfaces 320), heptagon (with seven reflecting surfaces 320), or octagon (with eight reflecting surfaces 320). In FIG. 3, the polygon mirror 301 has a substantially square cross-sectional shape and four reflecting surfaces (320A, 320B, 320C, and 320D). The polygon mirror 301 in FIG. 3 may be referred to as a square mirror, a cube mirror, or a four-sided polygon mirror. In FIG. 3, the polygon mirror 301 may have a shape similar to a cube, cuboid, or rectangular prism. Additionally, the polygon mirror 301 may have a total of six sides, where four of the sides include faces with reflective surfaces (320A, 320B, 320C, and 320D).

A polygon mirror 301 may be continuously rotated in a clockwise or counter-clockwise rotation direction about a rotation axis of the polygon mirror 301. The rotation axis may correspond to a line that is perpendicular to the plane of rotation of the polygon mirror 301 and that passes through the center of mass of the polygon mirror 301. In FIG. 3, the polygon mirror 301 rotates in the plane of the drawing, and the rotation axis of the polygon mirror 301 is perpendicular to the plane of the drawing. An electric motor may be configured to rotate a polygon mirror 301 at a substantially fixed rotation speed (e.g., a rotational frequency of approximately 1 Hz (or, 1 revolution per second), 10 Hz, 50 Hz, 100 Hz, 500 Hz, or 1,000 Hz). As an example, a polygon mirror 301 may be mechanically coupled to an electric motor (e.g., a synchronous electric motor) which is configured to spin the polygon mirror 301 at a rotation speed of approximately 160 Hz (or, 9600 revolutions per minute (RPM)).

In FIG. 3, the output beam 125 may be reflected sequentially from the reflective surfaces 320A, 320B, 320C, and 320D as the polygon mirror 301 is rotated. This results in the output beam 125 being scanned along a particular scan axis (e.g., a horizontal or vertical scan axis) to produce a sequence of scan lines, where each scan line corresponds to a reflection of the output beam 125 from one of the reflective surfaces of the polygon mirror 301. In FIG. 3, the output beam 125 reflects off of reflective surface 320A to produce one scan line. Then, as the polygon mirror 301 rotates, the output beam 125 reflects off of reflective surfaces 320B, 320C, and 320D to produce a second, third, and fourth respective scan line. A lidar system 100 may be configured so that the output beam 125 is first reflected from polygon mirror 301 and then from scan mirror 302 (or vice versa). As an example, an output beam 125 from light source 110 may first be directed to polygon mirror 301, where it is reflected by a reflective surface of the polygon mirror 301, and then the output beam 125 may be directed to scan mirror 302, where it is reflected by reflective surface 320 of the scan mirror 302. In the example of FIG. 3, the output beam 125 is reflected from the polygon mirror 301 and the scan mirror 302 in the reverse order. In FIG. 3, the output beam 125 from light source 110 is first directed to the scan mirror 302, where it is reflected by reflective surface 320, and then the output beam 125 is directed to the polygon mirror 301, where it is reflected by reflective surface 320A.

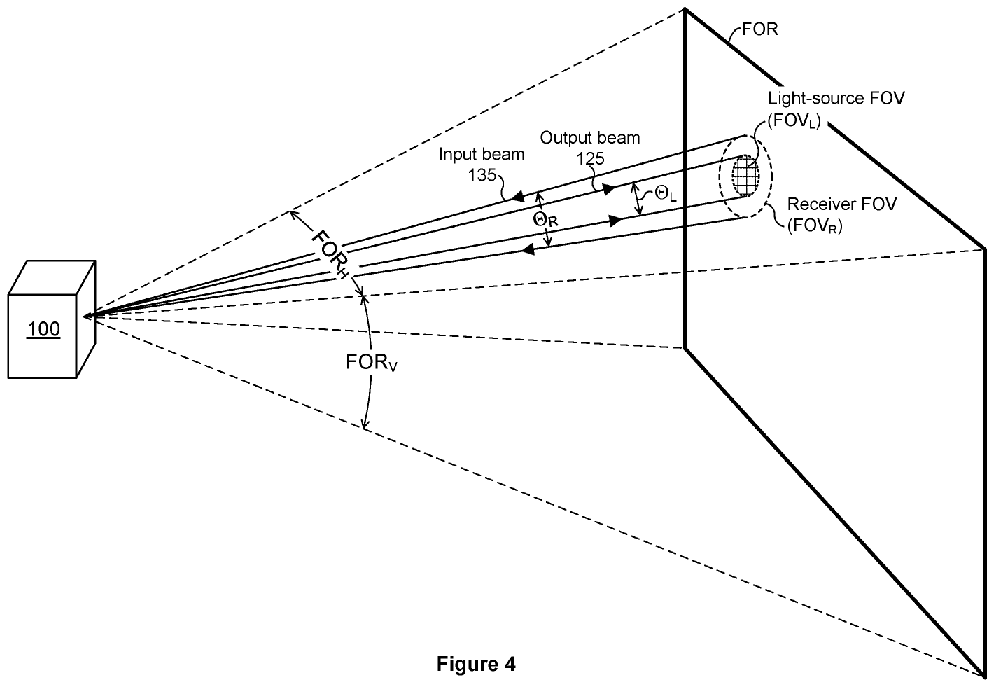

FIG. 4 illustrates an example light-source field of view (FOV_{L}) and receiver field of view (FOV_{R}) for a lidar system 100. A light source 110 of lidar system 100 may emit pulses of light as the FOV_{L} and FOV_{R} are scanned by scanner 120 across a field of regard (FOR). A light-source field of view may refer to an angular cone illuminated by the light source 110 at a particular instant of time. Similarly, a receiver field of view may refer to an angular cone over which the receiver 140 may receive or detect light at a particular instant of time, and any light outside the receiver field of view may not be received or detected. As an example, as the light-source field of view is scanned across a field of regard, a portion of a pulse of light emitted by the light source 110 may be sent downrange from lidar system 100, and the pulse of light may be sent in the direction that the FOV_{L} is pointing at the time the pulse is emitted. The pulse of light may scatter off a target 130, and the receiver 140 may receive and detect a portion of the scattered light that is directed along or contained within the FOV_{R}.

A scanner 120 may be configured to scan both a light-source field of view and a receiver field of view across a field of regard of the lidar system 100. Multiple pulses of light may be emitted and detected as the scanner 120 scans the FOV_{L} and FOV_{R} across the field of regard of the lidar system 100 while tracing out a scan pattern 200. The light-source field of view and the receiver field of view may be scanned synchronously with respect to one another, so that as the FOV_{L} is scanned across a scan pattern 200, the FOV_{R} follows substantially the same path at the same scanning speed. Additionally, the FOV_{L} and FOV_{R} may maintain the same relative position to one another as they are scanned across the field of regard. As an example, the FOV_{L} may be substantially overlapped with or centered inside the FOV_{R} (as illustrated in FIG. 4), and this relative positioning between FOV_{L} and FOV_{R} may be maintained throughout a scan. As another example, the FOV_{R} may lag behind the FOV_{L} by a particular, fixed amount throughout a scan (e.g., the FOV_{R} may be offset from the FOV_{L} in a direction opposite the scan direction).

An output beam of light 125 emitted by light source 110 may be a collimated optical beam having any suitable beam divergence, such as for example, a full-angle beam divergence Θ_{L} of approximately 0.5 to 10 milliradians (mrad). A divergence Θ_{L} of output beam 125 (which may be referred to as an angular size of the output beam) may correspond to an angular measure of an increase in beam size (e.g., a beam radius or beam diameter) as output beam 125 travels away from light source 110 or lidar system 100. An output beam 125 may have a substantially circular cross section with a beam divergence characterized by a single divergence value. As an example, an output beam 125 with a circular cross section and a full-angle beam divergence Θ_{L} of 2 mrad may have a beam diameter or spot size of approximately 20 cm at a distance of 100 m from lidar system 100. An output beam 125 may have a substantially elliptical cross section characterized by two divergence values. As an example, output beam 125 may have a fast axis and a slow axis, where the fast-axis divergence is greater than the slow-axis divergence. As another example, output beam 125 may be an elliptical beam with a fast-axis divergence of 4 mrad and a slow-axis divergence of 2 mrad.

The angular size Θ_{R} of a FOV_{R} may correspond to an angle over which the receiver 140 may receive and detect light. The receiver field of view may be any suitable size relative to the light-source field of view. As an example, the receiver field of view may be smaller than, substantially the same size as, or larger than the angular size of the light-source field of view. The light-source field of view may have an angular size of less than or equal to 50 milliradians, and the receiver field of view may have an angular size of less than or equal to 50 milliradians. The FOV_{L} may have any suitable angular size Θ_{L}, such as for example, an angular size of approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. Similarly, the FOV_{R} may have any suitable angular size Θ_{R}, such as for example, an angular size of approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. The light-source field of view and the receiver field of view may have approximately equal angular sizes. As an example, Θ_{L} and Θ_{R} may both be approximately equal to 0.5 mrad, 1 mrad, or 2 mrad. Alternatively, the receiver field of view may be larger than the light-source field of view, or the light-source field of view may be larger than the receiver field of view. As an example, Θ_{L} may be approximately equal to 1 mrad, and Θ_{R} may be approximately equal to 2 mrad. As another example, Θ_{R} may be approximately L times larger than Θ_{L}, where L is any suitable factor, such as for example, 1.1, 1.2, 1.5, 2, 3, 5, or 10.

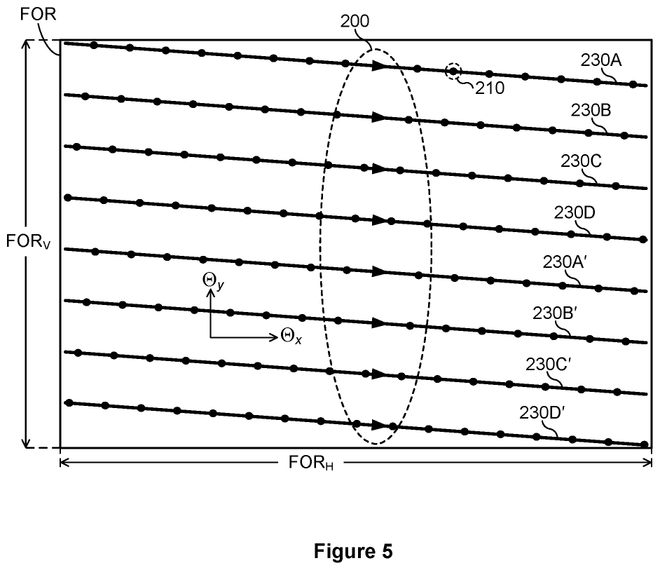

FIG. 5 illustrates an example unidirectional scan pattern 200 that includes multiple pixels 210 and multiple scan lines 230. A scan pattern 200 may include any suitable number of scan lines 230 (e.g., approximately 1, 2, 5, 10, 20, 50, 100, 500, or 1,000 scan lines), and each scan line 230 of a scan pattern 200 may include any suitable number of pixels 210 (e.g., 1, 2, 5, 10, 20, 50, 100, 200, 500, 1,000, 2,000, or 5,000 pixels). The scan pattern 200 illustrated in FIG. 5 includes eight scan lines 230, and each scan line 230 includes approximately 16 pixels 210. A scan pattern 200 in which the scan lines 230 are scanned in two directions (e.g., alternately scanning from right to left and then from left to right) may be referred to as a bidirectional scan pattern 200, and a scan pattern 200 in which the scan lines 230 are scanned in the same direction may be referred to as a unidirectional scan pattern 200. The scan pattern 200 in FIG. 2 may be referred to as a bidirectional scan pattern, and the scan pattern 200 in FIG. 5 may be referred to as a unidirectional scan pattern 200 where each scan line 230 travels across the FOR in substantially the same direction (e.g., approximately from left to right as viewed from the lidar system 100). Scan lines 230 of a unidirectional scan pattern 200 may be directed across a FOR in any suitable direction, such as for example, from left to right, from right to left, from top to bottom, from bottom to top, or at any suitable angle (e.g., at a 0°, 5°, 10°, 30°, or 45° angle) with respect to a horizontal or vertical axis. Each scan line 230 in a unidirectional scan pattern 200 may be a separate line that is not directly connected to a previous or subsequent scan line 230.

A unidirectional scan pattern 200 may be produced by a scanner 120 that includes a polygon mirror (e.g., polygon mirror 301 of FIG. 3), where each scan line 230 is associated with a particular reflective surface 320 of the polygon mirror. As an example, reflective surface 320A of polygon mirror 301 in FIG. 3 may produce scan line 230A in FIG. 5. Similarly, as the polygon mirror 301 rotates, reflective surfaces 320B, 320C, and 320D may successively produce scan lines 230B, 230C, and 230D, respectively. Additionally, for a subsequent revolution of the polygon mirror 301, the scan lines 230A′, 230B′, 230C′, and 230D′ may be successively produced by reflections of the output beam 125 from reflective surfaces 320A, 320B, 320C, and 320D, respectively. One full revolution of a S-sided polygon mirror may correspond to S successive scan lines 230 of a unidirectional scan pattern 200. As an example, the four scan lines 230A, 230B, 230C, and 230D in FIG. 5 may correspond to one full revolution of the four-sided polygon mirror 301 in FIG. 3. Additionally, a subsequent revolution of the polygon mirror 301 may produce the next four scan lines 230A′, 230B′, 230C′, and 230D′ in FIG. 5.

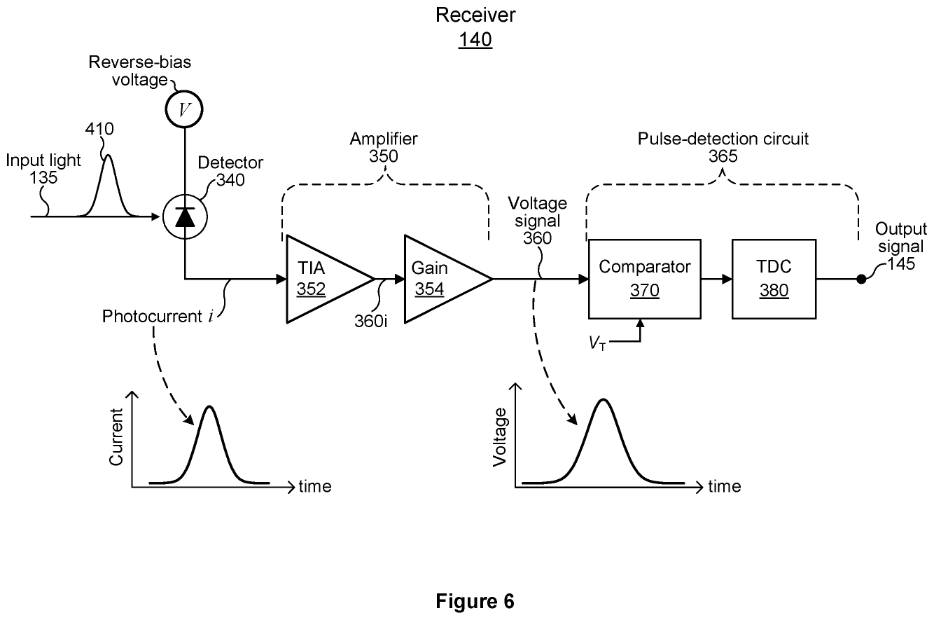

FIG. 6 illustrates an example receiver 140 that includes a detector 340, electronic amplifier 350, and pulse-detection circuit 365. The detector 340 receives a pulse of light 410, and in response to the received pulse of light 410, the detector produces a photocurrent signal i, which is sent to the amplifier 350. The photocurrent signal includes a pulse of electrical current (as shown in the example graph of current versus time) that corresponds to the received pulse of light 410, and the amplifier 350 produces a voltage pulse (as shown in the example graph of voltage versus time) that corresponds to the pulse of electrical current. An amplifier 350 and a pulse-detection circuit 365 may include circuitry that receives an electrical-current signal (e.g., photocurrent i) from a detector 340 and performs current-to-voltage conversion, signal amplification, sampling, filtering, signal conditioning, analog-to-digital conversion, time-to-digital conversion, pulse detection, threshold detection, rising-edge detection, falling-edge detection, or pulse time-of-arrival determination. An electronic amplifier 350 may include one or more transimpedance amplifiers (TIAs) 352 or one or more voltage-gain circuits 354, and a pulse-detection circuit 365 may include one or more comparators 370 or one or more time-to-digital converters (TDCs) 380. The amplifier 350 in FIG. 6 includes one TIA 352 and one voltage-gain circuit 354, and the pulse-detection circuit 365 includes one comparator 370 and one TDC 380. The output signal 145 from the pulse-detection circuit 365 may be sent to a controller 150, and based on the output signal 145, the controller 150 may determine the time of arrival of the received pulse of light 410 or a distance to a target 130 from which the received pulse of light was scattered.

In FIG. 6, the detector 340 receives an input-light signal 135 and produces a photocurrent signal i that is sent to an amplifier 350. The photocurrent signal i produced by the detector 340 in response to the input light 135 may be referred to as a photocurrent, electrical-current signal, electrical current, detector current, or current. The detector 340 may be a PN photodiode, a PIN photodiode, an APD, a SPAD, a QD photodetector, or any other suitable detector. The detector 340 may have an active region or an avalanche-multiplication region that includes silicon (Si), germanium (Ge), silicon germanium (SiGe), silicon germanium tin (SiGeSn), InGaAs, indium aluminum arsenide (InAlAs), InAsSb (indium arsenide antimonide), AlAsSb (aluminum arsenide antimonide), AlInAsSb (aluminum indium arsenide antimonide), or any other suitable detector material. The detector 340 may be configured to detect light at one or more operating wavelengths of a lidar system 100, such as for example at a wavelength of approximately 905 nm, 1200 nm, 1400 nm, 1500 nm, or 1550 nm, or at one or more wavelengths in the 1200-1600 nm range. For example, a light source 110 of a lidar system 100 may produce an output beam 125 having a wavelength of approximately 905 nm, and the detector 340 may be a silicon photodetector that detects 905-nm light. As another example, a light source 110 may emit light at one or more wavelengths from 1400 nm to 1600 nm, and the detector 340 may be a InGaAs APD that detects light in the 1400-1600 nm range. A receiver 140 may include a detector 340 with a single detector element (as illustrated in FIG. 6), or a receiver 140 may include a one-dimensional or two-dimensional detector array with multiple detector elements, as described below.

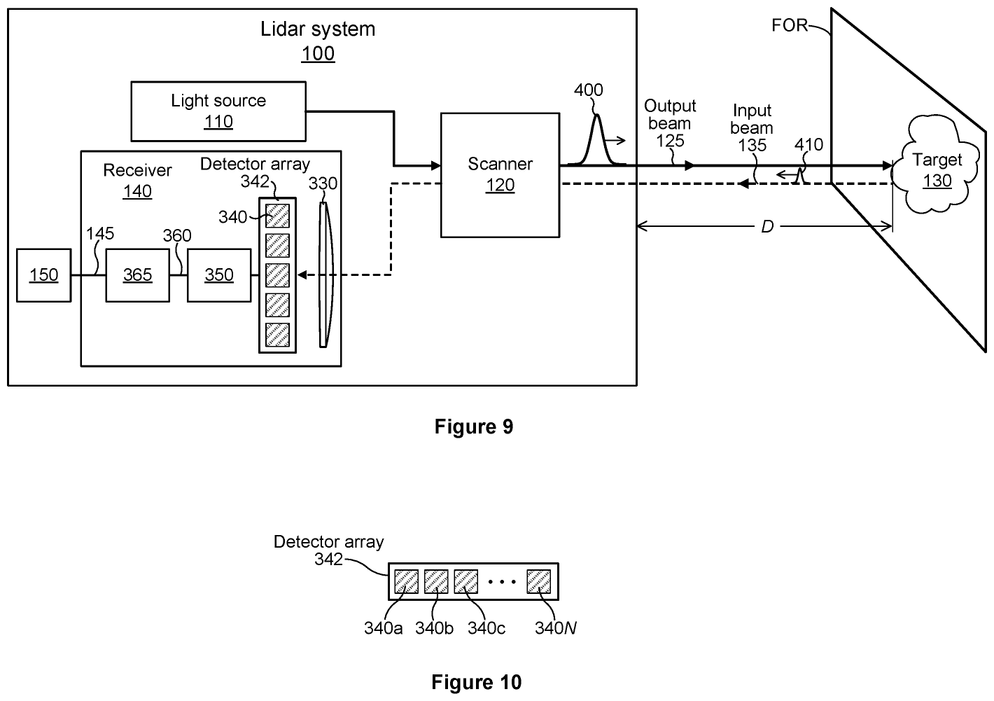

The receiver 140 in FIG. 6 includes a detector 340 coupled to an electronic amplifier 350, which in turn, is coupled to a pulse-detection circuit 365. The detector 340 may also be coupled to a voltage source that supplies a reverse-bias voltage V to the detector 340, as illustrated in FIG. 6. The detector 340 receives input light 135 and produces a photocurrent i that is sent to the amplifier 350, and the amplifier 350 amplifies the photocurrent signal to produce a voltage signal 360 that is sent to the pulse-detection circuit 365. In the example of FIG. 6, the input light 135 includes a received pulse of light 410 (which may include a portion of a pulse of light 400 emitted by a light source 110 and scattered by a remote target 130, e.g., as illustrated in FIG. 9). The photocurrent signal i includes a pulse of electrical current that corresponds to the received pulse of light 410, and the voltage signal 360 includes a voltage pulse that corresponds to the pulse of electrical current. A detector 340 producing a photocurrent signal i that corresponds to a received pulse of light 410 may refer to the detector 340 producing a pulse of current in response to receiving or detecting the pulse of light 410. Additionally, a photocurrent signal i (which includes a pulse of current) and a pulse of light 410 that correspond to one another may refer to the pulse of current and the pulse of light 410 having similar pulse characteristics (e.g., similar rise times, fall times, shapes, or durations). For example, the pulse of electrical current may have a rise time, fall time, or duration that is approximately equal to or somewhat greater than that of the pulse of light 410 (e.g., a rise time, fall time, or duration between 1× and 2× that of the pulse of light 410). The pulse of electrical current may have a somewhat longer rise time, fall time, or duration due to a limited electrical bandwidth of the detector 340 or the detector circuitry. As another example, the pulse of light 410 may have a 1-ns rise time and a 4-ns duration, and the corresponding pulse of electrical current produced by the detector 340 may have a 1.2-ns rise time and a 5-ns duration.

An electronic amplifier 350 may receive a photocurrent signal i from a detector 340 and amplify the photocurrent signal to produce a voltage signal 360 that corresponds to the received photocurrent. As an example, in response to a received pulse of light 410 (e.g., light from an emitted pulse of light 400 that is scattered by a remote target 130), a detector 340 may produce a photocurrent i that includes a pulse of electrical current corresponding to the received pulse of light 410. An amplifier 350 may receive the electrical-current pulse from the detector 340 and produce a voltage signal 360 that includes a voltage pulse corresponding to the received current pulse. An amplifier 350 producing a voltage pulse that corresponds to a pulse of current may refer to the amplifier 350 producing the voltage pulse in response to receiving the pulse of current. Additionally, the voltage pulse and the current pulse corresponding to one another may refer to the voltage pulse and the current pulse having similar rise times, fall times, shapes, durations, or other similar characteristics. For example, the voltage pulse may have a rise time, fall time, or duration that is between 1× and 2× that of the pulse of electrical current. The voltage pulse may have a somewhat longer rise time, fall time, or duration due to a limited electrical bandwidth of the amplifier 350. As another example, the pulse of electrical current may have a 1.2-ns rise time and a 5-ns duration, and the corresponding voltage pulse may have a 1.5-ns rise time and a 7-ns duration.

The electronic amplifier 350 in FIG. 6 includes a transimpedance amplifier (TIA) 352 followed by a voltage-gain circuit 354 (which may be referred to as a voltage amplifier or a gain channel). The TIA 352 receives the photocurrent signal i and amplifies the photocurrent to produce an intermediate voltage signal 360i, and the voltage amplifier 354 further amplifies the intermediate voltage signal to produce an output voltage signal 360 that is supplied to the pulse-detection circuit 365. A TIA 352 may be referred to as a current-to-voltage converter, and producing a voltage signal from a received photocurrent signal may be referred to as performing current-to-voltage conversion. The transimpedance gain or amplification of a TIA 352 may be expressed in units of ohms (Ω), or equivalently volts per ampere (V/A). For example, if a TIA 352 has a gain of 100 V/A, then for a photocurrent i with a peak current of 10 μA, the TIA may produce a voltage signal 360 with a corresponding peak voltage of approximately 1 mV. The gain circuit 354 in FIG. 6 may receive a voltage pulse from a TIA 352, and the gain circuit 354 may amplify the voltage pulse by any suitable amount, such as for example, by a voltage gain of approximately 0 dB, 3 dB, 10 dB, 20 dB, 30 dB, 40 dB, or 50 dB. Alternatively, an electronic amplifier 350 may not include a separate voltage amplifier, and a TIA 352 may amplify a photocurrent signal i to directly produce a voltage signal 360 (e.g., without an additional or separate voltage-amplification stage located after the TIA). An electronic amplifier 350 may include an electronic filter (e.g., a low-pass, high-pass, or band-pass filter) that filters the photocurrent signal i, intermediate voltage signal 360i, or voltage signal 360. For example, a TIA 352 or voltage amplifier 354 may include a high-pass filter that attenuates signals below a particular upper cutoff frequency (e.g., below 1 MHz, 10 MHz, 50 MHz, 100 MHz, 200 MHz, or any other suitable frequency). As another example, a TIA 352 or voltage amplifier 354 may include a low-pass filter that attenuates signals above a particular lower cutoff frequency (e.g., above 200 MHz, 500 MHz, 1 GHz, 2 GHz, or any other suitable frequency). As another example, a TIA 352 or voltage amplifier 354 may include a band-pass filter having particular lower and upper cutoff frequencies.

The pulse-detection circuit 365 in FIG. 6 includes one comparator 370 and one time-to-digital converter (TDC) 380. A comparator 370 may receive a voltage signal 360 from a TIA 352 or gain circuit 354 and produce an electrical-edge signal (e.g., a rising edge or a falling edge) when the received voltage signal 360 rises above or falls below a particular threshold voltage V_{T}. As an example, when a received voltage signal 360 rises above V_{T}, a comparator 370 may produce a rising-edge digital-voltage signal (e.g., a signal that steps from approximately 0 V to approximately 2.5 V, 3.3 V, 5 V, or any other suitable digital-high level). Additionally or alternatively, when a received voltage signal 360 falls below V_{T}, a comparator 370 may produce a falling-edge digital-voltage signal (e.g., a signal that steps down from approximately 2.5 V, 3.3 V, 5 V, or any other suitable digital-high level to approximately 0 V). The TDC 380 in FIG. 6 may receive an electrical-edge signal from the comparator 370 and produce an electrical output signal 145 (e.g., a digital signal, a digital word, or a digital value) that represents a time when the edge signal is received from the comparator 370. The time when the edge signal is received from the comparator 370 may correspond to a time of arrival of a received pulse of light 410, which may be used to determine a round-trip time of flight for a pulse of light to travel from a lidar system 100 to a target 130 and back to the lidar system 100. The output of the TDC 380 may include one or more numerical values, where each numerical value (which may be referred to as a numerical time value, a time value, a digital value, or a digital time value) corresponds to a time interval determined by the TDC 380. A TDC 380 may include or may be coupled to a counter or clock with any suitable period, such as for example, a clock period of 5 ps, 10 ps, 15 ps, 20 ps, 30 ps, 50 ps, 100 ps, 0.5 ns, 1 ns, 2 ns, 5 ns, or 10 ns. As an example, the TDC 380 may have an internal counter or clock with a 20-ps period, and the TDC 380 may determine that an interval of time between emission of a pulse of light and receipt of an electrical-edge signal is equal to 25,000 time periods, which corresponds to a time interval of approximately 0.5 microseconds. The TDC 380 may send an output signal 145 that includes the numerical value “25000” to a controller 150 of the lidar system 100.

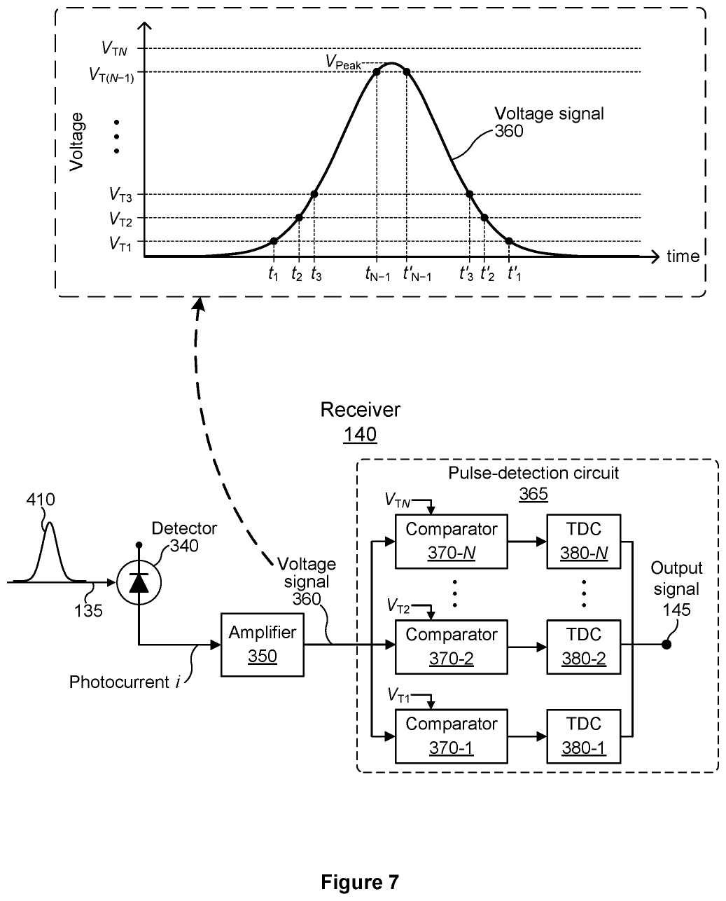

FIG. 7 illustrates an example receiver 140 with a pulse-detection circuit 365 that includes multiple comparators 370 and multiple time-to-digital converters (TDCs) 380. The input beam 135 includes a received pulse of light 410, and the detector 340 produces a photocurrent signal i in response to the received pulse of light. The electronic amplifier 350 receives the photocurrent signal and produces a voltage signal 360, where the voltage signal 360 corresponds to the received pulse of light 410. The voltage signal 360 and the received pulse of light 410 corresponding to one another may refer to the voltage signal 360 and the pulse of light 410 having similar rise times, fall times, shapes, durations, or other similar pulse characteristics. For example, a voltage pulse of the voltage signal 360 that is produced in response to the received pulse of light 410 may have a rise time, fall time, or duration that is between 1× and 4× that of the pulse of light 410. The voltage signal 360 may have a somewhat longer rise time, fall time, or duration due to a limited electrical bandwidth of the detector 340 or the amplifier 350. As another example, the received pulse of light may have a 1-ns rise time, a 4-ns duration, and a 1-ns fall time, and the corresponding voltage signal 360 may include a voltage pulse with a 1.5-ns rise time, a 7-ns duration, and a 3-ns fall time.

A light source 110 of a lidar system 100 may emit a pulse of light 400, and a receiver 140 may be configured to detect an input beam 135 that includes a received pulse of light 410 (where the received pulse of light 410 includes a portion of the emitted pulse of light 400 scattered by a remote target 130). A receiver 140 of a lidar system 100 may include one or more detectors 340, one or more electronic amplifiers 350, multiple comparators 370, or multiple time-to-digital converters (TDCs) 380. The receiver 140 in FIG. 7 includes a detector 340 configured to receive input light 135 and produce a photocurrent i that corresponds to the received pulse of light 410. The amplifier 350 amplifies the photocurrent i to produce a voltage signal 360 that is sent to the pulse-detection circuit 365. The receiver in FIG. 7 is similar to that of FIG. 6, except in FIG. 7, the pulse-detection circuit 365 includes multiple comparators 370 and multiple TDCs 380.

The voltage signal 360 produced by the amplifier 350 in FIG. 7 is coupled to N comparators (comparators 370-1, 370-2, . . . , 370-N), and each comparator is supplied with a particular threshold voltage (V_{T1}, V_{T2}, . . . , V_{TN}). A pulse-detection circuit 365 may include 1, 2, 5, 10, 50, 100, 500, 1,000, or any other suitable number of comparators 370, and each comparator 370 may be supplied with a different threshold voltage. The pulse-detection circuit 365 in FIG. 6 includes one comparator 370, while the pulse-detection circuit 365 in FIG. 7 includes multiple comparators 370. For example, the pulse-detection circuit 365 in FIG. 7 may include N=10 comparators, and the threshold voltages may be set to 10 values between 0 volts and 1 volt (e.g., V_{T1}=0.1 V, V_{T2}=0.2 V, and V_{T10}=1.0 V). Each comparator may produce an electrical-edge signal (e.g., a rising or falling electrical edge) when the voltage signal 360 rises above or falls below a particular threshold voltage. For example, comparator 370-2 may produce a rising edge at time t₂ when the voltage signal 360 rises above the threshold voltage V_{T2}, and comparator 370-2 may produce a subsequent falling edge at time t₁ when the voltage signal 360 falls below the threshold voltage V_{T2}.

The pulse-detection circuit 365 in FIG. 7 includes N time-to-digital converters (TDCs 380-1, 380-2, . . . , 380-N), and each comparator 370 is coupled to a TDC 380. Each comparator-TDC pair in FIG. 7 (e.g., comparator 370-1 and TDC 380-1) may be referred to as a threshold detector. A comparator may provide an electrical-edge signal to a corresponding TDC, and the TDC may act as a timer that produces an electrical output signal that represents a time when the edge signal is received from the comparator. For example, when the voltage signal 360 rises above the threshold voltage V_{T1} at time t₁, comparator 370-1 may produce a rising-edge signal that is supplied to the input of TDC 380-1, and the TDC 380-1 may produce a digital time value corresponding to time t₁. Additionally, when the voltage signal 360 subsequently falls below the threshold voltage V_{T1} at time the comparator 370-1 may produce a falling-edge signal that is supplied to the input of TDC 380-1, and TDC 380-1 may produce another digital time value corresponding to time t′₁. The digital time values may be referenced to a time when a pulse of light 400 is emitted by a light source 110, and one or more digital time values may correspond to or may be used to determine a round-trip time for the pulse of light to travel from a lidar system 100, to a target 130, and back to the lidar system 100.

The voltage signal 360 illustrated in FIG. 7 may be an analog signal produced by the electronic amplifier 350 and may correspond to the pulse of light 410 detected by the receiver 140. The voltage levels on the y-axis correspond to the threshold voltages V_{T1}, V_{T2}, . . . , V_{TN} of the respective comparators 370-1, 370-2, . . . , 370-N. The time values t₁, t₂, t₃, . . . , t_{N-1} correspond to times when the voltage signal 360 exceeds the corresponding threshold voltages, and the time values t′₁, t′₂, t′₃, . . . , t′_{N-1} correspond to times when the voltage signal 360 falls below the corresponding threshold voltages. For example, at time t₁ when the voltage signal 360 exceeds the threshold voltage V_{T1}, comparator 370-1 may produce an edge signal, and TDC 380-1 may output a digital value corresponding to the time t₁. Additionally, the TDC 380-1 may output a digital value corresponding to the time t₁ when the voltage signal 360 falls below the threshold voltage V_{T1}. Alternatively, the receiver 140 may include an additional TDC (not illustrated in FIG. 7) configured to produce a digital value corresponding to time t₁ when the voltage signal 360 falls below the threshold voltage V_{T1}. The output signal 145 from pulse-detection circuit 365 may include one or more digital values that correspond to one or more of the time values t₁, t₂, t₃, . . . , t_{N-1} and t′₁, t′₂, t′₃, . . . , t′_{N-1}. Additionally, the output signal 145 may also include one or more values corresponding to the threshold voltages associated with the time values. Since the voltage signal 360 in FIG. 7 does not exceed the threshold voltage V_{TN}, the corresponding comparator 370-N may not produce an edge signal. As a result, TDC 380-N may not produce a time value, or TDC 380-N may produce a signal indicating that no edge signal was received.

The receiver 140 in FIG. 7 detects a received pulse of light 410, and the pulse-detection circuit 365 produces an output signal 145 that corresponds to the received pulse of light 410. For example, the output signal 145 in FIG. 7 may be a digital signal that corresponds to the analog voltage signal 360, which in turn corresponds to the photocurrent signal i, which in turn corresponds to the received pulse of light 410. The output signal 145 may include one or more digital time values from each of the TDCs 380 that received one or more edge signals from a comparator 370, and the digital time values may represent the analog voltage signal 360. For example, TDC 380-1 may provide two digital time values (corresponding to times t₁ and t′₁) as part of the output signal 145. The output signal 145 from a pulse-detection circuit 365 may be sent to a controller 150, and a time of arrival of the received pulse of light (which may be referred to as a time of receipt for the received pulse of light) may be determined based at least in part on the time values produced by the TDCs. For example, the time of arrival may be determined from a time associated with a peak (e.g., Vₚₑₐₖ), a temporal center (e.g., a centroid or weighted average), or a rising or falling edge of the voltage signal 360.

The output signal 145 in FIG. 7 may correspond to the received pulse of light 410 and may include digital values from each of the TDCs that receive an edge signal from a comparator. Each digital value may represent a time interval between the emission of an optical pulse by a light source 110 and the receipt of an edge signal from a comparator. For example, a light source 110 may emit a pulse of light 400 that is scattered by a target 130, and a receiver 140 may receive a portion of the scattered pulse of light as an input pulse of light 410. When the light source emits the pulse of light, a count value of the TDCs may be reset to zero counts, and a digital value produced by a TDC 380 may represent an amount of time elapsed since the pulse of light was emitted. Alternatively, the TDCs in receiver 140 may accumulate counts continuously over multiple pulse periods (e.g., for 10, 100, 1,000, 10,000, or 100,000 pulse periods), and when a pulse of light is emitted, instead of resetting a TDC count value to zero counts, a TDC count associated with the time when pulse was emitted may be stored in memory. After the pulse of light is emitted, the TDCs may continue to accumulate counts that correspond to elapsed time without resetting the TDC count value to zero counts. In this case, a digital value produced by a TDC 380 may represent a count value at the time an edge signal is received by the TDC 380. Additionally, an amount of time elapsed since the pulse of light 400 was emitted may be determined by subtracting a count value associated with the emission of the pulse of light from the count value of the edge signal associated with a received pulse of light 410.

A round-trip time of flight (e.g., a time for an emitted pulse of light to travel from the lidar system 100 to a target 130 and back to the lidar system 100) may be determined based on a difference between a time of arrival and a time of emission for a pulse of light, and the distance D to the target 130 may be determined based on the round-trip time of flight. A time of arrival of a received pulse of light 410 may correspond to (i) a time associated with a peak of voltage signal 360, (ii) a time associated with a temporal center of voltage signal 360, or (iii) a time associated with a rising edge of voltage signal 360. For example, in FIG. 7 a time associated with the peak voltage (Vₚₑₐₖ) may be determined based on the threshold voltage V_{T(N-1)} (e.g., an average of the times t_{N-1} and t′_{N-1} may correspond to the peak-voltage time). As another example, a curve-fit or interpolation operation may be applied to the values of an output signal 145 to determine a time associated with the peak voltage or rising edge. A curve may be fit to the values of an output signal 145 to produce a curve that approximates the shape of a received optical pulse 410, and a time associated with the peak or rising edge of the curve may correspond to a peak-voltage time or a rising-edge time. As another example, a curve that is fit to the values of an output signal 145 of a pulse-detection circuit 365 may be used to determine a time associated with a temporal center of voltage signal 360 (e.g., the temporal center may be determined by calculating a centroid or weighted average of the curve).

Determining an interval of time between emission and receipt of a pulse of light may be based on determining (1) a time associated with the emission of a pulse of light 400 and (2) a time when a received pulse of light 410 (which may include a portion of the emitted pulse of light 400 scattered by a target 130) is detected by a receiver 140. As an example, a TDC 380 may count the number of time periods, clock cycles, or fractions of clock cycles between an electrical edge associated with emission of a pulse of light and an electrical edge associated with detection of scattered light from the emitted pulse of light. Determining when scattered light from the pulse of light is detected by receiver 140 may be based on determining one or more times for one or more rising or falling edges (e.g., rising or falling edges produced by one or more comparators 370) associated with the detected pulse of light. Determining a time associated with emission of a pulse of light 400 may be based on an electrical trigger signal. As an example, a light source 110 may produce an electrical trigger signal for each pulse of light that is emitted, or an electrical device (e.g., controller 150) may provide a trigger signal to the light source 110 to initiate the emission of each pulse of light. A trigger signal associated with emission of an optical pulse may be provided to a TDC 380, and a rising edge or falling edge of the trigger signal may correspond to a time when the optical pulse is emitted. A time associated with emission of an optical pulse may be determined based on an optical trigger signal. As an example, a time associated with the emission of a pulse of light 400 may be determined based at least in part on detection of a portion of light from the emitted pulse of light. The portion of the emitted pulse of light (which may be referred to as an optical trigger pulse) may be detected prior to or just after the corresponding emitted pulse of light exits the lidar system 100 (e.g., less than 10 ns after the emitted pulse of light exits the lidar system). The optical trigger pulse may be detected by a separate detector (e.g., a PIN photodiode or an APD) or by the receiver 140. The optical trigger pulse may be produced when a portion of light from an emitted pulse of light is scattered or reflected from a surface located within lidar system 100 (e.g., a surface of a beam splitter or window, or a surface of light source 110, mirror 115, or scanner 120). Some of the scattered or reflected light may be received by a detector 340 of receiver 140, and a pulse-detection circuit 365 coupled to the detector 340 may be used to determine that an optical trigger pulse has been detected. The time at which the optical trigger pulse was detected may be used to determine the emission time of the pulse of light 400.

A temporal correction or offset may be applied to a determined time of emission or time of arrival to account for signal delay within a lidar system 100. For example, there may be a time delay of 2 ns between an electrical trigger signal that initiates emission of a pulse of light and a time when the emitted pulse of light 400 exits the lidar system 100. To account for the 2-ns time delay, a 2-ns offset may be added to an initial time of emission determined by a receiver 140 or a controller of the lidar system 100. For example, a receiver 140 may receive an electrical trigger signal at time t_{TRIG} indicating emission of a pulse of light by light source 110. To compensate for the 2-ns delay between the trigger signal and the pulse of light exiting the lidar system 100, the emission time of the pulse of light may be indicated as (t_{TRIG}+2 ns). Similarly, there may be a 1-ns time delay between a received pulse of light 410 entering the lidar system 100 and a time when electrical edge signals corresponding to the received pulse of light are received by one or more TDCs 380 of a receiver 140. To account for the 1-ns time delay, a 1-ns offset may be subtracted from a determined time of arrival for a received pulse of light.

A pulse-detection circuit 365 or a controller 150 may determine a time of arrival of a received pulse of light 410. The time of arrival of a received pulse of light 410 may correspond to a time associated with a rising edge, falling edge, peak, or temporal center of the received pulse of light 410. The time of arrival of a received pulse of light 410 may be determined based on a corresponding photocurrent signal i produced by a detector 340. The photocurrent signal i may include a pulse of current corresponding to a received pulse of light 410, and an electronic amplifier 350 may produce a voltage signal 360 with a voltage pulse that corresponds to the pulse of current. The pulse-detection circuit 365 may determine the time of arrival of the received pulse of light 410 based on a characteristic of the voltage pulse (e.g., based on a time associated with a rising edge, falling edge, peak, or temporal center of the voltage pulse). Since the voltage signal 360 corresponds to the photocurrent signal i, determining a time of arrival based on a photocurrent signal i may include determining the time of arrival from a corresponding voltage signal 360. For example, the pulse-detection circuit 365 in FIG. 7 may determine the time of arrival of the received pulse of light 410 from the voltage signal 360, where the voltage signal 360 corresponds to the photocurrent signal i, which in turn corresponds to the received pulse of light.

Based on the time of arrival of a received pulse of light 410, a pulse-detection circuit 365 or a controller 150 may determine a round-trip time T for the received pulse of light 410 to travel to a target 130 and back to a lidar system 100. Additionally, a pulse-detection circuit 365 or a controller 150 may determine a distance D from the lidar system 100 to the target 130 based on the round-trip time T For example, a detector 340 may produce a pulse of photocurrent i in response to a received pulse of light 410, and an amplifier 350 may produce a voltage pulse (e.g., voltage signal 360) corresponding to the pulse of photocurrent. Based on the voltage signal 360, a pulse-detection circuit 365 or a controller 150 may determine a time of arrival of the received pulse of light. Additionally, the pulse-detection circuit 365 or the controller 150 may determine a time of emission for a pulse of light 400 (e.g., a time at which the pulse of light was emitted by a light source 110), where the received pulse of light 410 includes scattered light from the emitted pulse of light. Based on the time of arrival (T_{A}) and the time of emission (T_{E}), the pulse-detection circuit 365 or the controller 150 may determine the round-trip time T (e.g., T=T_{A}−T_{E}), and the distance D may be determined from the expression D=c·T/2.

A controller 150 may be located within a receiver 140, external to the receiver 140, or partially within and partially external to the receiver 140. For example, a controller 150 may be located external to the receiver 140, and an output signal 145 may be sent to the controller 150 for processing or analysis. Additionally, based on the output signal 145, the controller 150 may determine a time of arrival of a received pulse of light 410 or a distance D to a target 130. Alternatively, at least part of a controller 150 may be located within a receiver 140. For example, a controller 150 may include an ASIC that is located within the receiver 140 (e.g., the ASIC may include an amplifier 350 and a pulse-detection circuit 365, as well as additional circuitry configured to receive and process the output signal 145 from the pulse-detection circuit 365). In addition to an ASIC located within the receiver 140, the controller 150 may also include one or more additional processors located external to the receiver 140 or external to the lidar system 100. For example, an ASIC located within the receiver 140 may receive an output signal 145 and determine a time of arrival of a received pulse of light 410 or a distance to a target 130, and a processor located external to the receiver may process data from the ASIC to produce a point cloud, identify an object located ahead of a vehicle, or provide control signals to a vehicle's driving system. A time of arrival of a received pulse of light 410 being determined by a pulse-detection circuit 365 may refer to the time of arrival being determined by (i) the pulse-detection circuit 365, (ii) the pulse-detection circuit 365 and the controller 150, or (iii) the controller 150. Similarly, the distance D to a target 130 being determined by a controller 150 may refer to the distance to the target 130 being determined by (i) the pulse-detection circuit 365, (ii) the pulse-detection circuit 365 and the controller 150, or (iii) the controller 150.

A receiver 140 of a lidar system 100 may include one or more analog-to-digital converters (ADCs). As an example, instead of including multiple comparators and TDCs, a receiver 140 may include an ADC that receives a voltage signal 360 from an amplifier 350 and samples the signal to produce a digital representation of the voltage signal. The ADC may produce an output signal 145 that includes a series of digital values representing the temporal behavior or shape of the voltage signal 360, and a time of arrival of a received pulse of light 410 may be determined based on the output signal 145. Although this disclosure describes or illustrates example receivers 140 that include one or more comparators 370 and one or more TDCs 380, a receiver 140 may additionally or alternatively include one or more ADCs. As an example, in FIG. 7, instead of the N comparators 370 and N TDCs 380, the receiver 140 may include a pulse-detection circuit 365 with an ADC configured to receive the voltage signal 360 and produce a digital output signal 145 that includes digitized values that correspond to the voltage signal 360. One or more of the approaches for determining an optical characteristic of a received pulse of light 410 as described herein may be implemented using a pulse-detection circuit 365 that includes one or more comparators 370 and TDCs 380 or using a pulse-detection circuit 365 that includes one or more ADCs. For example, an optical characteristic (e.g., a time of arrival) of a received pulse of light 410 may be determined from an output signal 145 provided by multiple TDCs 380 of a pulse-detection circuit 365 (e.g., as illustrated in FIG. 7), or an optical characteristic may be determined from an output signal 145 provided by one or more ADCs of a pulse-detection circuit.

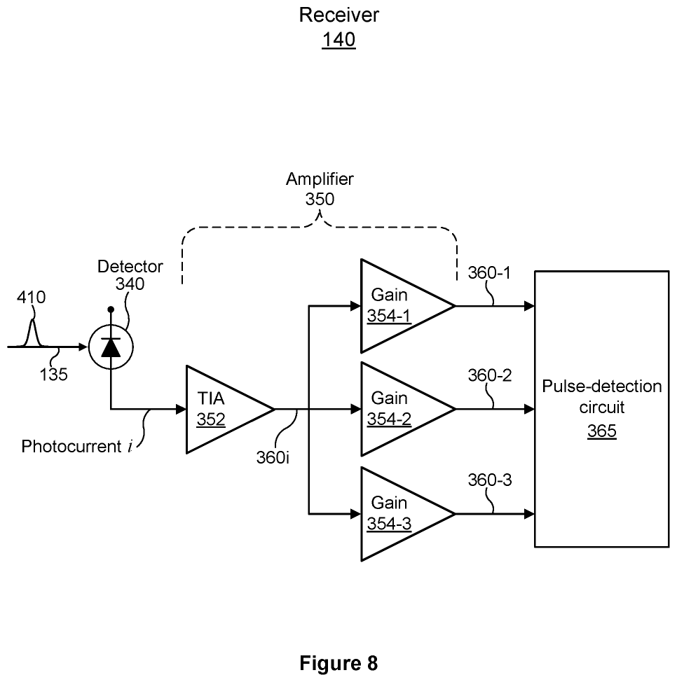

FIG. 8 illustrates an example receiver 140 with an electronic amplifier 350 that includes three voltage amplifiers (354-1, 354-2, and 354-3). An electronic amplifier 350 may include one or more TIAs 352 and one or more voltage amplifiers 354. The amplifier 350 in FIG. 6, which may be referred to as a single-channel amplifier, includes one TIA 352 and one voltage amplifier 354. In other embodiments, an amplifier 350 may be a multi-channel amplifier that includes a TIA 352 that is coupled to 2, 3, 4, 5, 10, or any other suitable number of voltage amplifiers 354. The voltage signal produced by each voltage amplifier may be coupled to a pulse-detection circuit 365. For example, the pulse-detection circuit may include multiple comparators 370 and multiple TDCs 380, and each voltage amplifier 354 may be coupled to one or more of the comparators of the pulse-detection circuit. Each comparator 370 of the pulse-detection circuit 365 may (i) receive a voltage signal produced by one of the voltage amplifiers and (ii) provide an electrical-edge signal to a corresponding TDC 380 when the received voltage signal rises above or falls below a particular threshold voltage.

The electronic amplifier 350 in FIG. 8, which may be referred to as a three-channel amplifier, includes one TIA 352 and three voltage amplifiers 354. The three voltage amplifiers are arranged in parallel so that each voltage amplifier receives an intermediate voltage signal 360i produced by the TIA 352. Each voltage amplifier may provide a particular voltage gain or a particular frequency filtering to the intermediate voltage signal 360i to produce a particular voltage signal 360 that is supplied to the pulse-detection circuit 365. For example, voltage amplifier 354-1 may amplify the intermediate voltage signal 360i by a voltage gain of 10 dB to produce voltage signal 360-1. Additionally, voltage amplifier 354-2 may amplify the intermediate voltage signal 360i by 20 dB to produce voltage signal 360-2, and voltage amplifier 354-3 may amplify the intermediate voltage signal 360i by 30 dB to produce voltage signal 360-3. As another example, voltage amplifier 354-1 may have unity gain (e.g., a voltage gain of 0 dB), or the intermediate voltage signal 360i may be directly coupled to the pulse-detection circuit as voltage signal 360-1 without being amplified by a voltage amplifier. An electronic amplifier 350 that includes multiple voltage amplifiers 354 with different gain values may provide a greater dynamic range or sensitivity than a single-channel electronic amplifier 350. Additionally or alternatively, each gain channel of a multi-channel amplifier may provide a frequency filter (e.g., a low-pass, high-pass, or band-pass filter) having particular frequency characteristics. For example, in FIG. 8, voltage amplifier 354-1 may include a low-pass filter with a cutoff frequency of 1 GHz. Additionally, voltage amplifier 354-2 may include a low-pass filter with a cutoff frequency of 600 MHz, and voltage amplifier 354-3 may include a low-pass filter with a cutoff frequency of 300 MHz.

FIG. 9 illustrates an example lidar system 100 with a receiver 140 that includes a one-dimensional detector array 342. The lidar system 100 in FIG. 9 includes a light source 110 that emits pulses of light 400 and a scanner 120 that scans the emitted pulses of light across a field of regard (FOR) of the lidar system. The pulses of light 400 emitted by the light source 110 may have one or more of the following optical characteristics: one or more wavelengths between 900 nm and 2000 nm; a pulse energy between 0.01 μJ and 100 μJ; a pulse repetition frequency between 80 kHz and 10 MHz; and a pulse duration between 0.1 ns and 100 ns. For example, the light source 110 may emit pulses of light 400 with a wavelength of approximately 1550 nm, a pulse energy of approximately 0.5 μJ per pulse, a pulse repetition frequency of approximately 750 kHz, and a pulse duration of approximately 3 ns. As another example, the light source 110 may emit pulses of light 400 with a wavelength from approximately 1500 nm to approximately 1510 nm. As another example, the light source 110 may emit pulses of light 400 having one or more wavelengths between approximately 1400 nm and approximately 1600 nm.

The lidar system 100 in FIG. 9 includes a receiver 140 that detects a received pulse of light 410, where the received pulse of light may include a portion of the emitted pulse of light 400 scattered by a target 130. The lidar system 100 in FIG. 9, which may be referred to as a lidar system with a detector array, includes a receiver 140 with a one-dimensional detector array 342. The detector array 342 includes multiple detector elements 340, where each detector element is configured to receive at least a portion of a received pulse of light 410 and produce a corresponding photocurrent signal. The detector array 342 in FIG. 9 is a 1×5 one-dimensional array that includes five detector elements 340 arranged in a line along a particular axis or direction. The input beam 135, which includes a received pulse of light 410, is focused by a focusing lens 330 onto the detector array 342, and one or more of the detector elements 340 may receive at least a portion of the received pulse of light 410. As the output beam 125 is scanned to different locations across the field of regard, the input beam 135 may be incident on corresponding detector elements 340 of the detector array 342, where the corresponding detector elements are related to the different locations that are scanned. Each of the one or more detector elements 340 that receives a portion of the pulse of light 410 may produce a photocurrent signal that is amplified by the electronic amplifier 350 to produce one or more voltage signals 360. The pulse-detection circuit 365 may receive the one or more voltage signals 360 and produce an output signal 145 that is sent to a controller 150. Based on the output signal 145, the pulse-detection circuit 365 or the controller 150 may determine a time of arrival of the received pulse of light 140. Additionally, the pulse-detection circuit 365 or the controller 150 may determine the distance D from the lidar system 100 to the target 130 based on the time of arrival of the received pulse of light 410.

The received pulse of light 410 in FIG. 9 may be incident on one or more detector elements 340 of the detector array 342. Each of the one or more detector elements 340 that receives at least a portion of the pulse of light 410 may produce a photocurrent signal corresponding to the received pulse of light. The electronic amplifier 350 may amplify each of the one or more photocurrent signals to produce one or more voltage signals, each voltage signal corresponding to one of the photocurrent signals. For example, the received pulse of light 410 in FIG. 9 may be incident on one of the detector elements 340 of the detector array 342, and the detector element may produce a photocurrent signal corresponding to the received pulse of light. The electronic amplifier 350 may amplify the photocurrent signal to produce a corresponding voltage signal 360 which is sent to the pulse-detection circuit 365. As another example, the received pulse of light 410 may be incident on three of the detector elements 340 of the detector array 342. Each of the three detector elements may receive a portion of the received pulse of light 410 and may produce a photocurrent signal corresponding to the portion of the received pulse of light. The electronic amplifier 350 may amplify the three photocurrent signals to produce three corresponding voltage signals which are sent to the pulse-detection circuit 365.

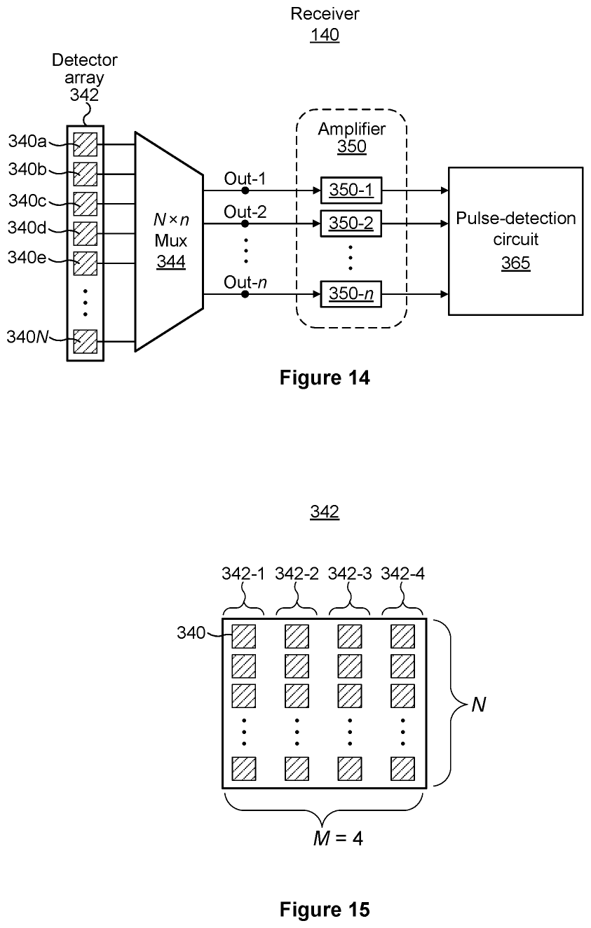

Photocurrent signals produced by the detectors 340 of a detector array 342 may be coupled to an amplifier 350. For example, each detector element 340 of a detector array 342 may be coupled to a TIA 352 of an amplifier 350. A detector array 342 with N detector elements 340 may be coupled to an amplifier 350 with N TIAs 352, where each detector element is coupled to one of the TIAs. Alternatively, the detector elements 340 of a detector array 342 may be coupled to an amplifier 350 through a switch or multiplexer (e.g., as illustrated in FIG. 14 and described below).

FIG. 10 illustrates a top view of an example one-dimensional detector array 342. A receiver 140 may include a detector array 342 that includes a one-dimensional or a two-dimensional arrangement of two or more detectors 340. Each detector 340 of a detector array 342 may be referred to as a detector element. The detector array 342 in FIG. 10 is a 1×N one-dimensional array that includes N detector elements 340 arranged in a line along a particular axis or direction. The axis or direction along which the detector elements are arranged may correspond to an axis or direction along which an output beam 125 is scanned. The parameter N is a positive integer that may have a value of 2, 4, 5, 10, 20, 50, 100, 200, 500, 1,000, or any other suitable value. For example, the parameter N may have a value of 100, which corresponds to a 1×100 one-dimensional detector array 342 with 100 detector elements 340. A received pulse of light 410 may be incident on one or more detector elements 340 of a detector array 342, and each of the one or more detectors may produce a photocurrent signal i that corresponds to the received pulse of light 410. For example, a received pulse of light 410 may be incident on detector 340b, and detector 340b may produce a photocurrent signal in response to the received pulse of light 410. Additionally, detectors 340a, 340b, and the other detectors of the detector array 342 may receive little or none of the received pulse of light 410, and those detectors may produce little to no significant photocurrent in response to the received pulse of light. As another example, a received pulse of light 410 may be incident on detectors 340a, 340b, and 340c, and each of the three detectors may produce a photocurrent signal corresponding to the portion of the received pulse of light that was incident on that detector. Additionally, the other detectors of the detector array 342 may receive little or none of the received pulse of light 410, and those detectors may produce little to no significant photocurrent in response to the received pulse of light 410.

Each detector element 340 of a detector array 342 may be a PN photodiode, a PIN photodiode, an APD, a SPAD, a quantum dot (QD) photodetector, or any other suitable detector. Each detector element 340 of a detector array 342 may have an active region or an avalanche-multiplication region that includes silicon (Si), germanium (Ge), silicon germanium (SiGe), silicon germanium tin (SiGeSn), indium gallium arsenide (InGaAs), indium aluminum arsenide (InAlAs), lead sulfide (PbS), indium arsenide antimonide (InAsSb), aluminum arsenide antimonide (AlAsSb), aluminum indium arsenide antimonide (AlInAsSb), or any other suitable detector material. For example, the detector array 342 in FIG. 10 may include detector elements 340 with InGaAs or InAlAs active regions, and the detector elements may be configured to detect light in the 1400-1600-nm wavelength range. As another example, the detector array 342 may include detector elements 340 with lead sulfide quantum dots configured to detect light in the 1400-1600-nm wavelength range.

A receiver 140 may include a detector array 342 having any suitable 1×N one-dimensional array of detectors 340 or any suitable M×N two-dimensional array of detectors 340 (where M and N are each integers greater than or equal to 2). Each of the parameters M and N may have a value of 2, 4, 5, 10, 20, 50, 100, 200, 500, 1,000, or any other suitable value. For example, a one-dimensional detector array 342 may include a 1×2 array of two detectors, a 1×4 array of four detectors, a 1×10 array of 10 detectors, a 1×100 array of 100 detectors, or a 1×500 array of 500 detectors. As another example, a two-dimensional detector array 342 may include a 2×2 array of four detectors, a 2×4 array of eight detectors, a 4×16 array of 64 detectors, a 16×16 array of 256 detectors, a 100×100 array of 10,000 detectors, or a 100×500 array of 50,000 detectors.

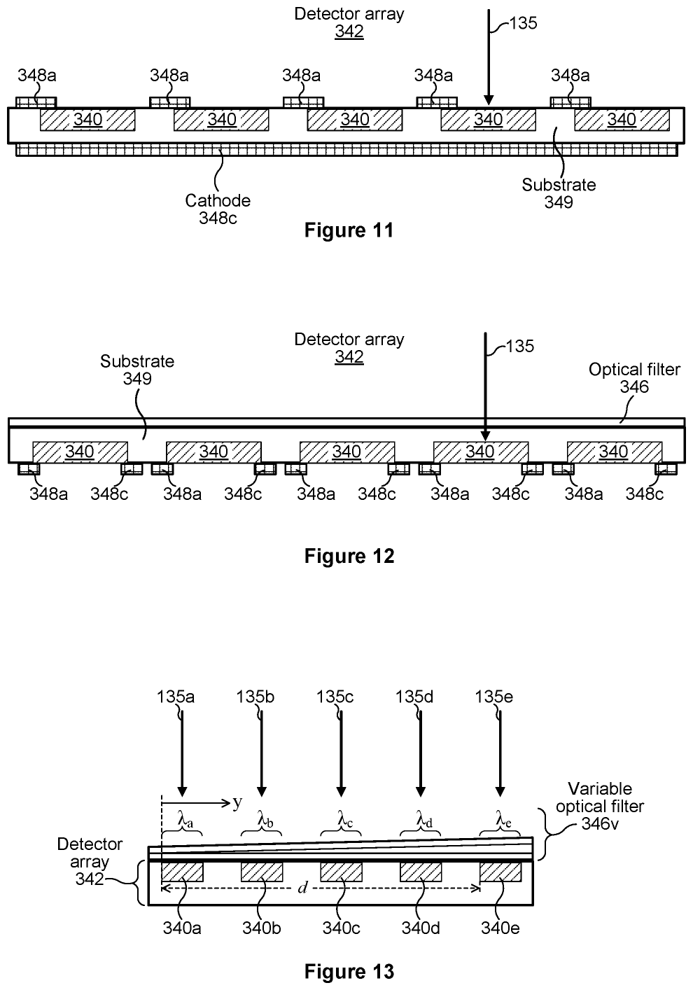

FIGS. 11-12 each illustrate a side view of an example one-dimensional detector array 342. A detector array 342 may be electrically configured as a device with (i) a common cathode and separate, electrically isolated anodes, (ii) a common anode and separate, electrically isolated cathodes, or (iii) separate, electrically isolated anodes and separate, electrically isolated cathodes. The detector array 342 in FIG. 11 is configured as a common-cathode device with separate anodes 348a and one common cathode 348c. Each of the five detector elements 340 is electrically coupled to one of five separate anodes 348a, which are electrically isolated from one another, and the detector cathodes are all electrically coupled to a single cathode 348c. The detector array 342 in FIG. 12 is configured as a separate-anode and separate-cathode device. Each of the five detector elements 340 is electrically coupled to one of five separate anodes 348a, which are electrically isolated from one another. Additionally, each of the five detector elements 340 is electrically coupled to one of five separate cathodes 348c, which are electrically isolated from one another.

Each detector element 340 of a detector array 342 may be electrically configured as a diode that includes a p-doped region that is electrically coupled to an anode and a n-doped region that is electrically coupled to a cathode, where the p-doped and n-doped regions form a p-n junction. In a common-anode detector array 342, the anodes of each of the detectors 340 may be electrically coupled together to form a common anode, while the detector cathodes are electrically isolated from one another. The common anode may be coupled to a voltage source that provides a reverse-bias voltage to the p-n junctions of the detectors 340, and the cathodes of each of the detectors may be coupled to an electronic amplifier 350 (e.g., each cathode may be coupled to the input of a TIA 352). In a common-cathode detector array 342 (e.g., as illustrated in FIG. 11), the cathodes of each of the detectors 340 may be electrically coupled together to form a common cathode 348c, while the detector anodes 348a are electrically isolated from one another. The common cathode 348c may be coupled to a voltage source that provides a reverse-bias voltage, and the anodes 348a of each of the detectors may be coupled to an electronic amplifier 350 (e.g., each anode may be coupled to the input of a TIA 352). In a separate-anode, separate-cathode detector array 342 (e.g., as illustrated in FIG. 12), the anodes 348a of each of the detectors 340 may be electrically isolated from one another, and the cathodes 348c of each of the detectors may be electrically isolated from one another. One end (e.g., anode 348a or cathode 348c) of each of the detectors 340 may be electrically coupled to an electronic amplifier 350 and the other end may be coupled to a reverse-bias voltage source.

Two terminals (e.g., two anodes or two cathodes) being electrically isolated from one another may refer to the two terminals having greater than a particular value of electrical resistance between them (e.g., the resistance between two electrically isolated anodes may be greater than 1 kΩ, 10 kΩ, 100 kΩ, or 1 MΩ). For example, in FIG. 11 the resistance between each of the anodes 348a may be greater than 1 kΩ, As another example, in FIG. 12 the resistance between each of the anodes 348a may be greater than 10 kΩ, and the resistance between each of the cathodes 348c may be greater than 10 kΩ, The substrate 349 in FIG. 12 may be configured to have a high resistivity at least in the regions around the anodes and cathodes to provide electrical isolation between the anodes and cathodes. Two terminals (e.g., two anodes or two cathodes) being electrically coupled together may refer to the two terminals having less than a particular value of electrical resistance between them (e.g., the resistance between two electrically connected cathodes may be less than 1 kΩ, 100Ω, 10Ω, or 1Ω). For example, the resistance between the cathodes of each of the detectors 340 in FIG. 11 may be less than 10Ω. A common-anode or common-cathode configuration may be provided by combining or electrically connecting the respective anodes or cathodes through an electrically conductive substrate 349. For example, a portion of the substrate 349 in FIG. 11 may include a low resistivity semiconductor material that electrically couples the cathodes of each of the detectors 340 to the common cathode 348c.

A detector array 342 with electrically isolated anodes and electrically isolated cathodes may provide improved electrical isolation between detector elements 340 as compared to a common-anode or common-cathode detector array. For example, the detector 340 in FIG. 11 that receives input beam 135 may produce a corresponding photocurrent signal. Additionally, one or more other detectors of the detector array 342 may also produce a corresponding cross-talk current signal caused by electrical coupling through the common cathode 348c. For the detector array 342 in FIG. 12, the detector 340 that receives input beam 135 may produce a corresponding photocurrent signal, and the other detectors may produce little or no cross-talk current signals since the anodes and cathodes of the detector array are electrically isolated.

A detector array 342 may include an optical filter 346 that transmits particular wavelengths of light to the detector elements 340 of the array. The optical filter 346 may include a dielectric coating that is deposited onto the detectors 340 or the detector substrate 349, and the coating may transmit particular wavelengths of light to the detectors 340. Additionally, the dielectric coating may reflect other wavelengths of light. The detector array 342 in FIG. 12 includes an optical filter 346 that may be deposited onto or attached to the substrate 349 of the detector array 342. The detector array 342 may be part of a lidar system 100 that operates with wavelengths between λ₁ and λ₂, and the optical filter 346 may provide an anti-reflection (AR) coating from approximately wavelength λ₁ to approximately wavelength λ₂. Compared to a detector array without an optical filter, an optical filter 346 with an AR coating may provide for increased transmission of an input beam 135 to the detector elements 340 of a detector array 342. Additionally, the optical filter 346 may provide a moderate or high-reflectivity at wavelengths less than approximately λ₁ or at wavelengths greater than approximately wavelength λ₂. For example, for a lidar system 100 operating in the 1530-1560-nm wavelength range, an optical filter 346 may have a reflectivity of less than or equal to 2% over the 1530-1560-nm operating wavelength range. Additionally, the optical filter 346 may have a reflectivity of greater than 50% from approximately 800 nm to approximately 1500 nm (e.g., the optical filter 346 may reflect most light from a source external to the lidar system, such as another lidar system operating at 905 nm). As another example, for a lidar system 100 operating at approximately 1550 nm, an optical filter 346 may have a reflectivity of less than or equal to 0.5% from approximately 1545 nm to approximately 1555 nm. Additionally, the optical filter 346 may have a reflectivity of greater than 50% from approximately 800 nm to approximately 1530 nm and from approximately 1570 nm to approximately 1650 nm.

An optical filter 346 with an AR coating that covers a lidar system operating wavelength range may provide for reduced optical loss due to reflection of an input beam 135 at an input surface of a detector array 342. This reduction in optical loss corresponds to an increased amount of the input beam 135 that is transmitted to the detector elements 340 and a corresponding increase in detection efficiency for a detector array 342. For example, an optical filter 346 may provide a reflectivity of less than 5% at one or more operating wavelengths of a lidar system, which may correspond to an optical transmission of greater than approximately 95% of an input beam 135 through the optical filter 346 and into the detector array 342. By comparison, a detector array 342 without an optical filter may have a reflectivity of greater than 25% (which corresponds to an optical transmission into the detector array of less than 75%). Additionally, an optical filter 346 that provides increased reflectivity at wavelengths outside of the operating wavelength range may provide for rejection of unwanted light from other sources external to the lidar system 100.

FIG. 13 illustrates a side view of an example one-dimensional detector array 342 with a variable optical filter 346v. A detector array 342 may include a variable optical filter 346 that transmits particular wavelengths of light to the detector elements 340 of the array, where the particular transmitted wavelengths vary with position along the detector array. In FIG. 13, five input beams (135a, 135b, 135c, 135d, and 135e) are incident on five respective detectors (340a, 340b, 340c, 340d, and 340e) of a detector array 342. The five input beams may have five different respective wavelengths λₐ, λ_{b}, λ_{c}, λ_{d}, and λₑ. The detector elements 340 in FIG. 13 are arranged along the y-axis, and the variable optical filter 346 may have an optical transmission profile that varies along the y-axis. For example, the portion of the variable optical filter 346v located above detector element 340a may have an AR coating configured to transmit light with an approximate wavelength λₐ. The portion of the variable optical filter 346v may provide a reflectivity of less than 2% at the wavelength λₐ, which corresponds to approximately 98% or greater of input beam 135a being transmitted through the filter 346v to detector 340a. Similarly, the portion of the variable optical filter 346v located above detector element 340b may have an AR coating that transmits light with an approximate wavelength kb (e.g., approximately 98% of input beam 135b may be transmitted through the filter 346v to the detector 340b). The transmission profile of the variable optical filter 346v may continue to change in this manner along the y-axis (e.g., the portion of the variable optical filter 346v located above detector element 340e may have an AR coating that transmits light with an approximate wavelength λₑ). As another example, the five input beams 135a through 135e may have respective wavelengths λₐ through λₑ of approximately 1542 nm, 1546 nm, 1550 nm, 1554 nm, and 1558 nm. Above detector element 340a, the variable optical filter 346v may have an optical transmission of greater than 96% at 1542 nm. Additionally, at this location, the transmission of the filter 346v at 1546-1558 nm may be less than 80% (e.g., the filter may have a reflectivity of greater than 80% at 1546-1558 nm). Similarly, above detector element 340b, the variable optical filter 346v may have an optical transmission of greater than 96% at 1546 nm, and at this location the transmission of the filter 346v at 1542 nm and 1550-1558 nm may be less than 80%. A variable optical filter 346v may provide for reduced optical cross-talk between detector elements 340 in a lidar system that operates with multiple different wavelengths.

While the optical filter 346 in FIG. 12 may provide a substantially uniform optical transmission profile across a detector array, the variable optical filter 346v in FIG. 13 provides a transmission profile that varies across a detector array. The optical transmission of a variable optical filter 346v may change with distance along a detector array 342 in any suitable manner, such as for example, in a stepwise, linear, quadratic, logarithmic, or exponential manner. For example, a variable optical filter 346v with a stepwise optical-transmission profile may have a substantially uniform transmission along a particular length of a detector array 342, and then the transmission may change, or step, to a different profile. A stepwise optical-transmission profile applied to the detector array 342 in FIG. 13 may provide a substantially uniform optical transmission of greater than 96% for wavelength λₐ in the vicinity of detector 340a. The optical-transmission profile may then change in the vicinity of detector 340b to provide a substantially uniform optical transmission of greater than 96% for wavelength kb. The transmission profile of the variable optical filter 346v may continue to change from one detector to the next in this stepwise manner along the y-axis. As another example, a variable optical filter 346v with a linear optical-transmission profile may have an optical transmission that varies approximately linearly with position y along the length of a detector array 342. For the detector array 342 in FIG. 13, a linear optical-transmission profile may be expressed as λ_{T} (y)=λₐ+[(λₑ−λₐ)/d]·y, where λ_{T} is the wavelength of maximum transmission (e.g., a wavelength at which the transmission is greater than or equal to 96%) as a function of the position y along the y-axis, and d is the distance between detectors 340a and 340e located at opposite ends of the array. In the vicinity of detector 340a (where y≅0), the variable optical filter 346v may have a wavelength of maximum transmission of approximately λₐ. The maximum-transmission wavelength may change linearly with position so that in the vicinity of detector 340e (where y≅d), the variable optical filter may have a wavelength of maximum transmission of approximately λe.

FIG. 14 illustrates an example receiver 140 that includes a one-dimensional detector array 342 and a multiplexer 344. The multiplexer 344, which may be referred to as a mux, is a N×n electronic multiplexer located between the detector array 342 and the electronic amplifier 350. The multiplexer 344 has N inputs and n outputs, where N is an integer equal to the number of detector elements 340 in the detector array 342, and n is an integer greater than or equal to 1. The number of multiplexer outputs n (which may equal the number of amplifier channels of the amplifier 350) may have any suitable value, such as for example, 1, 2, 4, 8, 16, 50, or 100. Additionally, the number of multiplexer outputs n may be less than the number of multiplexer inputs N. The detector array 342 in FIG. 14 includes N detector elements, and each detector element is coupled to an input of the multiplexer 344. The electronic amplifier 350 includes n amplifier channels (350-1, 350-2, . . . , 350-n), and each output of the multiplexer 344 is coupled to one of the amplifier channels. Each of the amplifier channels (350-1, 350-2, . . . , 350-n) may include a TIA 352 and one or more voltage amplifiers 354 (e.g., as illustrated in FIG. 8).

A N×n electronic multiplexer 344 may include an electronic switching device that couples a subset of its N inputs to the n outputs, where the number of inputs N is greater than the number of outputs n. For example, a 10×1 multiplexer 344 may have one output and may couple one of its 10 inputs to the one output. As another example, a 100×5 multiplexer may have five outputs and may couple five of its 100 inputs to the five outputs. Additionally, a multiplexer 344 may be reconfigurable to allow the particular inputs that are coupled to the outputs of the multiplexer to be changed dynamically. The multiplexer 344 in FIG. 14 may couple one or more photocurrent signals from one or more respective detector elements 340 to one or more respective inputs of the electronic amplifier 350. For example, a received pulse of light 410 may be incident on detector element 340b, and the multiplexer 344 may couple the photocurrent from detector 340b to an input of the amplifier 350. A subsequent pulse of light may be incident on detector element 340c, and the multiplexer 344 may be reconfigured to couple detector 340c to the amplifier 350. As another example, the multiplexer 344 in FIG. 14 may be a 100×4 multiplexer, and a received pulse of light 410 may be incident on up to four detector elements (e.g., detector elements 340a, 340b, 340c, 340d). The amplifier 350 may include four amplifier channels, and the multiplexer 344 may couple the four detector elements to the four respective amplifier channels (e.g., detector element 340a may be coupled to amplifier channel 350-1, and detector element 340b may be coupled to amplifier channel 350-2). A subsequent pulse of light may be incident on different detector elements (e.g., detector elements 340b, 340c, 340d, 340e), and the multiplexer 344 may be reconfigured to couple those detector elements to the amplifier 350 (e.g., detector element 340b may be coupled to amplifier channel 350-1, and detector element 350c may be coupled to amplifier channel 350-2).

A received pulse of light 410 may be incident on one detector element 340 of a detector array 342. Alternatively, a received pulse of light 410 may be incident on two or more detector elements 340 of a detector array 342. For example, a received pulse of light may be defocused or may have a beam profile that extends beyond a single detector element. Using a multiplexer 344 followed by an amplifier 350 with multiple amplifier channels may allow multiple detector signals to be sent in parallel to a pulse-detection circuit 365. For example, a received pulse of light 410 may be incident on four detector elements 340 of a detector array 342 so that each detector element receives a portion of the pulse of light. The four detector elements may be coupled to an amplifier 350 via a N×n multiplexer 344, where the multiplexer has four or more output channels (e.g., n is greater than or equal to 4), and the amplifier 350 has four or more amplifier channels. Each of the four detector elements may produce a photocurrent signal corresponding to the portion of the received pulse of light incident on that detector element, and each of the four photocurrent signals may be coupled to an amplifier channel of the amplifier 350 via the multiplexer 344.

As an output beam 125 with emitted pulses of light 400 is scanned across a field of regard of a lidar system 100, the corresponding input beam 135 with received pulses of light 410 may be incident on different detector elements 340 of a detector array 342. The particular detector elements 340 on which a received pulse of light 410 is incident may be correlated with a direction in which a corresponding emitted pulse of light 400 was directed or may be correlated with a wavelength of the corresponding emitted pulse of light 400. For example, for a pulse of light 400 that is emitted from a lidar system 100 in a particular direction, a corresponding received pulse of light 410 may be incident on one or more particular detector elements 340 of a detector array 342. A multiplexer 344 may be configured to direct the photocurrents from those particular detector elements to an amplifier 350. Additionally, as an output beam 125 is scanned across a field of regard, the corresponding input beam 135 may move across the detector elements of a detector array 342. The multiplexer 344 may be reconfigured in synch with the output beam 125 as the output beam is scanned. For example, the multiplexer 344 may be reconfigured to couple particular detector elements 340 to an amplifier 350 based on the direction of the output beam 125 at a particular time or based on the location of the input beam 135 on the detector array 342 at a particular time. As the output beam 125 is scanned to a different location, the multiplexer 344 may dynamically change the selected detector elements 340 accordingly based on the different direction of the output beam or based on the corresponding location of the input beam 135 on the detector array 342.

FIG. 15 illustrates an example detector array 342 that includes four one-dimensional detector arrays (342-1, 342-2, 342-3, 342-4). The detector array 342 in FIG. 15 may be referred to as a M×N two-dimensional detector array 342, where the parameter M equals 4. The 4×N two-dimensional detector array 342 includes four one-dimensional detector arrays (342-1, 342-2, 342-3, and 342-4), each one-dimensional detector array having N detector elements. A 1×N one-dimensional detector array 342 may be fabricated by starting with a M×N two-dimensional detector array 342, and the one-dimensional detector array with the lowest number of non-functioning detector elements may be selected. For example, the 4×N two-dimensional detector array 342 in FIG. 15 may be tested to determine the number of non-functioning detector elements 340 in each of the four one-dimensional detector arrays. Detector array 342-3 may have four non-functioning detector elements 340, while the other arrays may have five or more non-functioning detector elements. The 4×N two-dimensional detector array 342 may then be configured to operate as a one-dimensional detector array using detector array 342-3.

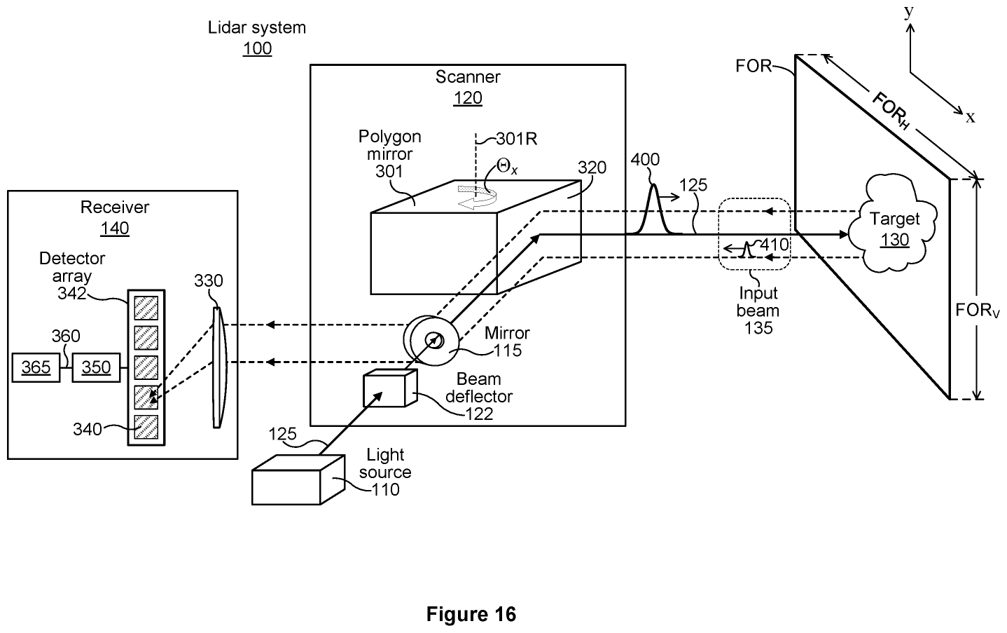

FIG. 16 illustrates an example lidar system 100 with a scanner 120 that includes a beam deflector 122. The lidar system 100 in FIG. 16 includes a light source 110 that emits an output beam 125 that includes a pulse of light 400 and a scanner 120 that scans the output beam across a field of regard (FOR) of the lidar system. The receiver 140 receives an input beam 135 that includes a received pulse of light 410, where the received pulse of light 410 may include a portion of the emitted pulse of light 400 scattered by a target 130. The receiver 140 includes a one-dimensional detector array 342, and the input beam 135 is focused onto one or more detector elements 340 of the detector array 342 by a focusing lens 330. One or more detector elements 340 of the detector array 342 may produce one or more respective photocurrent signals in response to the received pulse of light 410. The photocurrent signals may be sent to an electronic amplifier 350 which is coupled to a pulse-detection circuit 365. The receiver 140 may also include a multiplexer 344 (not shown in FIG. 16) located between the detector array 342 and the amplifier 350 (e.g., as illustrated in FIG. 14). The lidar system 100 in FIG. 16 may be referred to as a lidar system with a detector array 342.

A scanner 120 may include (i) a beam deflector 122 and (ii) a scan mirror. A scan mirror may refer to a device with a moveable mirror having one or more reflective surfaces 320 and configured to scan an output beam 125 within a field of regard. A scan mirror may include (i) a mirror with one reflective surface 320 that is rotated or pivoted to scan an output beam 125 or (ii) a polygon mirror 301 with multiple reflective surfaces 320 that is rotated to scan an output beam. For example, scan mirror 302 in FIG. 3 may be referred to as a scan mirror, and polygon mirror 301 in FIG. 3 or 16 may be referred to as a scan mirror or as a polygon scan mirror. The scanner 120 in FIG. 3 includes two scan mirrors: polygon mirror 301 and scan mirror 302. The scanner 120 in FIG. 16 includes a beam deflector 122 and one scan mirror (polygon mirror 301). In other embodiments, a scanner 120 may include a beam deflector 122 and a scan mirror with one reflective surface 320 that is rotated or pivoted to scan an output beam 125. For example, the scan mirror may include a galvanometer scanner or a MEMS device configured to cause a reflective surface 320 of the scan mirror to pivot back and forth over a particular angular range.

The scanner 120 in FIG. 16 includes a beam deflector 122, a mirror 115, and a polygon mirror 301. The output beam 125, which may include multiple pulses of light 400, is directed to the beam deflector 122, which may scan the output beam 125 along a first scan axis. The output beam 125 then travels through a hole in mirror 115, and the polygon scan mirror 301 may then scan the output beam 125 along a second scan axis different from the first scan axis. In FIG. 16, the first scan axis may correspond to a vertical direction (e.g., a y-direction), and the second scan axis may correspond to a horizontal direction (e.g., an x-direction). The polygon mirror 301 in FIG. 16 rotates in the Θₓ direction about the rotation axis 301R of the polygon mirror to scan the output beam 125 along the x-direction. The scanner 120 in FIG. 16 may scan the output beam 125 across all or a portion of the FOR. For example, the polygon mirror 301 may scan the output beam 125 along the x-axis across all or a portion of the horizontal FOR (FOR_{H}), and the beam deflector 122 may scan the output beam along the y-axis across all or a portion of the vertical FOR (FOR_{V}). The input beam 135, which may include multiple received pulses of light 410, is reflected by a reflective surface 320 of the polygon mirror 301 and is then directed by the mirror 115 to the receiver 140. The input beam 135 bypasses the beam deflector 122 (e.g., the input beam 135 exits the scanner 120 without encountering or being directed to the beam deflector) and is directed from the polygon mirror 301 to the receiver 140 by the mirror 115.

The mirror 115 in FIG. 16 may be referred to as a steering mirror, turning mirror, or pickoff mirror. A steering mirror 115 may be a fixed or non-moving mirror configured to reflect an input beam 135 (e.g., to direct or steer the input beam 135 to a receiver 140) or to reflect an output beam 125 (e.g., to direct or steer the output beam 125 to a scan mirror of a scanner 120). A lidar system 100 may include one or more steering mirrors 115, or a lidar system 100 may not include a steering mirror. The lidar system in FIG. 16 includes one steering mirror 115 located between the beam deflector 122 and the polygon mirror 301. The mirror 115 receives the input beam 135 from the polygon mirror 301 and reflects the input beam 135 so that the input beam bypasses the beam deflector and is directed to the receiver 140.

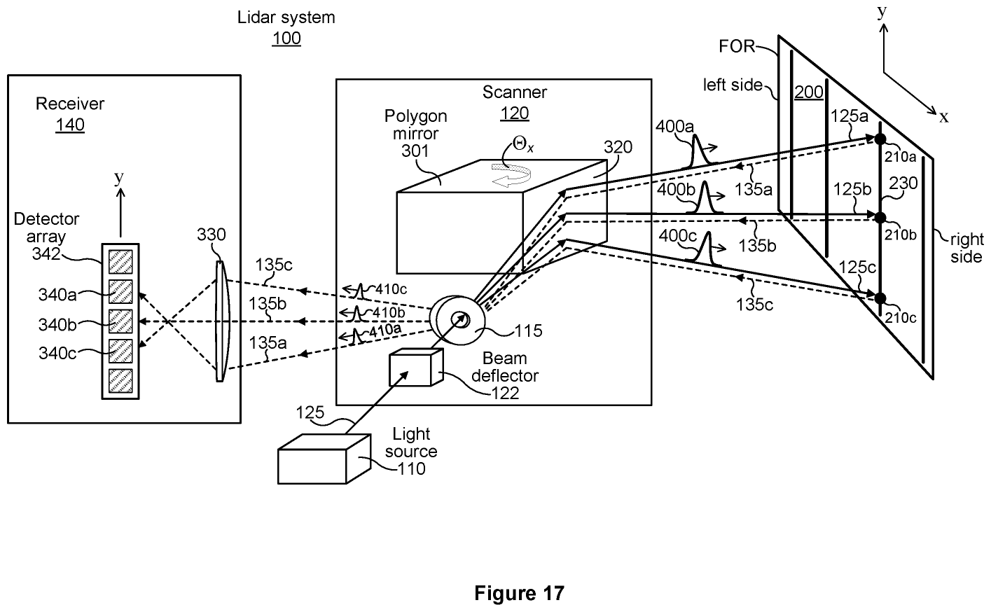

FIG. 17 illustrates the example lidar system 100 of FIG. 16 with the output beam 125 directed by a beam deflector 122 in three different directions. A scanner 120 may include (i) a beam deflector 122 that scans an output beam 125 along a first scan axis and (ii) a scan mirror that scans the output beam along a second scan axis different from the first scan axis. The first and second scan axes may each have any suitable orientation. For example, a beam deflector 122 may scan an output beam 125 along a first scan axis that is oriented approximately along a horizontal direction, vertical direction, or along any suitable angle with respect to a horizontal or vertical direction. As another example, the first scan axis may be directed at a particular angle with respect to a horizontal direction, and the second scan axis may be oriented at any suitable non-zero angle with respect to the first scan axis. As another example, the first scan axis may be orientated approximately along a horizontal direction, and the second scan axis may be oriented approximately along a vertical direction (or vice versa). As another example, the second scan axis may be approximately orthogonal to the first scan axis (e.g., the angle between the first and second scan axes may be approximately 90 degrees). As another example, a beam deflector 122 may scan an output beam 125 along a first scan axis to produce multiple scan lines 230, with each scan line oriented along the first scan axis, and a scan mirror may scan the output beam along a second scan axis to distribute the scan lines along the second scan axis. An output beam 125 may include multiple pulses of light 400, and each scan line 230 may include multiple pixels 210, each pixel associated with one of the pulses of light. A scan axis may be referred to as a scan direction.

In FIG. 17, the y-axis corresponds to the first scan axis, and the x-axis corresponds to the second scan axis. The beam deflector 122 scans the output beam 125 along the y-axis so that pulses of light 400 emitted by the light source 110 are directed along the y-axis. Additionally, the polygon scan mirror 301 rotates in the Θₓ direction to scan the output beam 125 along the x-axis so that the emitted pulses of light 400 are directed along the x-axis. The output beam 125 is scanned along the y-axis by the beam deflector 122 to produce a scan pattern 200 with four scan lines 230, each of which is oriented substantially along the y-axis, and the four scan lines are distributed along the x-axis by the rotation of the polygon mirror 301. The three output beams (125a, 125b, 125c) and the three corresponding input beams (135a, 135b, 135c) in FIG. 17 may correspond to the positions of the output beam 125 and the input beam 135 at three different instants of time. For example, the beam deflector 122 may scan the output beam 125 along scan line 230, and at a first instant of time, the light source 110 may emit pulse of light 400a directed along output beam 125a toward pixel 210a. The corresponding scattered light from pulse of light 400a may return along input beam 135a as received pulse of light 410a. Later, at a second instant of time, when the beam deflector 122 has scanned the output beam 125 to the position of output beam 125b, the light source 110 may emit pulse of light 400b directed along output beam 125b toward pixel 210b. The corresponding scattered light may return along input beam 135b as received pulse of light 410b. Later again, at a third instant of time, when the beam deflector 122 has scanned the output beam 125 to the position of output beam 125c, the light source 110 may emit pulse of light 400c directed along output beam 125c toward pixel 210c. The corresponding scattered light may return along input beam 135c as received pulse of light 410c. Each output beam and corresponding input beam may be at least partially overlapped or may share a common propagation axis. For clarity, in FIG. 17 each of the input beams 135a, 135b, and 135c is displaced with respect to each of the corresponding output beams 125a, 125b, and 125c.

The input beams of light 135a, 135b, and 135c (which correspond the direction of the input beam of light 135 at three different instants of time) are each reflected by reflective surface 320 of the polygon scan mirror 301 and then directed to the receiver 140 by the mirror 115. The input beams of light 135a, 135b, and 135c bypass the beam deflector 122, since the beams enter and exit the scanner 120 without encountering or being directed to the beam deflector. The input beams of light are directed to the detector array 342, which includes multiple detector elements 340 arranged along a direction corresponding to the axis along which the beam deflector 122 scans the output beam 125. In FIG. 17, the beam deflector 122 scans the output beam 125 along the y-axis, and the detector elements 340 are arranged along a direction corresponding to the y-axis. At any particular instant of time, the input beam 135 may be directed to a portion of the detector array 342 that corresponds to a direction along which the output beam 125 was directed by the beam deflector 122. For example, input beam 135a, which includes received pulse of light 410a and which corresponds to output beam 125a, is directed to detector element 340a. Additionally, input beam 135b, which includes received pulse of light 410b and which corresponds to output beam 125b, is directed to detector element 340b. Finally, input beam 135c, which includes received pulse of light 410c and which corresponds to output beam 125c, is directed to detector element 340c.

A polygon mirror 301 may include S reflective surfaces 320, where S is an integer greater than or equal to 2. As the polygon mirror 301 rotates, each reflective surface 320 may produce a single scan across a FOR of a lidar system 100, and the lidar system 100 may produce one point cloud corresponding to the single scan. A single scan across the FOR may correspond to one reflective surface 320 of the polygon mirror 301 scanning the output beam 125 (along with associated pulses of light 400) from one end of the FOR to an opposite end of the FOR (e.g., from a left side to a right side, or from an upper end to a lower end). For each full revolution of a polygon mirror 301 with S sides, a lidar system 100 may produce S corresponding point clouds, one for each reflective surface 320 of the polygon mirror. The polygon mirror 301 in FIG. 17 includes four reflective surfaces 320 (e.g., S=4). As one reflective surface 320 of the polygon mirror 301 scans the output beam 125 along the x-axis from the left side of the FOR to the right side (which corresponds to a single scan across the FOR), the beam deflector 122 scans the output beam 125 along the y-axis to produce four scan lines 230. The four scan lines 230, along with the associated emitted pulses of light 400 and pixels 210, may correspond to a single scan across the FOR and may correspond to one point cloud. For one full revolution of the polygon mirror 301, the lidar system 100 may produce four scans across the FOR and four corresponding point clouds, one for each of the four reflective surfaces 320. If a polygon mirror 301 is rotated at a rotation speed of R revolutions per second, a lidar system 100 may produce point clouds at a frame rate of F frames per second according to the expression F=S×R. Additionally, if a light source 110 emits pulses of light 400 at a pulse repetition frequency of PRF, the approximate number of pixels 210 in each point cloud (Pix) may be determined from the expression Pix=PRF/F. In the example of FIG. 17, if the four-sided polygon mirror 301 is rotated at 5 revolutions per second, then the lidar system 100 may produce point clouds at a 20-Hz frame rate. Additionally, if the light source 110 emits pulses of light with a PRF of 600 kHz, then each point cloud may include approximately 30,000 pixels.

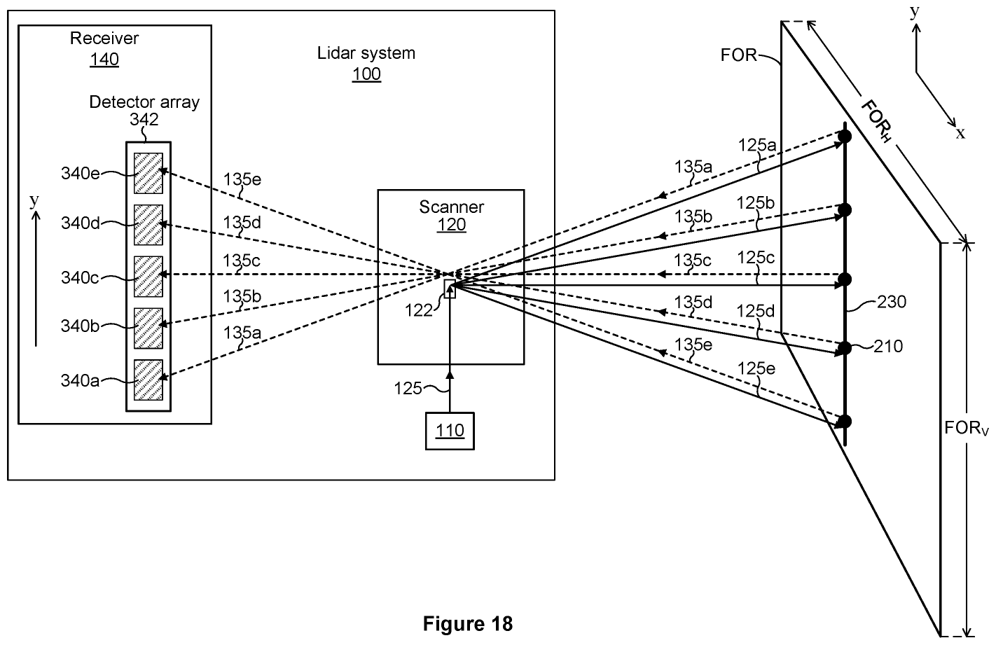

FIG. 18 illustrates an example lidar system 100 with the output beam 125 directed by a beam deflector 122 in five different directions. The scanner 120 includes a beam deflector 122 that scans the output beam 125 along the y-axis within the vertical field of regard (FOR_{V}). The scanner 120 may also include a scan mirror (not shown in FIG. 18) that scans the output beam 125 along the x-axis within the horizontal field of regard (FOR_{H}). The five output beams (125a, 125b, 125c, 125d, 125e) and the three corresponding input beams (135a, 135b, 135c, 135d, 135e) in FIG. 18 may correspond to the positions of the output beam 125 and the input beam 135 at five different instants of time. For example, the beam deflector 122 may begin the scan of scan line 230 with output beam 125a located near the top of the FOR and then may move in sequence, ending with output beam 125e located near the bottom of the FOR. The input beams 135a, 135b, 135c, 135d, and 135e travel through the scanner, bypassing the beam deflector 122, and are directed to the respective detector elements 340a, 340b, 340c, 340d, and 340e of the detector array 342.

Each output beam 125 in FIG. 18 is directed by the beam deflector 122 in a particular direction along the y-axis, and each input beam 135 returns back to the lidar system 100 along approximately the same direction or path as the corresponding output beam 125. Additionally, each input beam 135 is directed to a portion of the detector array 342 corresponding to the direction along the y-axis at which the output beam was directed by the beam deflector 122. For example, output beam 125a is directed along the y-axis to the upper part of the FOR, and the corresponding input beam 135a is directed to detector element 340a, which is located along the y-axis at the lower part of the detector array 342. For a pulse of light 400 emitted along output beam 125a, the corresponding received pulse of light 410 may be directed to detector element 340a. Output beam 125b is directed along the y-axis to the upper-middle part of the FOR, and the corresponding input beam 135b is directed to detector element 340b, which is located along the y-axis at the lower-middle part of the detector array 342. Output beam 125c is directed along the y-axis to the middle part of the FOR, and the corresponding input beam 135c is directed to detector element 340c, which is located along the y-axis near the middle of the detector array 342. Output beam 125d is directed along the y-axis to the lower-middle part of the FOR, and the corresponding input beam 135d is directed to detector element 340d, which is located along the y-axis at the upper-middle part of the FOR. Finally, output beam 125e is directed along the y-axis to the lower part of the FOR, and the corresponding input beam 135e is directed to detector element 340e, which is located along the y-axis at the upper part of the detector array 342.

A receiver 140 may include a lens 330 that focuses the input beam 135 onto a detector array 342 (e.g., as illustrated in FIG. 17), and the lens may cause the position of the input beams on the detector array 342 to be inverted with respect to FIG. 18. For example, with a focusing lens 330 added to the receiver 140 in FIG. 18, input beam 135a may be directed to detector element 340e, and input beam 135e may be directed to detector element 340a. In either case, with or without a focusing lens, the detector elements 340 of a detector array 342 may be arranged along a direction that corresponds to the axis along which the beam deflector 122 scans the output beam 125. In each of FIGS. 17 and 18, the beam deflector 122 scans the output beam 125 along the y-axis, and the detector elements 340 are arranged along a direction corresponding to the y-axis. Additionally, each input beam 135 is directed to a portion of the detector array 342 that corresponds to the direction along the y-axis at which the corresponding output beam 125 was directed. The y-axis along which the beam deflector 122 scans the output beam 125 is effectively mapped to the detector array 342 so that a received pulse of light 410 is directed to a portion of the detector array that corresponds to the direction along the y-axis that a corresponding emitted pulse of light 400 was directed by the beam deflector. Moreover, each detector element 340 of the detector array 342 may be configured to detect received pulses of light 410 originating from a particular direction or location with respect to the y-axis. For example, in FIG. 18, detector element 340e may be configured to detect received pulses of light 410 originating from the lower part of the FOR. Additionally, detector element 340c may detect received pulses of light 410 originating from the middle part of the FOR, and detector element 340a may detect received pulses of light originating from the upper part of the FOR. As another example, the vertical FOR (FOR_{V}) may have a total angular extent of 10°, extending along the y-axis from −5° to +5°, and the FOR_{V} may be mapped to the detector array 342 so that each detector element 340 is configured to detect light originating from a particular angular portion of the FOR_{V}. Detector element 340a may detect received pulses of light 410 originating from +3° to +5° of the FOR_{V}; detector element 340b may detect received pulses of light 410 originating from +1° to +3° of the FOR_{V}; detector element 340c may detect received pulses of light 410 originating from −1° to +1° of the FOR_{V}; detector element 340d may detect received pulses of light 410 originating from −3° to −1° of the FOR_{V}; and detector element 340e may detect received pulses of light 410 originating from −5° to −3° of the FOR_{V}.

An input beam 135 may be incident on one or more detector elements 340 of a detector array 342. In FIGS. 16-18, each input beam 135 is directed to one detector element 340. For example, in FIG. 18, input beam 135a is directed to detector element 340a. In other embodiments, an input beam 135 may be incident on two or more detector elements 340 of a detector array 342. For example, in FIG. 18, a received pulse of light 410 that is part of input beam 135a may be incident on detector elements 340a and 340b, and each detector element may produce a photocurrent signal corresponding the portion of the pulse of light that was received by the detector element.

A lidar system 100 may be configured to scan an output beam 125 to any suitable number of directions or locations along a scan line 230. For example, a beam deflector 122 may direct an output beam 125 to approximately 2, 4, 10, 20, 50, 100, or 500 positions along a scan line 230, and a light source 110 may emit one or more pulses of light 400 at each of the one or more positions along the scan line. Additionally, a lidar system 100 may include a detector array 342 with any suitable number of detector elements 340, such as for example, approximately, 2, 4, 10, 20, 50, 100, or 500 detector elements 340. The number of detector elements 340 may be greater than, less than, or approximately equal to the number of positions along a scan line 230 that a beam deflector 122 directs an output beam 125. In the example of FIG. 18, the output beam 125 is scanned to five positions along a scan line 230, and the detector array 342 includes five detector elements 340. As another example, a beam deflector 122 may direct an output beam 125 to approximately 100 positions along a first scan axis, and a light source 110 may emit approximately 100 pulses of light 400 while the output beam is scanned along the first scan axis. Additionally, a detector array 342 may include approximately 50, 100, or 150 detector elements 340 configured to detect scattered pulses of light 410 from the approximately 100 emitted pulses of light 400. A beam deflector 122 may scan the output beam 125 along the first scan axis in discrete steps, stopping at each of the scan positions while a pulse of light 400 is emitted. Alternatively, a beam deflector 122 may scan the output beam 125 approximately continuously along the first scan axis without stopping, and pulses of light 400 may be emitted as the output beam 125 is scanned.

A receiver 140 that includes a 1×N detector array 342 may also include an electronic amplifier 350 with N amplifier channels. Each detector 340 may be coupled to one of the amplifier channels, and each amplifier channel may include a TIA 352 and one or more voltage amplifiers 354. The detector array 342 in FIG. 18 is a 1×5 one-dimensional array that includes five detector elements 340 arranged in a line along the y-axis. The receiver 140 in FIG. 18 may include an electronic amplifier 350 (not shown in FIG. 18) with five amplifier channels, and each detector element 340 may be coupled to one of the amplifier channels. Alternatively, a receiver 140 that includes a 1×N detector array 342 may also include a N×n electronic multiplexer 344 located between the detector array 342 and the electronic amplifier 350. The receiver 140 in FIG. 18 may include a 5×n electronic multiplexer 344 (not shown in FIG. 18) located between the detector array 342 and the electronic amplifier 350, where n is greater than or equal to 1 and less than 5. For example, the receiver 140 may include a 5×3 electronic multiplexer 344, and the electronic amplifier 350 may include three amplifier channels. The multiplexer 344 may be dynamically reconfigured as the output beam 125 is scanned along the y-axis. For example, when the output beam 125c is directed along the y-axis to the middle part of the FOR, the multiplexer 344 may be configured so that detector elements 340b, 340c, and 340d (which are located near the expected position of input beam 135c) are coupled to the amplifier channels. Then, when the output beam 125d is directed along the y-axis to the lower-middle part of the FOR, the multiplexer 344 may be reconfigured so that detector elements 340c, 340d, and 340e (which are located near the expected position of input beam 135d) are coupled to the amplifier channels.

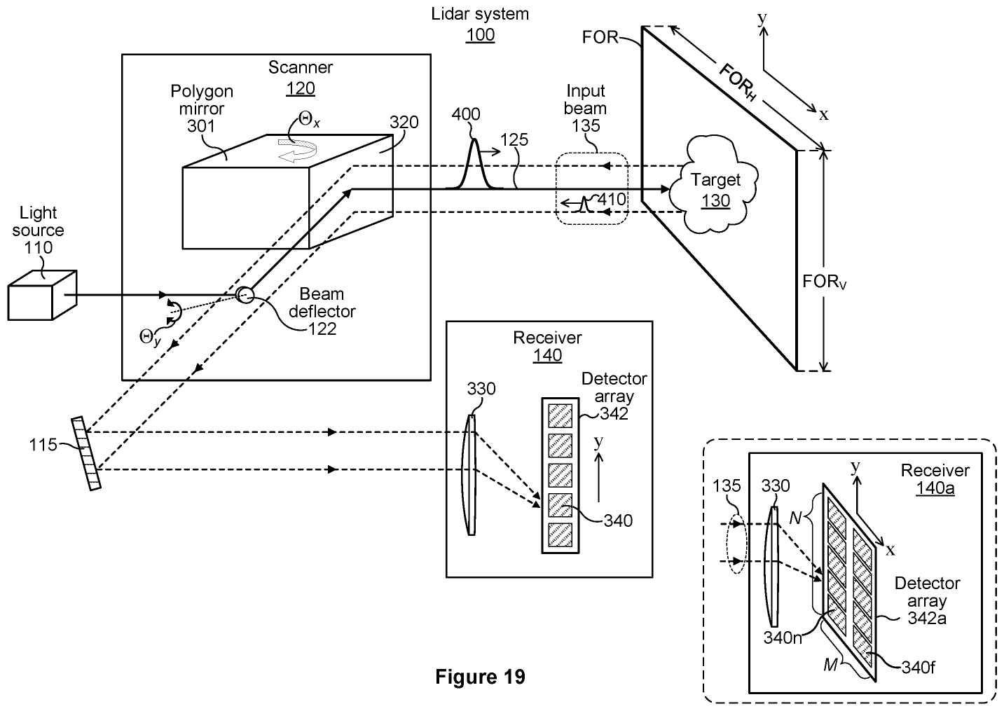

FIG. 19 illustrates an example lidar system 100 with a scanner 120 that includes a reflective beam deflector 122. The lidar system 100 in FIG. 19 includes a light source 110 that emits an output beam 125 that includes a pulse of light 400 and a scanner 120 that scans the output beam across a field of regard (FOR) of the lidar system. The receiver 140 receives an input beam 135 that includes a received pulse of light 410, where the received pulse of light 410 may include a portion of the emitted pulse of light 400 scattered by a target 130. The receiver 140 includes a one-dimensional detector array 342, and the input beam 135 is focused onto one or more detector elements 340 of the detector array 342 by a focusing lens 330. The lidar system 100 in FIG. 19 is similar to the lidar system 100 in FIGS. 16-17, except the scanner 120 in FIG. 19 includes a reflective beam deflector 122. Additionally, the scanner 120 in FIG. 19 does not include a steering mirror.

A reflective beam deflector 122 may refer to a beam deflector that includes one or more reflective surfaces 320 or one or more reflection diffraction gratings. A reflective beam deflector 122 may scan an output beam 125 by pivoting, rotating, or oscillating one or more reflective surfaces. For example, the reflective beam deflector 122 in FIG. 19 may include a MEMS device with a reflective surface 320, a polygon mirror with multiple reflective surfaces 320, or a resonant-mirror scanner. The beam deflector 122 may pivot, rotate, or oscillate in the Θ_{y} direction to scan the output beam 125 along the y-direction. A resonant-mirror scanner may include a reflective surface 320 coupled to a spring mechanism that is driven by an actuator to produce a periodic mechanical oscillation at a substantially fixed resonant frequency (e.g., 1 kHz). In other embodiments, a reflective beam deflector 122 may include a liquid-crystal beam deflector configured to act as a reflective diffraction device that diffracts the output beam 125 at an adjustable angle.

The beam deflector 122 in FIGS. 16-17 may be referred to as a transmissive beam deflector 122 in which the output beam 125 is transmitted through at least a portion of the beam deflector. A transmissive beam deflector 122 may include an electro-optic device, an acousto-optic device, a liquid-crystal device, a vibrating optical fiber, or an optical phased array. For example, a transmissive beam deflector 122 may include an electro-optic beam deflector in which the electro-optic effect is used to change the refractive index of an optically transmissive material (e.g., lithium niobate, potassium titanate, or strontium barium niobate). The electro-optic beam deflector may provide an angular deflection of a transmitted output beam 125 that is adjusted by changing the amplitude of a voltage applied to the deflector. As another example, a transmissive beam deflector 122 may include an acousto-optic deflector or scanner in which a transmitted output beam 125 is angularly deflected or diffracted by a diffraction grating provided by an acoustic signal applied to an optically transmissive material. As another example, a transmissive beam deflector 122 may include a liquid-crystal beam deflector in which a transmitted output beam 125 is angularly deflected or diffracted by an adjustable transmission diffraction grating produced by the liquid-crystal device. A liquid-crystal device may be configured as a transmissive beam deflector or as a reflective beam deflector. As another example, a transmissive beam deflector 122 may include a vibrating optical fiber in which the output beam 125 is transmitted through an optical fiber with a mechanically vibrating output end that causes the output beam to be angularly deflected. As another example, a transmissive beam deflector 122 may include optical phased array scanning device that uses an optical phased array to impart an angular deflection to the output beam 125.

The dashed-line inset in FIG. 19 illustrates an example receiver 140a with a two-dimensional detector array 342a. The receiver 140a in FIG. 19 may be used in a lidar system 100 as an alternative to a receiver 140 with a one-dimensional detector array 342. For example, a receiver 140a with a two-dimensional detector array 342a may be part of any of the lidar systems 100 of FIGS. 16-19 in which an input beam 135 bypasses the beam deflector 122. The detector array 342a in FIG. 19 is a 2×5 two-dimensional array of detector elements 340. A two-dimensional detector array 342a may have any suitable M×N (column×row) arrangement of detector elements 340, such as for example, a 2×50 array, a 3×100 array, or a 4×200 array. A two-dimensional detector array 342a may have less than 10 columns (M<10) and greater than 25 rows (N>25). The two-dimensional detector array 342a in FIG. 19 includes detector elements 340 arranged in five rows (N=5) along a direction corresponding to the y-axis and arranged in two columns (M=2) along a direction corresponding to the x-axis. Each row of detector elements 340 arranged along the y-axis may be configured to detect received pulses of light 410 originating from a particular direction or location with respect to the y-axis. Additionally, each column of detector elements 340 may be configured to detect received pulses of light 410 originating from a particular distance from the lidar system. For example, detector element 340n, which is part of the first column of detector elements, may be configured to primarily detect received pulses of light 410 from relatively near targets 130 (e.g., targets within 100 m of the lidar system), and detector element 340f, which is part of the second column, may be configured to primarily detect received pulses of light 410 from relatively far targets (e.g., targets located greater than 100 m from the lidar system). The two-dimensional detector array 342a in FIG. 19 may be considered to include two adjacent one-dimensional detector arrays corresponding to the two columns of detector elements. The one-dimensional detector array with detector element 340n may be referred to as a near-target detector array configured to detect received pulses of light 410 scattered from relatively near targets 130, and the one-dimensional detector array with detector element 340f may be referred to as a far-target detector array configured to detect received pulses of light scattered from relatively far targets. As another example, for a 3×100 detector array 342 with three columns: the first column of detector elements 340 may primarily detect nearby targets 130 (e.g., targets located within 50 m of a lidar system); the second column (located between the first and third columns) may primarily detect midrange targets (e.g., targets located between 50 m and 150 m from a lidar system); and the third column (adjacent to the second column) may primarily detect relatively far targets (e.g., targets located greater than 150 m from the lidar system). Similarly, a 4×N detector array 342 with four columns may be considered to include four adjacent one-dimensional detector arrays corresponding to the four columns of detector elements, and the four respective detector arrays may be referred to as a near-target detector array, a near midrange-target detector array, a far midrange-target detector array, and a far-target detector array.

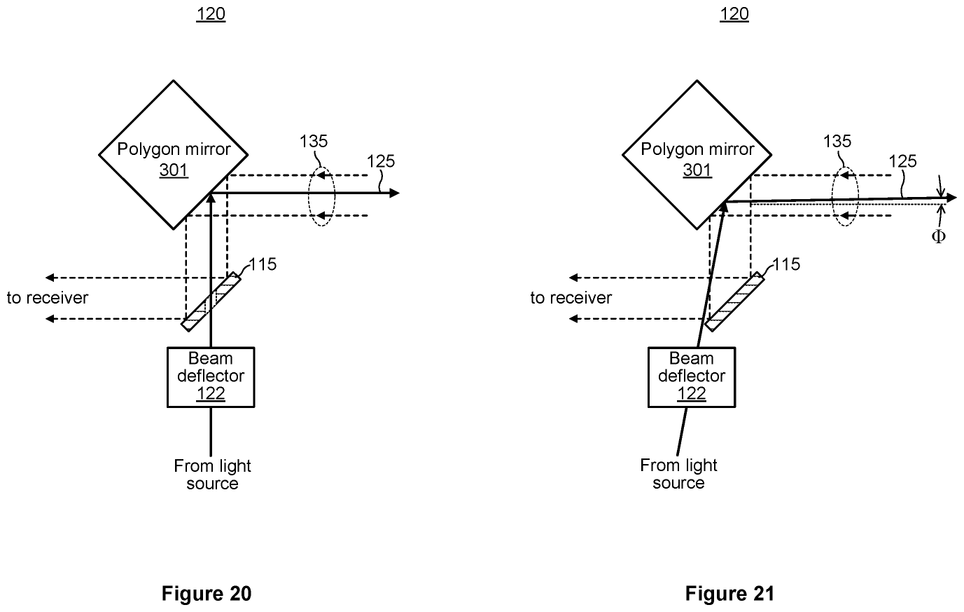

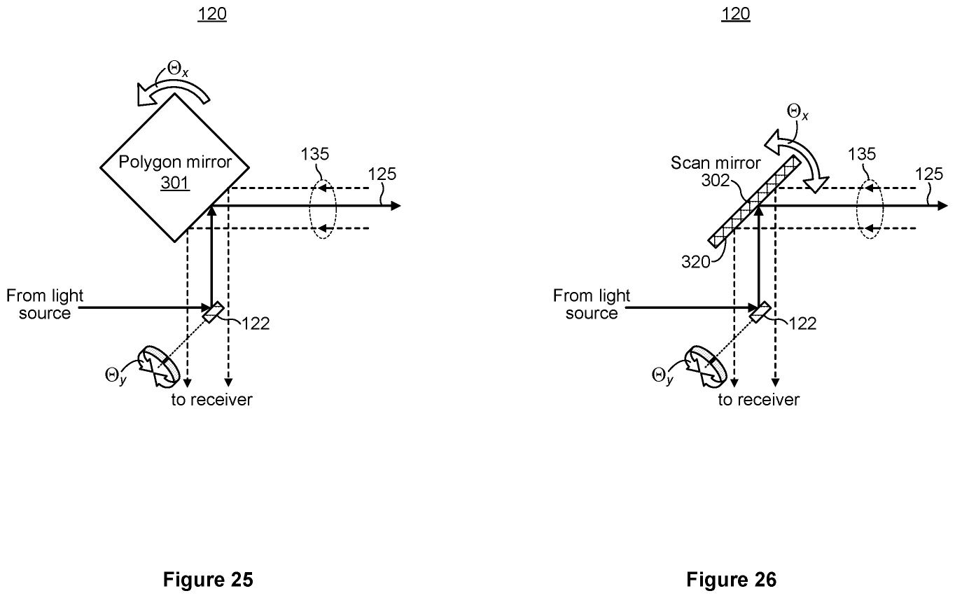

FIGS. 20-27 each illustrate an example scanner 120 that includes a beam deflector 122. Each of the scanners 120 in FIGS. 20-27 includes a beam deflector 122 and a scan mirror (e.g., polygon scan mirror 301 or scan mirror 302). In each of FIGS. 20-27, a beam deflector scans an output beam 125 along a first scan axis, and the output beam 125 (which includes multiple pulses of light 400) is then reflected from a scan mirror, which scans the output beam along a second scan axis. Additionally, an input beam 135 is reflected from the scan mirror and then may bypass the beam deflector 122. The beam deflectors 122 in FIGS. 20-24 are configured as transmissive beam deflectors, and the beam deflectors 122 in FIGS. 25-27 are configured as reflective beam deflectors. In other embodiments, one or more beam deflectors 122 in FIGS. 20-24 may be configured as reflective beam deflectors, and one or more beam deflectors 122 in FIGS. 25-27 may be configured as transmissive beam deflectors. The scanners 120 in FIGS. 20-23 include a steering mirror 115 configured to reflect either the output beam 125 or the input beam 135, and the scanners 120 in FIGS. 24-27 do not include a steering mirror. Each of FIGS. 20-27 illustrates an example scanner 120 that may be included in a lidar system with a detector array.

The scanner 120 in FIG. 20 includes a beam deflector 122, a polygon scan mirror 301, and a steering mirror 115. The steering mirror 115, which is located between the beam deflector 122 and the polygon mirror 301, reflects the input beam 135 to bypass the beam deflector and direct the input beam to a receiver 140. The output beam 125 passes through the beam deflector 122 and then travels through the steering mirror 115. The steering mirror 115 may include a hole in the mirror or a slot located near an edge of the mirror, and the output beam 125 may travel through the hole or slot. The scanner 120 in FIG. 20 is similar to the scanner 120 in FIGS. 16-17.

The scanner 120 in FIG. 21 includes a beam deflector 122, a polygon scan mirror 301, and a steering mirror 115. The input beam 135 is reflected by the steering mirror 115 and directed to a receiver 140. The steering mirror 115 does not include a hole, slot, or aperture for the output beam 125 to travel through. Instead of traveling through the mirror, the output beam 125 passes alongside the mirror 115 with a gap between the output beam and an edge of the mirror. The input beam 135 and output beam 125 may travel along approximately the same optical path (in opposite directions) with some angular offset Φ between the two beams. For example, the input beam 135 and output beam 125 may have an angular offset Φ between the beams that is less than or equal to approximately 50 mrad, 20 mrad, 10 mrad, 2 mrad, or 1 mrad.

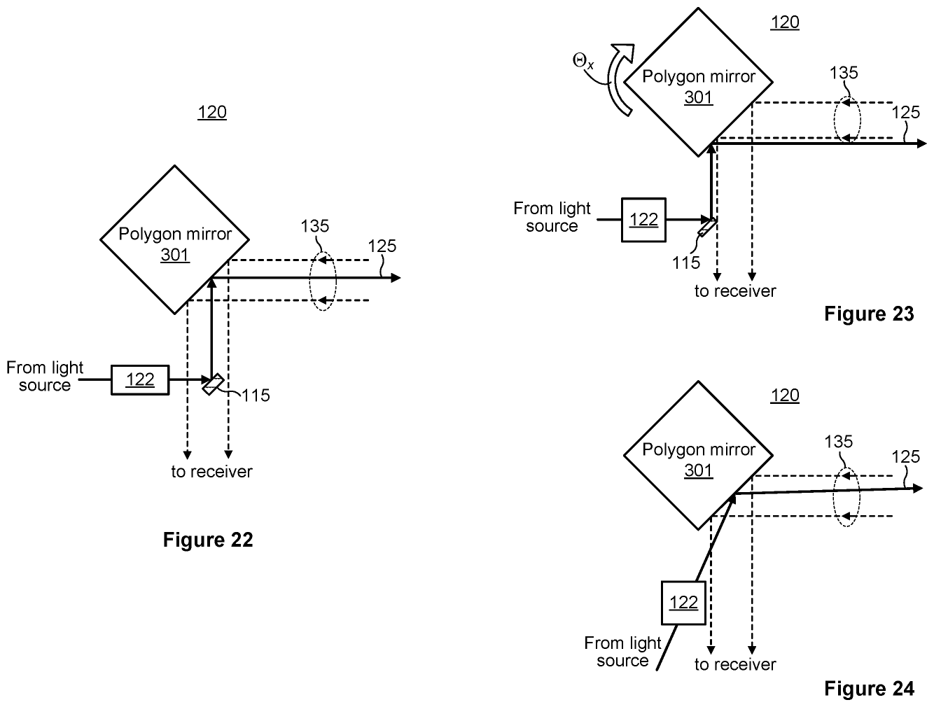

The scanner 120 in FIG. 22 includes a beam deflector 122, a polygon scan mirror 301, and a steering mirror 115. After traveling through the beam deflector 122, the output beam 125 is reflected by the steering mirror 115 and directed to the polygon mirror 301. The input beam 135 is reflected by the polygon mirror 301 and directed to a receiver. The mirror 115 may be located at least partially in the path of the input beam 135 and may block a portion of the input beam from reaching the receiver. The mirror 115 may have a diameter or size that is relatively small compared to the diameter of input beam 135. As a result, most of the input beam may travel by the mirror 115 to the receiver 140, with only a small portion of the input beam being blocked by the mirror 115. For example, with a 2-mm steering-mirror diameter and a 10-mm input-beam diameter, less than approximately 4% of the input beam 135 may be blocked by the steering mirror 115. Since a relatively small portion of the input beam 135 may be blocked by the beam deflector 122, the input beam 135 may be referred to as bypassing the beam deflector.

The scanner 120 in FIG. 23 includes a beam deflector 122, a polygon scan mirror 301, and a steering mirror 115. After traveling through the beam deflector 122, the output beam 125 is reflected by the steering mirror 115 and directed to the polygon mirror 301. The scanner 120 in FIG. 23 is similar to that in FIG. 22, except in FIG. 23 the mirror 115 is positioned so that the input beam 135 travels alongside the mirror 115. Since the mirror 115 is not located in the path of the input beam 135, the mirror 115 may not block any significant portion of the input beam from reaching the receiver. For example, less than 1% of the input beam 135 may be blocked by the steering mirror 115.

The scanner 120 in FIG. 24 includes a beam deflector 122 and a polygon scan mirror 301. The scanner 120 does not include a steering mirror 115, and after traveling through the beam deflector 122, the output beam 125 travels directly to the polygon mirror 301. The beam deflector 122 is positioned so that the input beam 135 bypasses the beam deflector by traveling alongside the beam deflector.

The scanner 120 in FIG. 25 includes a beam deflector 122 and a polygon scan mirror 301. The beam deflector 122 may pivot along the Θ_{y} direction to scan the output beam 125 along a y-axis, and the polygon mirror 301 may rotate along the Θₓ direction to scan the output beam 125 along an x-axis. The scanner 120 does not include a steering mirror 115, and after interacting with the beam deflector 122, the output beam 125 travels directly to the polygon mirror 301. The beam deflector 122 may be located at least partially in the beam path of the input beam 135 and may block a portion of the input beam from reaching the receiver. The beam deflector 122 may have a diameter or size that is relatively small compared to the diameter of the input beam 135. As a result, most of the input beam 135 may travel by the beam deflector 122, with only a small portion (e.g., less than 4%) of the input beam being blocked by the beam deflector. The scanner 120 in FIG. 25 is similar to the scanner 120 in FIG. 19.

The scanner 120 in FIG. 26 includes a beam deflector 122 and a scan mirror 302. The scan mirror 302 may include one reflective surface 320, and the scan mirror 302 may pivot back and forth along the Θₓ direction to scan the output beam 125 along an x-axis. The scanner 120 in FIG. 26 is similar to that in FIG. 25, except in FIG. 26 the scan mirror 302 includes a mirror with one reflective surface 320 that is pivoted back and forth to scan the output beam 125.

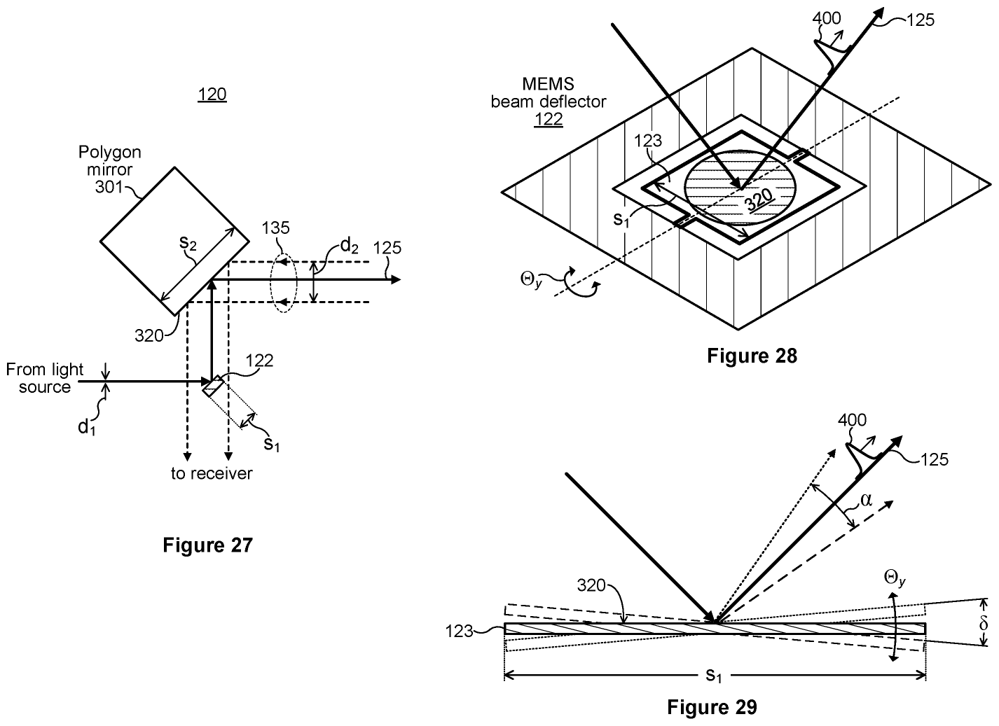

The scanner 120 in FIG. 27, which is similar to the scanner 120 in FIG. 25, includes the four dimensions d₁, d₂, s₁, and s₂. The output beam of light 125 has a beam diameter of d₁, and the input beam of light 135 has a beam diameter of d₂, where d₂ is greater than d₁. The aperture of the beam deflector 122 has a dimension (e.g., a length or diameter) of s₁, and the aperture of the polygon scan mirror 301 has a dimension (e.g., a length or diameter) of s₂, where s₂ is greater than s₁. The aperture of the beam deflector 122 may refer to an opening that the output beam 125 travels through or a surface that the output beam 125 is reflected or diffracted from. The scan-mirror aperture may refer to a reflective surface 320 of a scan mirror that the output beam 125 is reflected from. The dimension s₂ of the scan mirror may be greater than or equal to the beam diameter d₂ of the input beam 135, which may provide for the scan mirror to reflect all or most of the input beam without significant optical loss due to a size mismatch. The dimension s₁ of the beam deflector 122 may be greater than or equal to the beam diameter d₁ of the output beam 125, which may provide for the beam deflector to transmit or reflect all or most of the output beam without significant optical loss due to a size mismatch. The dimension s₁ of the beam deflector 122 may be less than the beam diameter d₂ of the input beam 135. Since the input beam 135 bypasses the beam deflector 122, the beam deflector does not need to accommodate the input beam, and the diameter d₂ of the input beam may be larger than the dimension s₁ of the beam deflector. The relationships between the dimensions in FIG. 27 may be expressed as s₂≥d₂>s₁≥d₁. For example, an output beam 125 may have a beam diameter d₁ of 1 mm, and an input beam 135 may have a beam diameter d₂ of 10 mm. Additionally, a beam deflector 122 may have a dimension s₁ of approximately 2 mm, and a polygon scan mirror 301 may have a dimension s₂ of approximately 15 mm. As another example, a beam deflector 122 may have a dimension s₁ that is approximately 1 to 4 times larger than the output-beam diameter d₁. As another example, a scan-mirror dimension s₂ or an input-beam diameter d₂ may be approximately 2 to 20 times larger than a beam-deflector dimension s₁.

FIGS. 28-29 each illustrate an example MEMS beam deflector 122. A microelectromechanical systems (MEMS) beam deflector 122 may include a MEMS device with a pivoting portion 123 that includes a reflective surface 320. FIG. 28 illustrates a perspective view of a MEMS beam deflector 122, and FIG. 29 illustrates a side view of the pivoting-mirror portion 123 of the MEMS beam deflector. The MEMS beam deflector 122 in FIGS. 28-29, which may be referred to as a reflective MEMS beam deflector, includes a pivoting portion 123 with a reflective surface 320 that reflects the output beam 125. The pivoting portion 123 is configured to pivot back and forth along the Θ_{y} direction to scan the emitted pulses of light 400 of the output beam 125 along a y-axis. The pivoting portion 123 pivots over an angular range δ, which results in the output beam 125 scanning over an angular range of α, where α is approximately equal to 2×6. The angular pivoting range δ of a MEMS beam deflector 122 may be approximately 1°, 2°, 5°, 10°, or any other suitable angular range. For example, the pivoting portion 123 of a MEMS beam deflector 122 may have an angular pivoting range δ of 4°, and the output beam 125 may be scanned along the y-axis over an angular range α of 8°. A scanner 120 may include a beam deflector 122 that is a MEMS beam deflector. For example, the beam deflector 122 in one or more of the scanners 120 in FIGS. 16-27 may be a MEMS beam deflector.

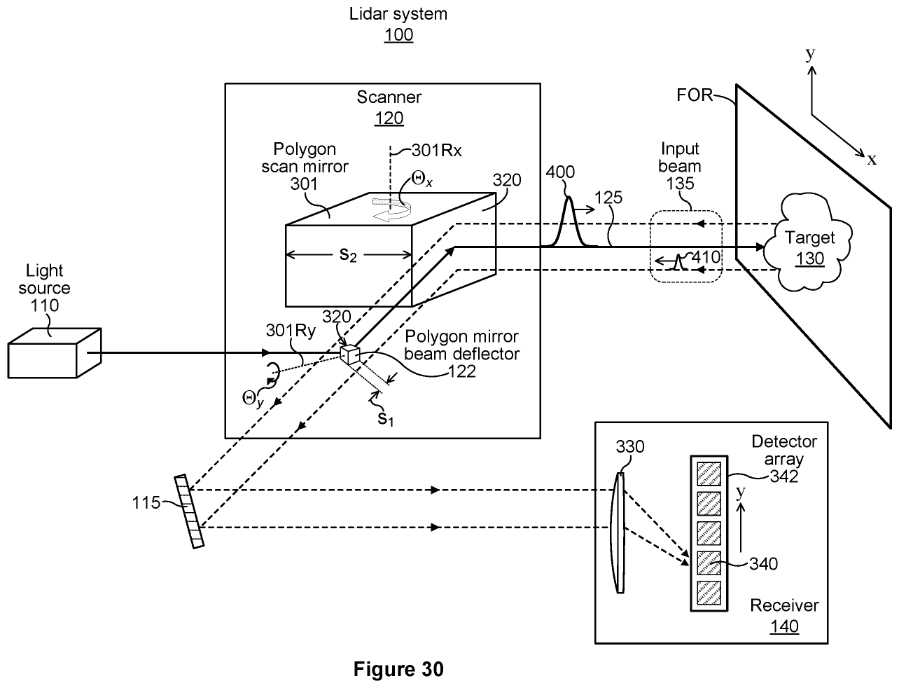

FIG. 30 illustrates an example lidar system 100 with a scanner 120 that includes a polygon mirror beam deflector 122. The beam deflector 122 in FIG. 30 includes a polygon mirror with four reflective surfaces 320 angularly offset from one another along the periphery of the polygon mirror. As the polygon mirror rotates, each reflective surface 320 reflects in sequence the output beam 125 to the polygon scan mirror 301. The polygon mirror beam deflector 122 rotates in the Θ_{y} direction about the rotation axis 301Ry to scan the output beam 125 along the y-axis, and the polygon scan mirror 301 rotates in the Θₓ direction about the rotation axis 301Rx to scan the output beam 125 along the x-axis. The lidar system 100 in FIG. 30 is similar to the lidar system 100 in FIG. 19. In FIG. 30, the polygon mirror beam deflector 122 and the polygon scan mirror 301 are similar, except the dimension s₂ of the polygon scan mirror 301 is larger than the dimension s₁ of the polygon mirror beam deflector 122. For example, the polygon scan-mirror dimension s₂ may be 2 to 20 times larger than the beam-deflector dimension s₁. As another example, the polygon scan-mirror dimension s₂ may be between approximately 10 mm and 40 mm, and the beam-deflector dimension s₁ may be between approximately 1 mm and 5 mm. The beam deflector 122 in one or more of the scanners 120 in FIGS. 16-27 may be a polygon mirror beam deflector 122.

In a scanner 120 that includes a beam deflector 122 and a scan mirror (e.g., polygon scan mirror 301 or scan mirror 302), the scanning speed of the beam deflector may be greater than the scanning speed of the scan mirror. For example, the beam-deflector scanning speed may be greater than or equal to four times the scan-mirror scanning speed. As another example, the beam-deflector scanning speed may be between four times and 400 times faster than the scan-mirror scanning speed. The scanning speed of a beam deflector or scan mirror may refer to a rotation speed, a pivot rate, or a beam-scanning speed. For example, the scanning speed of a polygon scan mirror 301 or a polygon mirror beam deflector 122 may be expressed as a rotation speed with units of revolutions per second (or, Hz) or degrees per second. As another example, the scanning speed of a scan mirror 302 or a MEMS beam deflector 122 may be expressed as a pivot rate with units of degrees per second, which may correspond to an average or peak angular speed at which the mirror 302 or the pivoting portion 123 is pivoted. As another example, the scanning speed of a beam deflector or scan mirror may be expressed as an angular beam-scanning speed with units of degrees per second, which may correspond to an average or peak angular speed at which the output beam 125 is scanned. In FIG. 30, the scanning speed of the polygon mirror beam deflector 122 may be greater than the scanning speed of the polygon scan mirror 301. For example, the polygon mirror beam deflector 122 may have a rotation speed that is approximately 4 to 400 times faster than the polygon scan mirror 301 rotation speed. As another example, the polygon mirror beam deflector 122 may have a rotation speed of approximately 200 Hz (or, 200 revolutions per second), and the polygon scan mirror 301 may have a rotation speed of approximately 5 Hz. In this case, the scanning speed of the beam deflector 122 is 40 times faster than the scanning speed of the scan mirror 301. Accordingly, over a 50-ms time period when the scan mirror 301 provides a single scan across the FOR, the beam deflector 122 may produce a scan pattern with 40 scan lines. For comparison, the scan pattern 200 in FIG. 17 includes four scan lines 230, which may correspond to the scanning speed of the beam deflector 122 being approximately four times faster than the scanning speed of the polygon mirror 301.

FIG. 31 illustrates an example lidar system 100 with a receiver 140 that includes a two-dimensional detector array 342. The output beam 125 in FIG. 31 is directed to the scanner 120, and the scanner scans the output beam across the field of regard (FOR). The scanner 120 may include a beam deflector 122 that scans the output beam 125 along the y-axis and a scan mirror (e.g., polygon scan mirror 301 or scan mirror 302) that scans the output beam along the x-axis. The input beam 135 bypasses the scanner 120 and is directed to the receiver 140 without passing through the scanner. A received pulse of light 410 may be incident on one or more detector elements 340 of the two-dimensional detector array 342, and each detector element may produce a photocurrent signal corresponding to the portion of the received pulse of light 410 that was detected. The dashed-line inset in FIG. 31 illustrates a top-view of the two-dimensional detector array 342, which includes 64 detectors 340 arranged in an 8×8 two-dimensional array. The input beam 135 is incident on four detector elements 340, and each of the four detector elements may produce a photocurrent signal corresponding to the received pulse of light 410.

A receiver 140 may include a two-dimensional detector array 342 with a M×N two-dimensional arrangement of detector elements 340, where M and N are each integers greater than or equal to 2. The detector elements 340 may be arranged in N rows along one direction corresponding to the y-axis and in M columns along another direction corresponding to the x-axis. Each detector element 340 of a two-dimensional detector array 342 may be configured to detect received pulses of light 410 originating from a particular portion of the FOR. For example, in FIG. 31, the target 130 from which the pulse of light 400 scatters is located approximately in the center of the FOR, and the corresponding input beam 135 is incident on approximately the center of the detector array 342. As another example, a subsequent pulse of light directed to target 130a in the lower-right portion of the FOR may produce a received pulse of light that is part of input beam 135a, which is incident on the lower-right portion of the detector array 342. As another example, detector 340 located in the upper-left portion of the detector array 342 may receive scattered pulses of light 410 originating from the upper-left portion of the FOR.

FIG. 32 illustrates an example lidar system 100 that scans a field of regard that includes four regions (240A, 240B, 240C, 240D). A single scan of the FOR may include one or more scans across each of the four regions (240A, 240B, 240C, and 240D), and the lidar system 100 may produce one point cloud corresponding to the single scan. For example, the lidar system 100 in FIG. 32 may scan an output beam 125 across each of the four regions once to produce a single scan of the FOR. The lidar system 100 may scan the four regions in any suitable sequence, such as for example: in the sequence 240A, 240B, 240C, 240D; or in the sequence 240B, 240D, 240A, 240C. The vertical FOR (FOR_{V}) may have an angular extent of approximately 2°, 5°, 10°, 15°, 20°, 30°, 45°, or any other suitable angular extent. Each region of the FOR has an angular range α along the y-axis, where a may be approximately 1°, 2°, 5°, 10°, 20°, or any other suitable angular range. For example, the FOR_{V} may have an angular extent of approximately 32°, and the angular range α of each region may be approximately 8°. The angular ranges α of each region in FIG. 32 may be approximately equal (e.g., each region may have an angular range of approximately 8°), or the angular ranges of one or more regions may be different (e.g., regions 240A and 240D may each have an angular range of approximately 8°, and regions 240B and 240C may each have an angular range of approximately 4°).

FIG. 33 illustrates the four-region field of regard of FIG. 32 with an example scan pattern 200. The scan pattern 200 includes a total of 24 scan lines 230. Each region 240 of the FOR includes six scan lines 230 that are oriented substantially along the y-axis and distributed along the x-axis. One of the scan lines 230 is illustrated with an example five pixels (210a, 210b, 210c, 210d, 210e). The FOR_{V} may have an angular extent of approximately 32°, extending from approximately −16° to +16° with respect to the 0° mark on the y-axis. For example, region 240D may extend from approximately −16° to −8°, and region 240C may extend from approximately −8° to 0°. Similarly, region 240B may extend from approximately 0° to +8°, and region 240A may extend from approximately +8° to +16°.

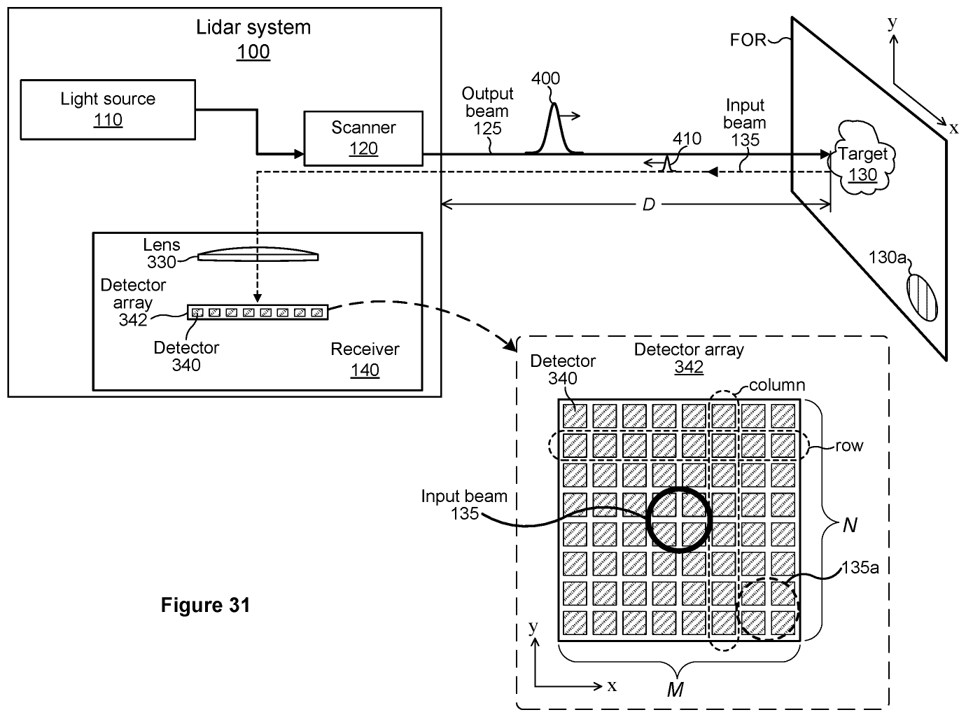

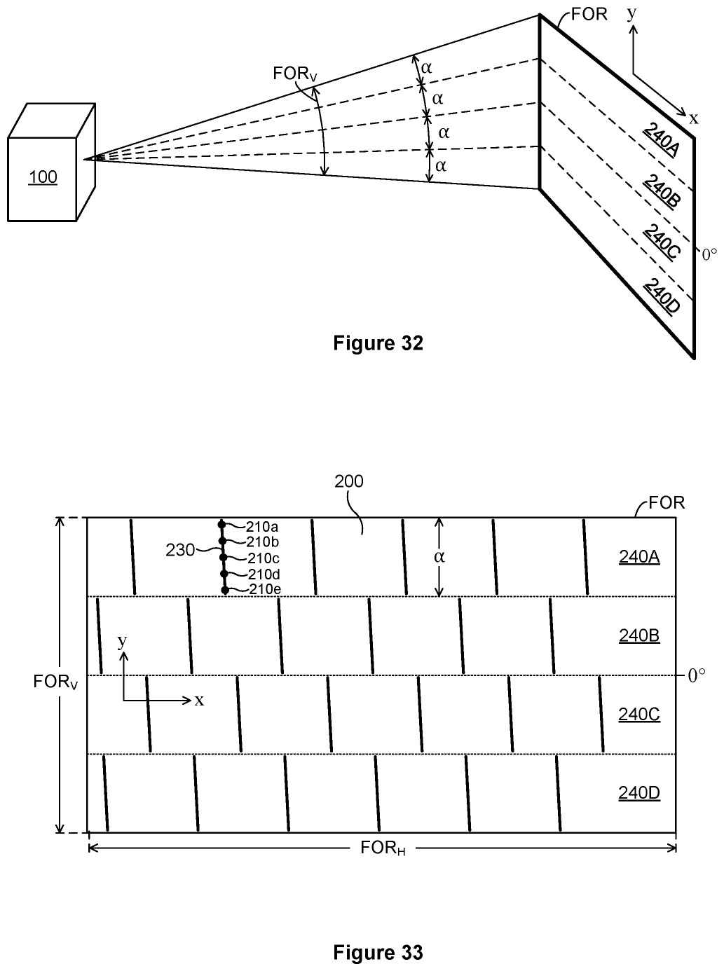

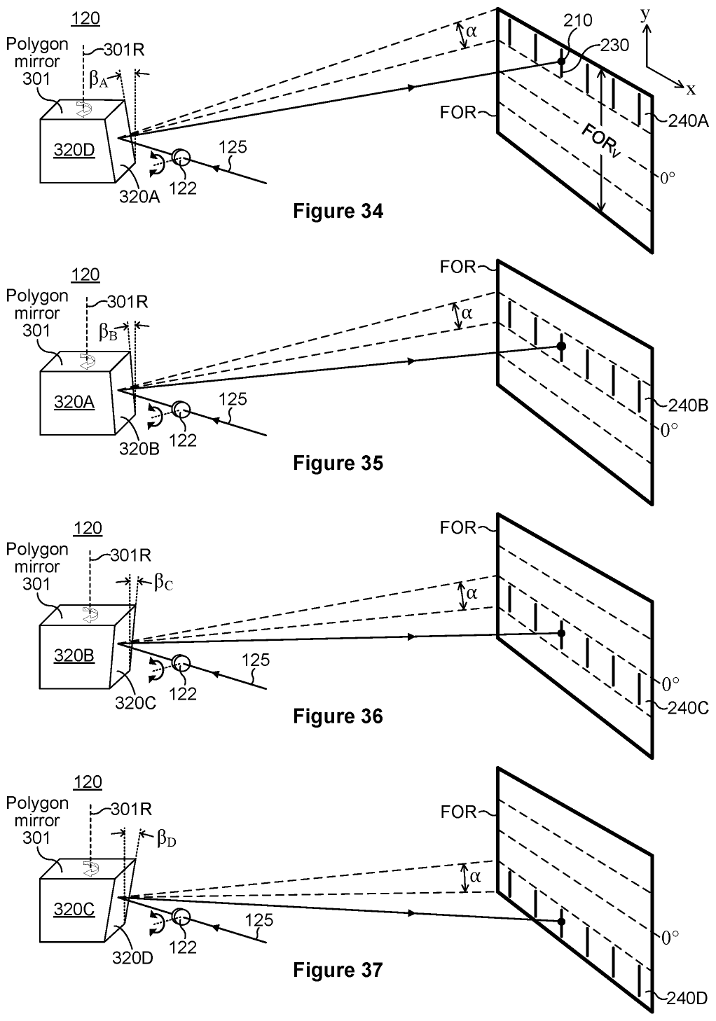

FIGS. 34-37 illustrate an example scanner 120 that includes a polygon mirror 301 with angled faces configured to scan the four regions of the field of regard of FIGS. 32-33. The scanner 120 in FIGS. 34-37, which may be part of the lidar system 100 in FIG. 32, includes a beam deflector 122 that scans the output beam 125 along the y-axis and an angle-faced polygon scan mirror 301 that scans the output beam along the x-axis. The beam deflector 122 may be a reflective or transmissive beam deflector. In each region of the FOR, the beam deflector 122 may scan the output beam 125 over an angular range α to produce six scan lines 230, and the polygon mirror 301 may rotate about the rotation axis 301R to distribute the scan lines along the x-axis. In FIGS. 34-37, each reflective surface of the polygon mirror 301 may scan the output beam 125 across one of the regions of the FOR (e.g., in FIG. 34, reflective surface 320A scans region 240A; in FIG. 35, reflective surface 320B scans region 240B; etc.). The angular range α may be approximately the same for each region of the FOR, or one or more regions of the FOR may have a different value for the angular range α.

The polygon scan mirror 301 in FIGS. 34-37 is a polygon mirror with angled faces, and each face of the polygon mirror includes a reflective surface 320. A polygon scan mirror 301 with angled faces may refer to a polygon mirror where one or more of the faces or reflective surfaces of the polygon mirror have non-zero angles with respect to the rotation axis 301R of the polygon mirror. Additionally, a polygon mirror with angled faces may have one or more faces with a first angle with respect to the rotation axis 301R and one or more other faces with a second angle with respect to the rotation axis, where the first and second angles are different. A reflective surface 320 having an angle of approximately zero degrees with respect to a rotation axis 301R corresponds to the reflective surface being approximately parallel to the rotation axis. Additionally, for a zero-degree angle between the reflective surface 320 and the rotation axis 301R, a surface normal to the reflective surface may be orthogonal to the rotation axis. A reflective surface 320 having a non-zero angle β with respect to a rotation axis 301R corresponds to the reflective surface being oriented at angle β with respect to the rotation axis. Additionally, for a non-zero angle β, a surface normal to the reflective surface 320 may be oriented with respect to the rotation axis 301 at an angle of (90°-β). For example, the reflective surface 320A in FIG. 34 may have a non-zero angle β_{A} of 6° with respect to the rotation axis 301, which corresponds to an angle of 84° between a surface normal to the reflective surface 320A and the rotation axis 301.

The polygon mirror 301 in FIGS. 34-37 rotates about the rotation axis 301R and has four faces with four reflective surfaces (320A, 320B, 320C, 320D). Each reflective surface has a particular non-zero angle with respect to the rotation axis 301R. Reflective surface 320A has an angle of β_{A} with respect to the rotation axis 301R, which causes the output beam 125 (which includes multiple pulses of light 400) to scan across region 240A. Reflective surface 320B has an angle of β_{B} with respect to the rotation axis 301R, which causes the output beam 125 to scan across region 240B. Reflective surface 320C has an angle of β_{C} with respect to the rotation axis 301R, which causes the output beam 125 to scan across region 240C. Reflective surface 320D has an angle of β_{D} with respect to the rotation axis 301R, which causes the output beam 125 to scan across region 240D. During one full revolution of the four-sided polygon scan mirror 301, the output beam 125 is reflected in sequence from each of the four reflective surfaces (320A, 320B, 320C, 320D) and is scanned once across each of the four regions (240A, 240B, 240C, 240D). One revolution of the polygon scan mirror 301 may correspond to a single scan of the FOR, and a lidar system 100 may produce one point cloud corresponding to the single scan. Each angled face of a polygon mirror may have any suitable angle β, such as for example, an angle of approximately 0.5°, 1°, 2°, 5°, or 10°. Additionally, one or more faces of a polygon mirror may be non-angled and may have an angle β of approximately 0°. In the example of FIGS. 34-37, β_{A} may be +6°, β_{B} may be +2°, β_{C} may be −2°, and β_{D} may be −6°.

The beam deflector 122 in FIGS. 34-37 scans the output beam 125 over an angular range of α along the y-axis, and the FOR has an angular extent of FOR_{V} along the y-axis. While the beam deflector 122 provides scanning along the y-axis over an angular range of α, the angled faces of the polygon mirror 301 allow for the scanner 120 to cover a larger angular range corresponding to the vertical field of regard (FOR_{V}). The FOR_{V} may have an angular extent along the y-axis that is greater than or equal to some fraction of r×α and less than or equal to r×α, where the parameter r is an integer greater than or equal to 2 and less than or equal to the number of reflective surfaces 320 of the polygon mirror 301. The parameter r may correspond to the number of regions 240 into which a FOR is divided. For example, a FOR_{V} may have an angular extent that is greater than or equal to 80% of r×α and less than or equal to r×α, which may be expressed as 0.8 (r×α)≤FOR_{V}≤(r×α). If FOR_{V}=(r×α), then adjacent regions of the FOR may have no angular overlap, and if FOR_{V}=0.8(r×α), then adjacent regions of the FOR may have approximately 20% angular overlap. In the example of FIGS. 34-37, the parameter r has a value of 4, and the angular range α may be 8°. The FOR_{V} may have an angular extent of approximately 32°, which corresponds to adjacent regions of the FOR being non-overlapping (in this case, FOR_{V}=r×α). Alternatively, adjacent regions of the FOR may have some amount of angular overlap. For example, the FOR_{V} may have an angular extent of approximately 26°, which may correspond to each of the adjacent regions of the FOR having an angular overlap of approximately 2° (in this case, FOR_{V}≅0.81(r×α)).

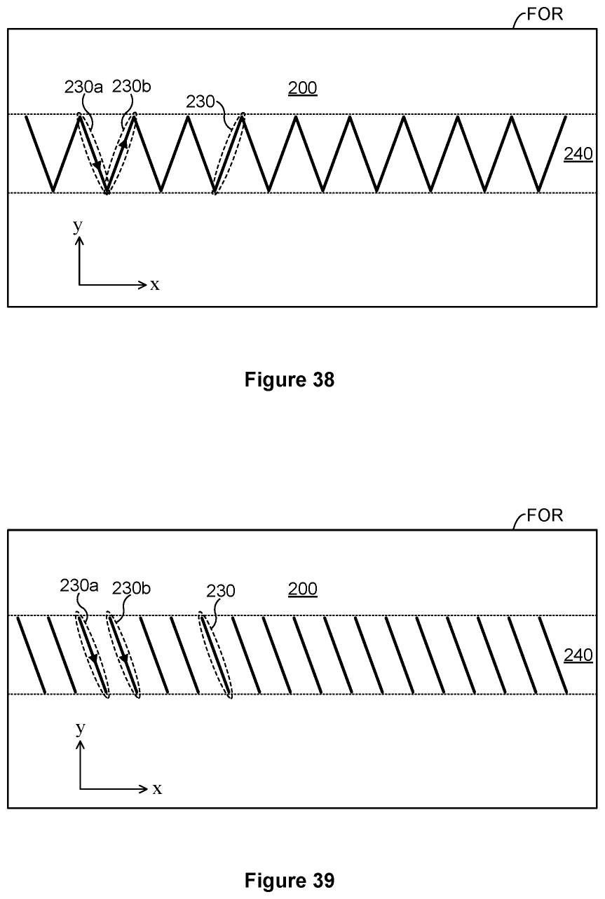

FIG. 38 illustrates an example bidirectional scan of a region 240 of a field of regard. A beam deflector 122 may scan an output beam 125 in two directions to produce the bidirectional scan of the region 240. The scan lines 230 in FIG. 38 may be scanned alternately in a downward motion from top to bottom of the region 240 and then in an upward motion from bottom to top. For example, scan line 230a may be scanned in a downward motion, and then scan line 230b may be scanned in an upward motion. The MEMS beam deflector 122 in FIGS. 28-29 may provide a bidirectional scan of a region 240 of a FOR. For example, when the pivoting-mirror portion 123 in FIG. 29 pivots in a clockwise direction, the output beam 125 may produce a scan line 230 that is scanned in a first direction (e.g., downward). When the pivoting-mirror portion 123 subsequently pivots in a counter-clockwise direction, the output beam 125 may produce a subsequent scan line 230 that is scanned in a second direction approximately opposite the first direction (e.g., upward).

FIG. 39 illustrates an example unidirectional scan of a region 240 of a field of regard. A beam deflector 122 may scan an output beam 125 in one direction to produce the unidirectional scan of the region 240. Each of the scan lines 230 in FIG. 39 may be scanned in approximately the same downward motion from top to bottom of the region 240. For example, scan line 230a may be scanned in a downward motion, and then scan line 230b may be scanned in another downward motion. The polygon mirror beam deflector 122 in FIG. 30 may provide a unidirectional scan of a region 240 of a FOR. For example, the polygon mirror beam deflector 122 may rotate in the same direction, and each scan line 230 may be produced by a reflection of the output beam from one of the reflective surfaces 320 of the polygon mirror beam deflector as the polygon mirror rotates.

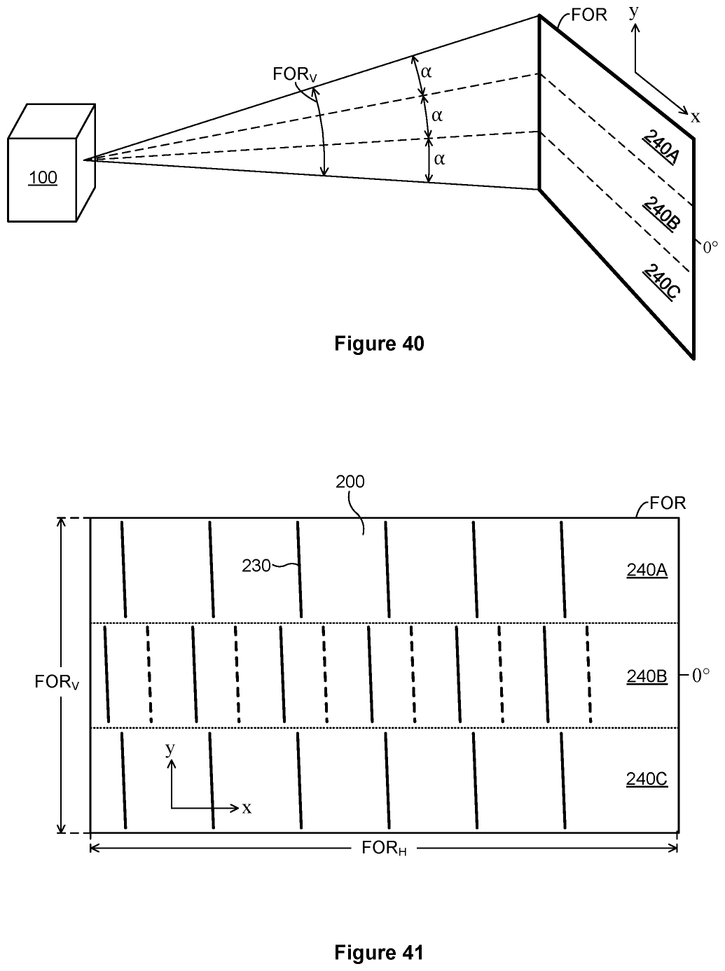

FIG. 40 illustrates an example lidar system 100 that scans a field of regard that includes three regions (240A, 240B, 240C). A single scan of the FOR may include one or more scans of an output beam 125 across each of the three regions (240A, 240B, and 240C), and the lidar system 100 may produce one point cloud corresponding to the single scan. For example, the lidar system 100 in FIG. 40 may scan each of the three regions once to produce a single scan of the FOR. As another example, the lidar system 100 in FIG. 40 may scan region 240A once, region 240B twice, and region 240C once. The lidar system 100 may scan the three regions in any suitable sequence, such as for example: in the sequence 240A, 240B, 240C; or in the sequence 240A, 240B, 240C, 240B (where region 240B is scanned twice).

FIG. 41 illustrates the three-region field of regard of FIG. 40 with an example scan pattern 200. Regions 240A and 240C each include six scan lines 230 that are oriented substantially along the y-axis and distributed along the x-axis. Region 240B includes 12 scan lines 230 that are also oriented substantially along the y-axis and distributed along the x-axis. For each scan of the FOR, the lidar system 100 may scan region 240B twice, where the solid scan lines represent a first scan of region 240B, and the dashed scan lines represent a later scan of region 240B. The FOR_{V} may have an angular extent of approximately 24°, extending from approximately −12° to +12° with respect to the 0° mark on the y-axis. For example, region 240C may extend from approximately −12° to −4°; region 240B may extend from approximately −4° to +4°; and region 240A may extend from approximately +4° to +12°.

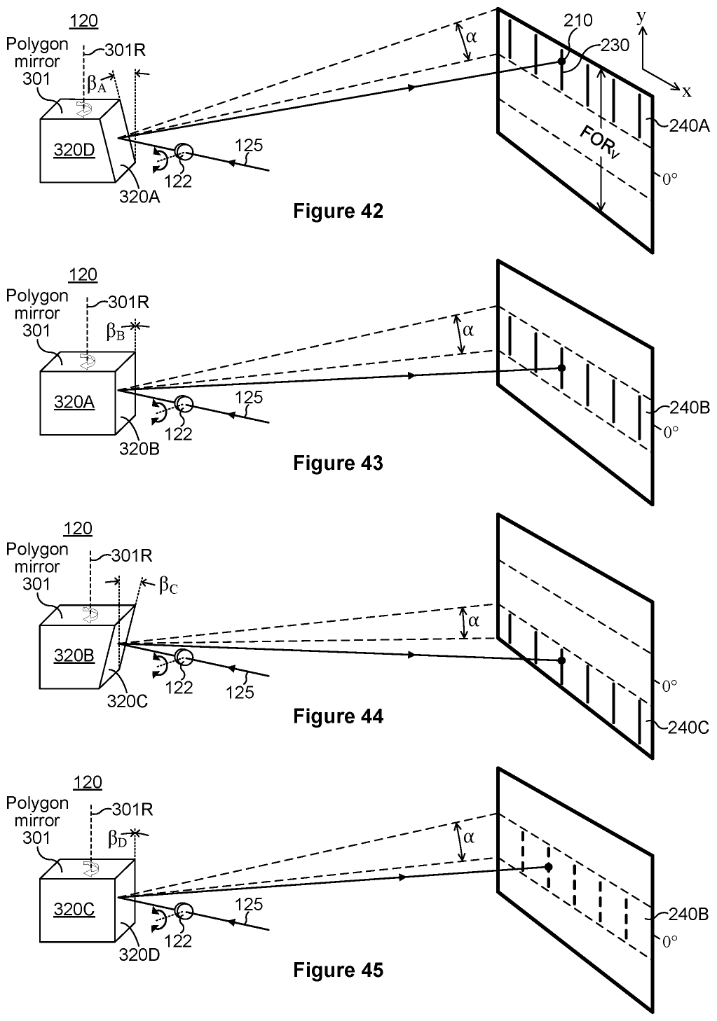

FIGS. 42-45 illustrate an example scanner 120 that includes a polygon mirror 310 with angled faces configured to scan the three regions of the field of regard of FIGS. 40-41. The scanner 120 in FIGS. 42-45, which may be part of the lidar system 100 in FIG. 40, includes a beam deflector 122 that scans the output beam 125 along the y-axis and an angle-faced polygon scan mirror 301 that scans the output beam along the x-axis. In each region of the FOR, the beam deflector 122 may scan the output beam 125 over an angular range α to produce six scan lines 230, and the polygon mirror 301 may rotate about the rotation axis 301R to distribute the scan lines along the x-axis. In FIGS. 42-45, each reflective surface of the polygon mirror 301 may scan the output beam 125 across one of the regions of the FOR. In FIG. 42, reflective surface 320A scans region 240A; in FIG. 43, reflective surface 320B scans region 240B; and in FIG. 44, reflective surface 320C scans region 240C. Additionally, in FIG. 45, reflective surface 320D provides a second scan of region 240B. The angular range α may be approximately the same for each region of the FOR, or one or more regions of the FOR may have a different value for the angular range α.

The polygon scan mirror 301 in FIGS. 42-45 is a polygon mirror with angled faces, and each face of the polygon mirror includes a reflective surface 320. The polygon mirror 301 in FIGS. 42-45 rotates about the rotation axis 301R and has four faces with four reflective surfaces (320A, 320B, 320C, 320D). Each reflective surface has a particular angle with respect to the rotation axis 301R. Reflective surface 320A has an angle of PA with respect to the rotation axis 301R, which causes the output beam 125 (which includes multiple pulses of light 400) to scan across region 240A. Reflective surface 320B has an angle of 0B with respect to the rotation axis 301R, which causes the output beam 125 to scan across region 240B. Reflective surface 320C has an angle of β_{C} with respect to the rotation axis 301R, which causes the output beam 125 to scan across region 240C. Reflective surface 320D has an angle of β_{D} (which is approximately equal to β_{B}) with respect to the rotation axis 301R, which causes the output beam 125 to scan across region 240B. During one full revolution of the four-sided polygon scan mirror 301, the output beam 125 is reflected in sequence from each of the four reflective surfaces (320A, 320B, 320C, 320D), and the output beam 125 scans the regions in the sequence 240A, 240B, 240C, 240B (where region 240B is scanned twice). One revolution of the polygon scan mirror 301 may correspond to a single scan of the FOR, and a lidar system 100 may produce one point cloud corresponding to the single scan.

The scanners in FIGS. 42-45 and FIGS. 34-37 are similar, except the polygon scan mirror 301 in FIGS. 42-45 includes two angled faces with approximately the same angle Γ (e.g., β_{B}≅β_{D}), while each of the angled faces of the polygon scan mirror 301 in FIGS. 34-37 has a different angle β. In the example of FIGS. 42-45, the reflective surfaces 320B and 320D may each have angles of approximately 0° and may each be approximately parallel to the rotation axis 301R. For example, in FIGS. 42-45, β_{A} may be +4°, β_{B} may be 0°, β_{C} may be −4°, and β_{D} may be 0°. The polygon scan mirror 301 in FIGS. 34-37 is considered a polygon scan mirror with angled faces since (i) each of the four reflective surfaces has a non-zero angle with respect to the rotation axis 301R and (ii) the reflective surfaces 320A, 320B, 320C, and 320D each have a different angle β with respect to the rotation axis 301R. The polygon scan mirror 301 in FIGS. 42-45 is considered a polygon scan mirror with angled faces since (i) the reflective surfaces 320A and 320C each have non-zero angles with respect to the rotation axis 301R and (ii) the reflective surfaces 320A, 320B, and 320C each have a different angle β with respect to the rotation axis 301R. A polygon scan mirror 301 may have two or more reflective surfaces 320 that have equal angles β with respect to a rotation axis 301R, and the two or more reflective surfaces 320 may each scan an output beam 125 (and associated emitted pulses of light 400) within the same region 240 of a FOR. In FIGS. 43 and 45, the reflective surfaces 320B and 320D have approximately the same angle β, which provides two scans of the output beam 125 across the middle region 240B for each revolution of the polygon scan mirror 301. Scanning the region 240B twice may provide for a point cloud with a higher density of pixels 210 in the middle of the FOR as compared to the upper and lower portions of the FOR.

The polygon scan mirror 301 in any of FIGS. 16-17, 19-25, 27, and 30 may be a polygon mirror with non-angled faces or a polygon mirror with angled faces. For example, the polygon mirror 301 in FIG. 30 may be a polygon mirror with non-angled faces, where each reflective surface 320 of the polygon mirror has an angle of approximately zero degrees with respect to the rotation axis 320Rx. Alternatively, the polygon mirror 301 in FIG. 30 may be a polygon mirror with angled faces, where at least one of the reflective surfaces 320 has a non-zero angle with respect to the rotation axis 320Rx.

A polygon scan mirror 301 with angled faces may have S reflective surfaces 320, and each reflective surface may have one of r different angles β with respect to a rotation axis 301R of the polygon mirror. For a polygon scan mirror 301 with angled faces, the parameter r is an integer greater than or equal to 2 (so that the angled faces have at least two different angles) and less than or equal to 5, the number of sides of the polygon scan mirror 301. A polygon scan mirror 301 with non-angled faces may be considered to have a parameter r equal to 1 (e.g., all the faces are oriented at approximately the same angle). The parameter r represents the number of different angles that a polygon scan mirror 310 includes. Additionally, the parameter r corresponds to the number of regions 240 into which a field of regard (FOR) is subdivided. For example, a polygon scan mirror 301 with four different angles β (e.g., as illustrated in FIGS. 34-37) may scan a FOR that is subdivided into four corresponding regions 240 (e.g., r=4). As another example, a polygon scan mirror 301 with three different angles β (e.g., as illustrated in FIGS. 42-45) may scan a FOR that is subdivided into three corresponding regions 240 (e.g., r=3). A polygon scan mirror 301 with angled faces may have 2, 3, 4, 5, 10, or any other suitable number r of different angles, and a FOR may be subdivided into any suitable number of regions corresponding to the parameter r.

A FOR that is scanned using a polygon scan mirror 301 with angled faces may be subdivided into r regions 240, each region corresponding to one of the r different angles β of the polygon mirror. In the example of FIGS. 34-37, the polygon scan mirror 301 has four reflective surfaces 320 (e.g., S=4), and the angled faces have four different angles β (e.g., r=4). Additionally, the FOR in FIGS. 34-37 is subdivided into four regions 240, where each region is associated with one of the four different angles β. In the example of FIGS. 42-45, the polygon scan mirror 301 has four reflective surfaces 320 (e.g., S=4), and the angled faces have three different angles β (e.g., r=3). Additionally, the FOR in FIGS. 42-45 is subdivided into three regions 240, where each region is associated with one of the three different angles β. Each reflective surface 320 of a polygon scan mirror 301 with angled faces may scan an output beam 125 within one of the r regions 240 of the FOR. For example, in FIGS. 42-45, reflective surface 320A scans region 240A, reflective surfaces 320B and 320D each scan region 240B, and reflective surface 320C scans region 240C.

A polygon scan mirror 301 with angled faces may have S reflective surfaces 320, and each reflective surface may have one of r different angles. As the polygon mirror 301 rotates, each reflective surface 320 may scan an output beam 125 across one region 240 of the FOR of a lidar system 100. A single scan across one region 240 may correspond to one reflective surface 320 of the polygon scan mirror 310 scanning the output beam 125 (along with associated pulses of light 400) from one end of the region to an opposite end of the region (e.g., from a left side to a right side, or from an upper end to a lower end). For example, in FIG. 34, as reflective surface 320A scans the output beam 125 (and associated pulses of light 400) along the x-axis from the left side of the FOR to the right side (which corresponds a single scan across region 240A), the beam deflector 122 scans the output beam 125 along the y-axis to produce six scan lines 230. Each full revolution of a polygon scan mirror 301 with angled faces may correspond to a single scan across a FOR of a lidar system 100 and may result in one point cloud being produced. If a polygon scan mirror 301 with angled faces is rotated at a rotation speed of R revolutions per second, a lidar system 100 may produce point clouds at a frame rate of R frames per second, where each point cloud includes pixels 210 corresponding to pulses of light 400 reflected from each of the S reflective surfaces of the polygon mirror. Additionally, if a light source 100 emits pulses of light 400 at a pulse repetition frequency of PRF, the approximate number of pixels 210 in each point cloud (Pix) may be determined from the expression Pix=PRF/R. In the example of FIGS. 34-37, if the polygon scan mirror 301 is rotated at 10 revolutions per second, then the lidar system 100 may produce point clouds at a 10-Hz frame rate. Additionally, if the light source of the lidar system emits pulses of light with a PRF of 500 kHz, then each point cloud may include approximately 50,000 pixels.

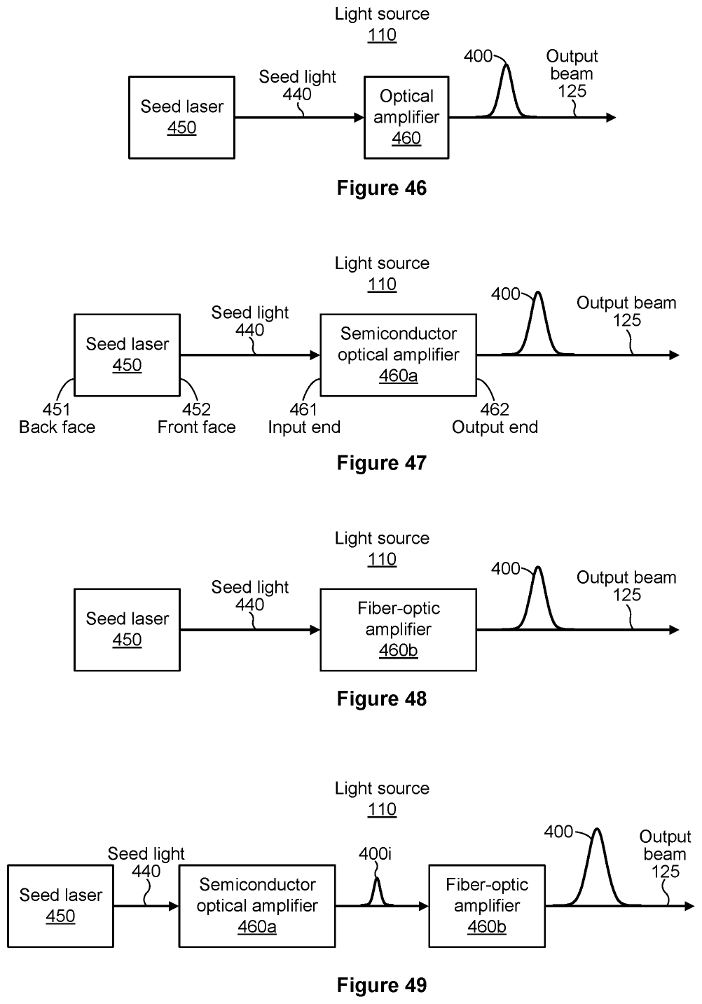

FIG. 46 illustrates an example light source 110 that includes a seed laser 450 and an optical amplifier 460. A light source 110 of a lidar system 100 may include (i) a seed laser 450 that produces seed light 440 and (ii) an optical amplifier 460 that amplifies the seed light to produce an output beam 125 that includes pulses of light 400. The seed laser 450 (which may be referred to as a seed laser diode) may include a laser diode, a Fabry-Perot laser diode, a quantum well laser, a DBR laser, a DFB laser, a VCSEL, a quantum dot laser diode, a GCSEL, a SCOWL, a single-transverse-mode laser diode, a multi-mode broad area laser diode, a laser-diode bar, a laser-diode stack, a tapered-stripe laser diode, a sampled-grating distributed Bragg reflector (SG-DBR) laser, or any other suitable type of laser. The seed laser 450 may be supplied with a substantially constant electrical current so that the seed light 440 has a substantially constant optical power, or the seed laser 450 may be supplied with pulses of electrical current so that the seed light 440 includes pulses of light. The seed laser 450 may be a fixed-wavelength laser that produces seed light 440 having a substantially constant wavelength, or the seed laser 450 may be a wavelength-tunable laser that produces seed light 440 with an adjustable wavelength. The optical amplifier 460 may include a semiconductor optical amplifier (SOA), a fiber-optic amplifier, or a SOA followed by a fiber-optic amplifier.

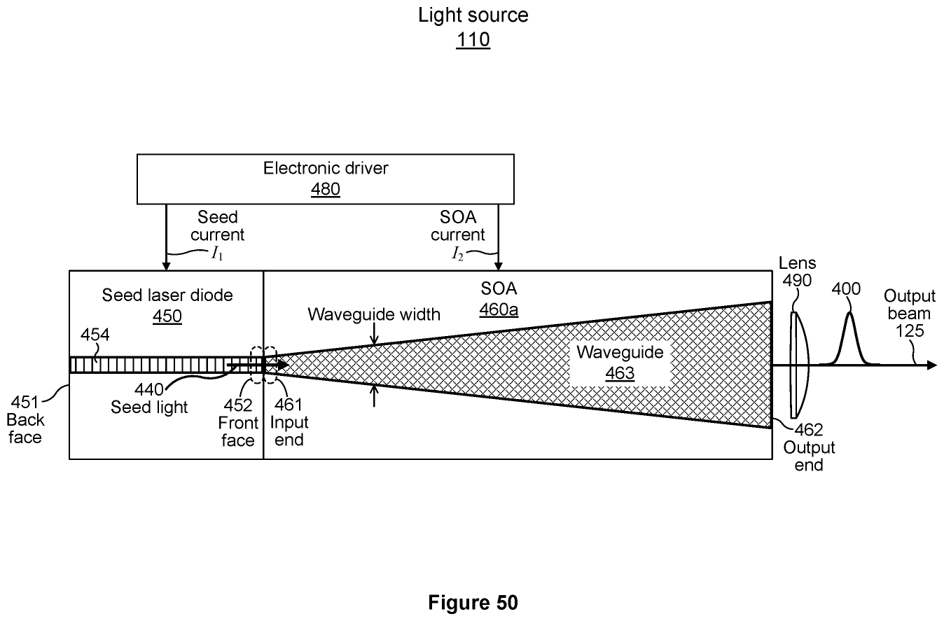

FIG. 47 illustrates an example light source 110 that includes a seed laser 450 and a semiconductor optical amplifier (SOA) 460a. A light source 110 of a lidar system 100 may include (i) a seed laser 450 that produces seed light 440 and (ii) a SOA 460a that amplifies the seed light to produce an output beam 125 that includes emitted pulses of light 400. A SOA 460a may include a semiconductor optical waveguide that receives the seed light 440 from the seed laser 450 and amplifies the seed light 440 as it propagates through the waveguide. The optical waveguide of a SOA 460a may be tapered (e.g., as illustrated in FIG. 50) or may be a straight, non-tapered waveguide having a substantially constant waveguide width. A seed laser 450 may produce seed light 400 that includes pulses of light, and the seed pulses of light may be amplified by the SOA 460a to produce emitted pulses of light 400. Alternatively, the seed laser 450 may produce seed light 440 having a substantially constant optical power, and the SOA 460a may amplify temporal portions of the seed light to produce emitted pulses of light 400, where each amplified temporal portion of the seed light corresponds to one of the emitted pulses of light 400. For example, a SOA 460a may amplify a 5-ns temporal portion of seed light 440 to produce an emitted pulse of light 400 having a duration of approximately 5 ns. A light source 110 that includes a seed laser 450 that supplies seed light 440 that is amplified by a SOA 460a may be referred to as a master-oscillator power-amplifier laser (MOPA laser) or a MOPA light source. The seed laser 450 may be referred to as a master oscillator, and the SOA 460a may be referred to as a power amplifier.

The seed laser 450 illustrated in FIG. 47 includes a front face 452 and a back face 451. The seed light 440 is emitted from the front face 452 and directed to the input end 461 of the SOA 460a. The seed light 440 may be emitted as a free-space beam, and a light source 110 may include one or more lenses (not illustrated in FIG. 47) that collimate the seed light 440 emitted from the front face 452 or that focus the seed light 440 into the waveguide of the SOA 460a. Alternatively, the seed laser 450 and the SOA 460a may be integrated together so that the seed light 440 is coupled directly from the seed laser 450 to the SOA 460a (e.g., as illustrated in FIG. 50). The front face 452 or back face 451 of a seed laser 450 may include a discrete facet formed by a semiconductor-air interface. Additionally, the front face 452 or the back face 451 may include a dielectric coating that provides a reflectivity (at the seed-laser operating wavelength) of between approximately 50% and approximately 99.9%. For example, the back face 451 may have a reflectivity of between 90% and 99.9% at a wavelength of the seed laser.

FIG. 48 illustrates an example light source 110 that includes a seed laser 450 and a fiber-optic amplifier 460b. The seed laser 450 may produce seed light 440 that includes pulses of light, and the fiber-optic amplifier 460b may amplify the seed pulses of light to produce an output beam 125 that includes emitted pulses of light 400. Each emitted pulse of light 400 may include amplified light from one of the seed pulses of light. The seed light 440 may be coupled to the fiber-optic amplifier 460b via an input optical fiber, and the output beam 125 may be a free-space beam that is emitted from an output optical fiber of the fiber-optic amplifier.

FIG. 49 illustrates an example light source 110 that includes a seed laser 450, a semiconductor optical amplifier (SOA) 460a, and a fiber-optic amplifier 460b. A light source 110 of a lidar system 100 may include a seed laser 450 followed by a SOA 460a, which in turn is followed by a fiber-optic amplifier 460b. The seed laser 450 produces seed light 440 that is amplified by the SOA 460a to produce relatively low-power intermediate pulses of light 400i which are then further amplified by the fiber-optic amplifier 460b to produce the emitted pulses of light 400. The seed light 400 may include pulses of light which are amplified by the SOA 460a to produce the intermediate pulses of light 400i. Alternatively, the seed laser 450 may produce seed light 440 having a substantially constant optical power, and the SOA 460a may amplify temporal portions of the seed light to produce the intermediate pulses of light 400i. A SOA 460a and a fiber-optic amplifier 460b may each have an optical power gain of 10 dB, 15 dB, 20 dB, 25 dB, 30 dB, 35 dB, 40 dB, or any other suitable optical power gain. In the example of FIG. 49, the SOA 460a may have a gain of 30 dB, and the fiber-optic amplifier 460b may have a gain of 20 dB, which corresponds to an overall gain of 50 dB. A temporal portion of seed light 440 with an energy of 5 pJ may be amplified by the SOA 460a (with a gain of 30 dB) to produce an intermediate pulse of light 400i with an energy of approximately 5 nJ. The fiber-optic amplifier 460b may amplify the 5-nJ pulse of light 400i by 20 dB to produce an output pulse of light 400 with an energy of approximately 0.5 μJ.

FIG. 50 illustrates an example light source 110 that includes a seed laser diode 450 integrated with a semiconductor optical amplifier (SOA) 460a. The SOA 460a includes an input end 461, an output end 462, and an optical waveguide 463 extending from the input end 461 to the output end 462. The seed laser diode 450 may produce seed light 440 that is coupled into the waveguide 463 of the SOA 460a via the input end 461. The SOA 460a may amplify a seed pulse of light or a temporal portion of the seed light 440 as the light propagates along the waveguide 463 from the input end 461 to the output end 462. The amplified light may be emitted from the output end 462 as an emitted pulse of light 400. The emitted pulse of light 400 may be part of an output beam 125, and the light source 110 may include a lens 490 configured to collect and collimate the pulses of light 400 from the output end 462 to produce a collimated output beam 125.

A waveguide 463 may include a semiconductor optical waveguide formed at least in part by the semiconductor material of the SOA 460a, and the waveguide 463 may confine light along transverse directions while the light propagates through the SOA 460a. A waveguide 463 may have a waveguide width that is substantially fixed along the length of the SOA (e.g., the width at the input end 461 is approximately equal to the width at the output end 462), or a waveguide 463 may have a tapered width (e.g., as illustrated in FIG. 50). For example, a waveguide 463 may have a substantially fixed width of approximately 5 μm, 10 μm, 20 μm, 50 μm, 100 μm, 200 μm, 500 μm, or any other suitable width. In FIG. 50, the SOA 460a has a tapered optical waveguide 463 that extends from the input end 461 to the output end 462. The tapered waveguide 463 has a width that increases along the length of the SOA from the input end 461 to the output end 462. For example, the width of the tapered waveguide 463 at the input end 461 may be approximately equal to the width of the waveguide 454 of the seed laser diode 450 (e.g., the waveguide width at the input end 461 may be approximately 1 μm, 2 μm, 5 μm, 10 μm, or 50 μm). At the output end 462 of the SOA 460a, the tapered waveguide 463 may have a width of approximately 50 μm, 100 μm, 200 μm, 500 μm, 1 mm, or any other suitable width. As another example, the width of the tapered waveguide 463 may increase approximately linearly from a width of approximately 20 μm at the input end 461 to a width of approximately 250 μm at the output end 462.

The input end 461 or the output end 462 of a SOA 460a may be a discrete facet formed by a semiconductor-air interface. Additionally, the input end 461 or the output end 462 may include a dielectric coating (e.g., an anti-reflection coating to reduce the reflectivity of the input end 461 or the output end 462). An anti-reflection (AR) coating may have a reflectivity at the seed-laser operating wavelength of less than 5%, 2%, 0.5%, 0.1%, or any other suitable reflectivity value. In FIG. 50, the output end 462 may have an AR coating that reduces the amount of amplified seed light reflected by the output end 462 back towards the seed laser diode 450. An AR coating applied to the input end 461 or the output end 462 may also prevent the SOA 460a from acting as a laser and emitting coherent light when little or no seed light 440 is present.

A light source 110 may include a seed laser diode 450 and a SOA 460a that are integrated together and disposed on or in a single chip or substrate. For example, a seed laser diode 450 and a SOA 460a may each be fabricated separately and then attached to the same substrate (e.g., using epoxy, adhesive, or solder). As another example, the seed laser diode 450 and the SOA 460a may be fabricated together on the same substrate. In the example of FIG. 47, the seed laser 450 and the SOA 460a may be separate devices that are not disposed on a single substrate, and the seed light 440 may be a free-space beam. In the example of FIG. 50, the seed laser 450 and the SOA 460a may be integrated together and disposed on or in a single chip or substrate (e.g., the seed laser 450 and the SOA 460a may be fabricated together on a single substrate).

In FIG. 50, rather than having a discrete facet formed by a semiconductor-air interface, the seed laser diode 450 and the SOA 460a may be integrated together so that the front face 452 of the seed laser diode 450 and the input end 461 of the SOA 460a are coupled together without a semiconductor-air interface. For example, the seed laser diode 450 may be directly connected to the SOA 460a so that the seed light 440 is directly coupled from the waveguide 454 of the seed laser diode 450 into the waveguide 463 of the SOA 460a. The front face 452 may be butt-coupled or affixed (e.g., using an optically transparent adhesive) to the input end 461, or the seed laser diode 450 and the SOA 460a may be fabricated together so that there is no separate front face 452 or input end 461 (e.g., the front face 452 and the input end 461 may be merged together to form a single interface between the seed laser diode 450 and the SOA 460a). Alternatively, the seed laser diode 450 may be coupled to the SOA 460a via a passive optical waveguide or via an optical modulator that transmits the seed light 440 from the front face 452 of the seed laser diode 450 to the input end 461 of the SOA 460a. For example, a passive optical waveguide may be located between the seed laser diode 450 and the SOA 460a, and the passive waveguide may convey the seed light 440 from the front face 452 of the seed laser diode 450 to the input end 461 of the SOA 460a. As another example, an optical phase or amplitude modulator may be located between the seed laser diode 450 and the SOA 460a, and the modulator may apply a phase or amplitude modulation to the seed light 440.

A light source 110 of a lidar system 100 may include an electronic driver 480 that (i) supplies electrical current to a seed laser 450 and (ii) supplies electrical current to a SOA 460a. In FIG. 50, the electronic driver 480 supplies seed current I₁ to the seed laser diode 450 to produce the seed light 440. The seed current I₁ supplied to the seed laser diode 450 may be a substantially constant DC electrical current so that the seed light 440 includes continuous-wave (CW) light or light having a substantially constant optical power. A substantially constant current may refer to a current that changes by less than 10%, 5%, or 1% over a time interval of approximately 100 s, 10 s, or 1 s. Similarly, seed light 440 having a substantially constant optical power may refer to seed light with an optical power that changes by less than 10%, 5%, or 1% over a time interval of approximately 100 s, 10 s, or 1 s. For example, the seed current I₁ may include a substantially constant DC current of approximately 1 mA, 10 mA, 100 mA, 200 mA, 500 mA, 1 A, or any other suitable DC electrical current. Additionally or alternatively, the seed current I₁ may include pulses of electrical current so that the seed light 440 includes seed pulses of light that are amplified by the SOA 460a.

In FIG. 50, the electronic driver 480 supplies SOA current I₂ to the SOA 460a, and the SOA current I₂ provides optical gain to temporal portions of the seed light 440 that propagate through the waveguide 463 of the SOA 460a. The SOA current I₂ may include pulses of electrical current, where each pulse of current causes the SOA 460a to amplify one seed pulse of light or one temporal portion of the seed light 440 to produce a corresponding emitted pulse of light 400. The SOA current I₂ may have a duration of approximately 0.5 ns, 1 ns, 2 ns, 5 ns, 10 ns, 20 ns, 50 ns, 100 ns, or any other suitable duration. The SOA current I₂ may have a peak amplitude of approximately 1 A, 2 A, 5 A, 10 A, 20 A, 50 A, 100 A, 200 A, 500 A, or any other suitable peak current. For example, the SOA current I₂ supplied to the SOA 460a may include a series of current pulses having a duration of approximately 5-10 ns and a peak current of approximately 100 A. The series of current pulses may result in the emission of a corresponding series of pulses of light 400, and each emitted pulse of light 400 may have a duration that is less than or equal to the duration of the corresponding electrical current pulse. For example, an electronic driver 480 may supply 5-ns duration current pulses to the SOA 460a at a repetition frequency of 700 kHz. This may result in emitted pulses of light 400 that have a duration of approximately 4 ns and the same pulse repetition frequency of 700 kHz.

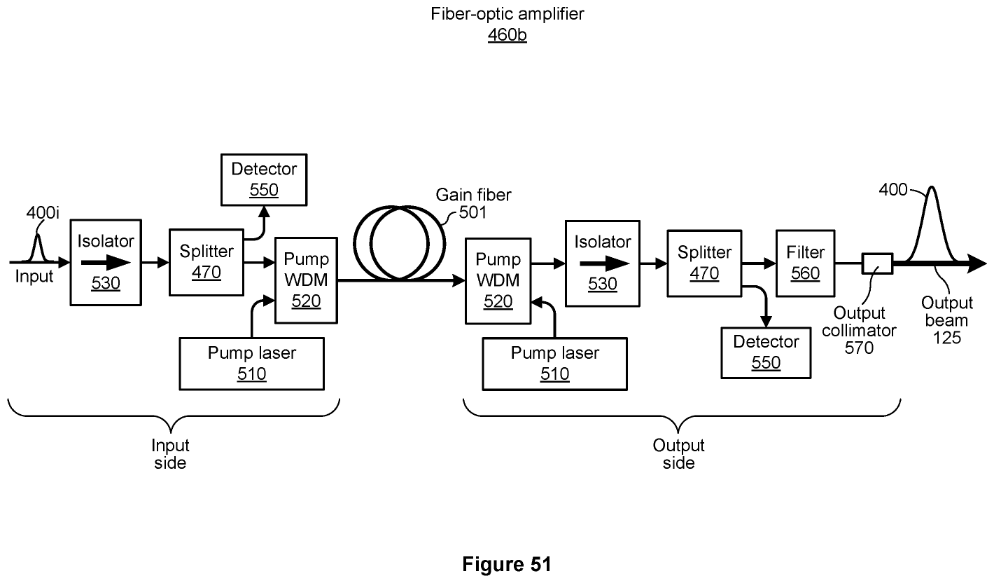

FIG. 51 illustrates an example fiber-optic amplifier 460b. A light source 110 of a lidar system 100 may include a fiber-optic amplifier 460b that amplifies seed pulses of light from a seed laser 450 or intermediate pulses of light 400i from a SOA 460a to produce an output beam 125 that includes pulses of light 400. A fiber-optic amplifier 460b may be terminated by a lens (e.g., output collimator 570) that produces a collimated free-space output beam 125 which may be directed to a scanner 120. A fiber-optic amplifier 460b may include one or more pump lasers 510, one or more pump WDMs 520, one or more optical gain fibers 501, one or more optical isolators 530, one or more optical splitters 470, one or more detectors 550, one or more optical filters 560, or one or more output collimators 570.

A fiber-optic amplifier 460b may include an optical gain fiber 501 that is optically pumped (e.g., provided with energy) by one or more pump lasers 510. The optically pumped gain fiber 501 may provide optical gain to each input pulse of light 400i while the pulse propagates through the gain fiber 501. The pump-laser light may travel through the gain fiber 501 in the same direction (co-propagating) as the pulse of light 400i or in the opposite direction (counter-propagating). The fiber-optic amplifier 460b in FIG. 51 includes one co-propagating pump laser 510 on the input side of the amplifier 460b and one counter-propagating pump laser 510 on the output side. A pump laser 510 may produce light at any suitable wavelength to provide optical excitation to the gain material of gain fiber 501 (e.g., a wavelength of approximately 808 nm, 810 nm, 915 m, 940 nm, 960 nm, 976 nm, or 980 nm). A pump laser 510 may be operated as a CW light source and may produce any suitable amount of average optical pump power, such as for example, approximately 1 W, 2 W, 5 W, 10 W, or 20 W of pump power. The pump-laser light from a pump laser 510 may be coupled into gain fiber 501 via a pump wavelength-division multiplexer (WDM) 520. A pump WDM 520 may be used to combine or separate pump light and the pulses of light 400i that are amplified by the gain fiber 501.

The fiber-optic core of a gain fiber 501 may be doped with a gain material that absorbs pump-laser light and provides optical gain to pulses of light 400i as they propagate along the gain fiber 501. The gain material may include rare-earth ions, such as for example, erbium (Er³⁺), ytterbium (Yb³⁺), neodymium (Nd³⁺), praseodymium (Pe³⁺), holmium (Ho³⁺), thulium (Tm³⁺), dysprosium (Dy³⁺), or any other suitable rare-earth element, or any suitable combination thereof. For example, the gain fiber 501 may include a core doped with erbium ions or with a combination of erbium and ytterbium ions. The rare-earth dopants absorb pump-laser light and are “pumped” or promoted into excited states that provide amplification to the pulses of light 400i through stimulated emission of photons. The rare-earth ions in excited states may also emit photons through spontaneous emission, resulting in the production of amplified spontaneous emission (ASE) light by the gain fiber 501.

A gain fiber 501 may include a single-clad or multi-clad optical fiber with a core diameter of approximately 6 μm, 7 μm, 8 μm, 9 μm, 10 μm, 12 μm, 20 μm, 25 μm, or any other suitable core diameter. A single-clad gain fiber 501 may include a core surrounded by a cladding material, and the pump light and the pulses of light 400i may both propagate substantially within the core of the gain fiber 501. A multi-clad gain fiber 501 may include a core, an inner cladding surrounding the core, and one or more additional cladding layers surrounding the inner cladding. The pulses of light 400i may propagate substantially within the core, while the pump light may propagate substantially within the inner cladding and the core. The length of gain fiber 501 in an amplifier 460b may be approximately 0.5 m, 1 m, 2 m, 4 m, 6 m, 10 m, 20 m, or any other suitable gain-fiber length.

A fiber-optic amplifier 460b may include one or more optical filters 560 located at the input or output side of the amplifier 460b. An optical filter 560 (which may include an absorptive filter, dichroic filter, long-pass filter, short-pass filter, band-pass filter, notch filter, Bragg grating, or fiber Bragg grating) may transmit light over a particular optical pass-band and substantially block light outside of the pass-band. The optical filter 560 in FIG. 51 is located at the output side of the amplifier 460b and may reduce the amount of ASE from the gain fiber 501 that accompanies the output pulses of light 400. For example, the filter 560 may be a band-pass filter that transmits light at the wavelength of the pulses of light 400i (e.g., 1550 nm) and attenuates light at wavelengths outside of a 5-nm pass-band centered at 1550 nm.

A fiber-optic amplifier 460b may include one or more optical isolators 530. An isolator 530 may reduce or attenuate backward-propagating light, which may destabilize or cause damage to a seed laser diode 450, SOA 460a, pump laser 510, or gain fiber 501. The isolators 530 in FIG. 51 may allow light to pass in the direction of the arrow drawn in the isolator and block light propagating in the reverse direction. Backward-propagating light may arise from ASE light from gain fiber 501, counter-propagating pump light from a pump laser 510, or optical reflections from one or more optical interfaces of a fiber-optic amplifier 460b. An optical isolator 530 may prevent the destabilization or damage associated with backward-propagating light by blocking most of the backward-propagating light (e.g., by attenuating backward-propagating light by greater than or equal to 5 dB, 10 dB, 20 dB, 30 dB, 40 dB, 50 dB, or any other suitable attenuation value).

A fiber-optic amplifier 460b may include one or more optical splitters 470 and one or more detectors 550. A splitter 470 may split off a portion of light (e.g., approximately 0.1%, 0.5%, 1%, 2%, or 5% of light received by the splitter 470) and direct the split off portion to a detector 550. In FIG. 51, each splitter 470 may split off and send approximately 1% of each pulse of light (400i or 400) to a detector 550. One or more detectors 550 may be used to monitor the performance or health of a fiber-optic amplifier 460b. If an electrical signal from a detector 550 drops below a particular threshold level, then a controller 150 may determine that there is a problem with the amplifier 460b (e.g., there may be insufficient optical power in the input pulses of light 400i or a pump laser 510 may be failing). In response to determining that there is a problem with the amplifier 460b, the controller 150 may shut down or disable the amplifier 460b, shut down or disable the lidar system 100, or send a notification that the lidar system 100 is in need of service or repair.

A fiber-optic amplifier 460b may include an input optical fiber configured to receive seed pulses of light from a seed laser 450 or input pulses of light 400i from a SOA 460a. The input optical fiber may be part of or may be coupled or spliced to one of the components of the fiber-optic amplifier 460b. For example, pulses of light 400i may be coupled into an optical fiber which is spliced to an input optical fiber of the isolator 530 located at the input to the amplifier 460b. As another example, the pulses of light 400i from a SOA 460 may be part of a free-space beam that is coupled into an input optical fiber of fiber-optical amplifier 460b using one or more lenses. As another example, an input optical fiber of fiber-optic amplifier 460b may be positioned at or near the output end 462 of a SOA 460 so that the pulses of light 400i are directly coupled from the SOA 460a into the input optical fiber.

The optical components of a fiber-optic amplifier 460b may be free-space components, fiber-coupled components, or a combination of free-space and fiber-coupled components. As an example, each optical component in FIG. 51 may be a free-space optical component or a fiber-coupled optical component. As another example, the input pulses of light 400i may be part of a free-space optical beam, and the isolator 530, splitter 470, and pump WDM 520 located on the input side of the amplifier 460b may each be free-space optical components. Additionally, the light from the pump laser 510 on the input side may be a free-space beam that is combined with the input pulses of light 400i by the pump WDM 520 on the input side, and the combined pump-seed light may form a free-space beam that is coupled into the gain fiber 501 via one or more lenses.

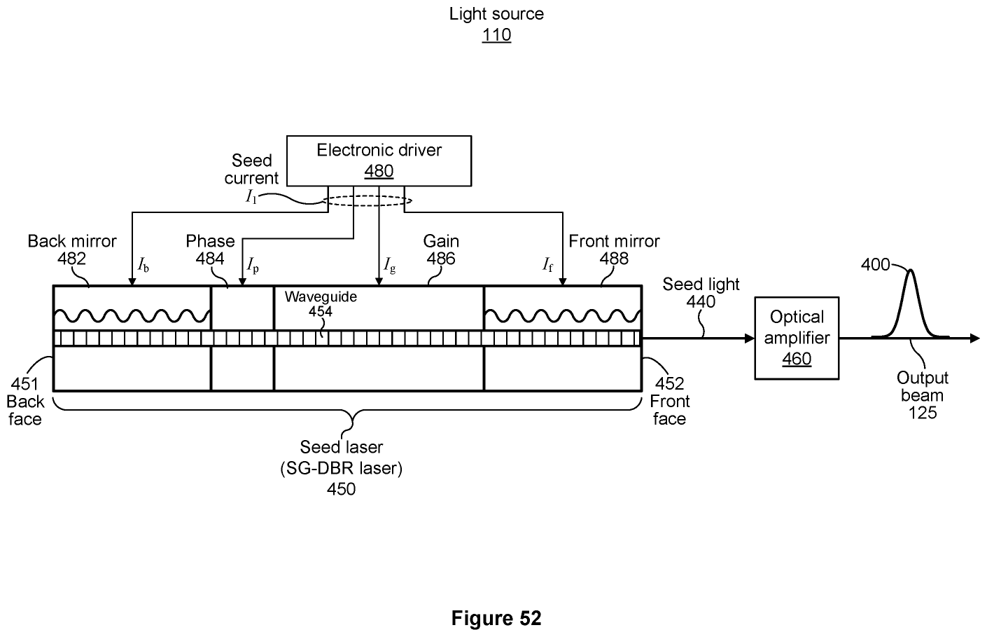

FIG. 52 illustrates an example light source 110 that includes a sampled-grating distributed Bragg reflector (SG-DBR) laser 450. The light source 110 in FIG. 52 may be referred to as a wavelength-tunable light source. The SG-DBR laser 450 may produce seed light 440 at multiple different wavelengths, and the optical amplifier 460 may amplify the seed light to produce an output beam 125 that includes pulses of light 400, where each emitted pulse of light has a particular wavelength of the multiple different wavelengths. For example, the SG-DBR laser 450 may produce a seed pulse of light at 1550 nm, and the optical amplifier 460 may amplify the seed pulse of light to produce an emitted pulse of light 400 having a 1550-nm wavelength. Then, the SG-DBR laser 450 may produce a seed pulse of light at 1555 nm, and the optical amplifier 460 may amplify the seed pulse of light to produce a subsequent emitted pulse of light 400 having a 1555-nm wavelength. The optical amplifier 460 in FIG. 52 may include a SOA 460a, a fiber-optic amplifier 460b, or a SOA 460a followed by a fiber-optic amplifier 460b. For example, the light source 110 in FIG. 52 may be similar to the light source 110 in FIG. 50, where the seed laser diode 450 is an SG-DBR laser and the optical amplifier 460 includes a SOA 460a that amplifies the seed light 440 produced by the SG-DBR laser. Additionally, the SG-DBR laser 450 and the SOA 460a may be integrated together so that the seed light 440 is coupled from the front mirror 488 of the SG-DBR laser directly into an input end 461 of the SOA 460a. Alternatively, the light source 110 in FIG. 52 may include a modulator or passive optical waveguide (not illustrated in FIG. 52) located between the SG-DBR laser 450 and the SOA 460a, and the modulator or passive waveguide may convey the seed light 440 from the front face 452 of the SG-DBR laser to the input end 461 of the SOA 460a.

A light source 110 of a lidar system 100 may be a wavelength-tunable light source that emits pulses of light 400, where each pulse of light has a particular wavelength of multiple different wavelengths. For example, each pulse of light 400 emitted by a wavelength-tunable light source 110 may have a particular wavelength of 2, 5, 10, 20, 50, 100, 500, or any other suitable number of different wavelengths. The different wavelengths may be distributed over any suitable wavelength range, such as for example, between 900 nm and 2000 nm, between 1400 nm and 1600 nm, or between 1530 nm and 1560 nm. Additionally, the pulses of light 400 emitted by a wavelength-tunable light source 110 may have one or more of the following optical characteristics: a pulse energy between 0.01 μJ and 100 μJ; a pulse repetition frequency between 80 kHz and 10 MHz; and a pulse duration between 0.1 ns and 100 ns. The light source 110 in any of FIGS. 9, 16-19, 31, and 46-50 may be a wavelength-tunable light source. A lidar system 100 that includes a wavelength-tunable light source 110 may be referred to as a lidar system with a wavelength-tunable light source.

A wavelength-tunable light source 110 (which may be referred to as a tunable light source) may include a wavelength-tunable seed laser diode 450 that produces seed light 440 at multiple different wavelengths. The seed light 440 may be amplified by an optical amplifier 460 to produce an output beam 125 that includes pulses of light 400, each emitted pulse of light having a particular wavelength of the multiple different wavelengths. For example, a wavelength-tunable seed laser 450 may produce a first seed pulse of light at a first wavelength (e.g., 1545 nm), and an optical amplifier 460 may amplify the first seed pulse of light to produce a first emitted pulse of light 400 at the first wavelength. The wavelength-tunable seed laser 450 may then produce a second seed pulse of light at a second wavelength (e.g., 1550 nm) that is different from the first wavelength, and the optical amplifier 460 may amplify the second seed pulse of light to produce a second emitted pulse of light 400 at the second wavelength.

A wavelength-tunable seed laser diode 450 may include any suitable laser diode configured to produce seed light 440 at multiple different wavelengths. For example, a wavelength-tunable seed laser diode 450 may include a wavelength-tunable distributed Bragg reflector (DBR) laser, a wavelength-tunable SG-DBR laser (as illustrated in FIG. 52), wavelength-tunable VCSEL, a wavelength-tunable external-cavity laser diode (e.g., an external-cavity laser diode may include an intracavity diffraction grating or electro-optic device that provides wavelength tuning). A wavelength-tunable seed laser diode 450 may refer to a laser diode that is capable of producing seed light 440 at multiple different wavelengths. For example, a wavelength-tunable seed laser diode 450 may be configured to produce seed light 440 at multiple different wavelengths between 1530 nm and 1560 nm.

An SG-DBR laser 450 (which may be referred to as a laser diode, a seed laser, or a seed laser diode) may be a wavelength-tunable seed laser diode that is configured to produce seed light 440 at multiple different wavelengths. The SG-DBR laser 450 in FIG. 52 includes a back mirror 482, a phase section 484, a gain section 486, and a front mirror 488, where the phase and gain sections are located between the front and back mirrors. A wavelength-tunable light source 110 may include an electronic driver 480 that supplies particular combinations of electrical currents to the back mirror 482, phase section 484, gain section 486, and front mirror 488, where each particular combination of electrical currents causes the SG-DBR laser 450 to produce seed light 440 at a particular wavelength of multiple different wavelengths. The electrical currents supplied to an SG-DBR laser 450 may be referred to collectively as the seed current I₁ and may include the following: current I_{b} supplied to the back mirror 482, current Iₚ supplied to the phase section 484, current I_{g} supplied to the gain section 486, and current I_{f} supplied to the front mirror 488. The gain-current I_{g} may produce and provide optical gain to the seed light 440 while the seed light propagates along the waveguide 454 of the SG-DBR laser 450. For example, the gain-current I_{g} may include pulses of electrical current, where each pulse of electrical current supplied to the gain section 486 causes the SG-DBR laser 450 to produce a seed pulse of light. Each seed pulse of light may have a particular wavelength that is determined by the currents I_{b}, Iₚ, and I_{f}. The seed pulses of light may be coupled to a SOA 460a, and the electronic driver 480 may supply pulses of electrical current to the SOA, where each pulse of current causes the SOA 460a to amplify one seed pulse of light to produce a corresponding emitted pulse of light 400. Each emitted pulse of light 400 may have a wavelength that matches or is approximately equal to the wavelength of the corresponding seed pulse of light.

The wavelength of a seed pulse of light produced by a SG-DBR laser 450 may be determined by the currents I_{b}, Iₚ, and I_{f} supplied to the respective back mirror 482, phase section 484, and front mirror 488 of the SG-DBR laser. The gain-current I_{g} may include a pulse of current that results in the gain section 486 providing optical gain and producing a seed pulse of light that propagates along the waveguide 454 back and forth within the SG-DBR laser 450. The back mirror 482 and the front mirror 488 may each act as a distributed mirror similar to a distributed Bragg reflector, and the seed pulse of light may be at least partially reflected by the back and front mirrors as it propagates along the waveguide 454. The wavelength of a seed pulse of light may be selected by applying particular values of the currents I_{b}, Iₚ, and I_{f} to the SG-DBR laser 450. For example, a controller 150 may store a look-up table that includes combinations of current values for I_{b}, Iₚ, and I_{f} that result in a seed pulse of light having a particular wavelength. By instructing the electronic driver 480 to supply particular values of the currents I_{b}, Iₚ, and I_{f} to the SG-DBR laser 450, a seed pulse of light with a particular corresponding wavelength may be produced. The controller 150 may provide instructions to the electronic driver 480 to switch between different values of the currents I_{b}, Iₚ, and I_{f} to produce seed pulses of light having different wavelengths. For example, adjusting a current supplied to the back mirror 482, phase section 484, or front mirror 488 may switch the SG-DBR laser 450 from a currently tuned first wavelength to a desired second wavelength. The SG-DBR laser 450 may be capable of switching wavelengths on a nanosecond time scale, allowing a light source 110 to have fast wavelength agility and to produce emitted pulses of light 400 having different wavelengths. For example, a light source 110 with a SG-DBR seed laser 450 may produce pulses of light 400 at a 500-kHz pulse repetition frequency, and the SG-DBR seed laser may be operated so that the wavelengths of the emitted pulses of light 400 change from pulse to pulse. Each emitted pulse of light 400 may have a different wavelength than one or more of the immediately preceding pulses of light and one or more of the immediately following pulses of light.

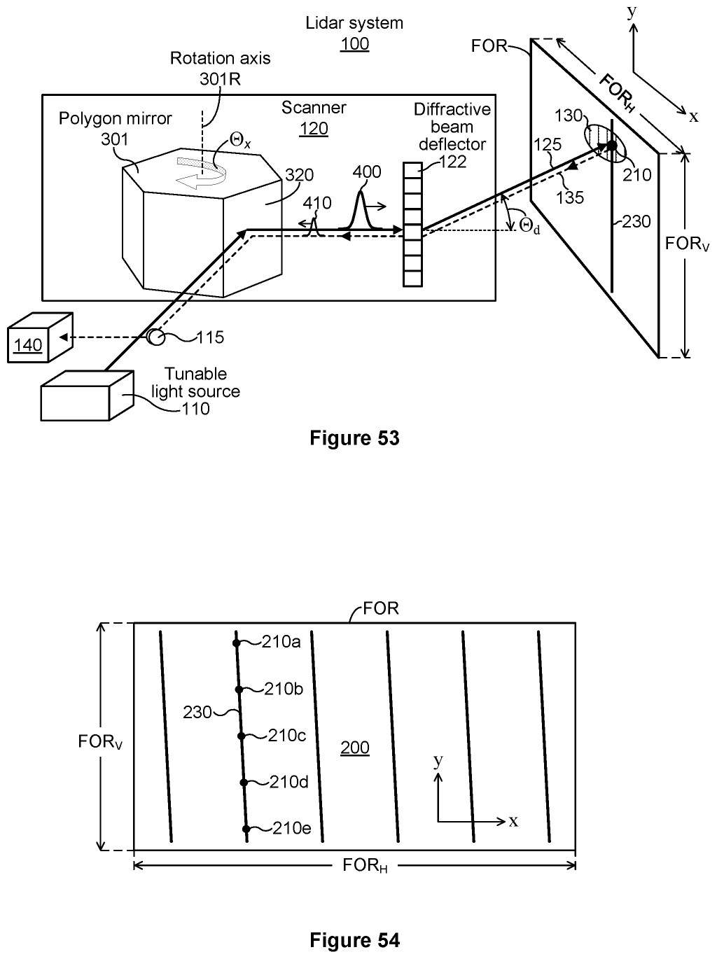

FIG. 53 illustrates an example lidar system 100 with a tunable light source 110 and a diffractive beam deflector 122. The lidar system 100 includes a wavelength-tunable light source 110 that emits pulses of light 400, where each pulse of light has a particular wavelength of multiple different wavelengths. For example, the tunable light source 110 in FIG. 53 may be similar to that illustrated in FIG. 52. The lidar system 100 in FIG. 53 may be referred to as a lidar system with a wavelength-tunable light source 110. The lidar system 100 also includes a scanner 120 that scans the output beam 125 (which includes emitted pulses of light 400) across the FOR of the lidar system. The scanner includes a polygon scan mirror 301 and a diffractive beam deflector 122. The diffractive beam deflector angularly deflects each emitted pulse of light 400 along the y-axis according to the wavelength of the pulse of light, and the polygon scan mirror 301 scans the output beam 125 along the x-axis. In FIG. 53, the emitted pulse of light 400 is deflected along the y-axis by an angle of Od with respect to the path of the output beam 125 prior to encountering the beam deflector 122, where the deflection angle Θ_{d} depends on the wavelength of the pulse of light. For example, a pulse of light 400 with a 1550-nm wavelength may be deflected by 2°, and a pulse of light with a 1555-nm wavelength may be deflected by 4°. In FIG. 53, the output beam 125 is first directed to the scan mirror 301 where it is reflected by a reflective surface 320, and then the output beam is directed to the diffractive beam deflector 122. In other embodiments, the output beam 125 may first encounter a diffractive beam deflector 122 and then be directed to a reflective surface 320 of a scan mirror 301. For example, the beam deflector 122 in FIG. 16 may be a diffractive beam deflector that first scans the output beam 125 along the y-axis based on wavelength, after which the output beam is directed to the polygon scan mirror 301.

A diffractive beam deflector 122 may include a diffractive optical element that deflects a pulse of light 400 at an angle that depends on the wavelength of the pulse of light. Rather than using a moving mirror that pivots or rotates to scan an output beam 125, a diffractive beam deflector 122 may scan an output beam using wavelength-dependent beam deflection that does not require moving parts. The angular deflection of a pulse of light 400 by a diffractive beam deflector 122 may be caused by optical diffraction, dispersion, or refraction. For example, a diffractive beam deflector 122 may include a diffraction grating (e.g., a transmissive or reflective diffraction grating), a prism, a grating prism (“grism”), a photonic crystal, an arrayed waveguide grating, a holographic optical element, or any other suitable optical element configured to diffract or deflect incident light at an angle according to the wavelength of the incident light. A diffractive beam deflector 122 may be referred to as a grating beam deflector, a wavelength-based beam deflector, a spectral beam deflector, or a beam deflector. The beam deflector 122 in any of FIGS. 16-27, 34-37, and 42-45 may be a diffractive beam deflector.

FIG. 54 illustrates an example scan pattern 200 produced by the lidar system 100 of FIG. 53. The scan pattern 200 includes six scan lines 230 that are each oriented substantially along the y-axis. The light source 110 may emit pulses of light 400 having different wavelengths, and the diffractive beam deflector 122 may produce the scan lines 230 by angularly deflecting the pulses of light along the y-axis according to wavelength. The scan lines 230 are distributed along the x-axis by the polygon scan mirror 301. One of the scan lines 230 is illustrated with an example five pixels (210a, 210b, 210c, 210d, 210e), and each pixel may correspond to an emitted pulse of light 400 having a particular wavelength. For example, pixels 210a, 210b, 210c, 210d, and 210e may be associated with pulses of light 400 having the respective wavelengths 1540 nm, 1542 nm, 1544 nm, 1546 nm, and 1548 nm. The polygon scan mirror 301 in FIG. 53 may be a polygon mirror with non-angled faces, and the tunable light source 110 and the diffractive beam deflector 122 may be configured to scan the output beam 125 along the y-axis over approximately the full angular extent of FOR_{V}. Alternatively, the polygon scan mirror 301 in FIG. 53 may be a polygon mirror with angled faces, and the FOR in FIG. 54 may be subdivided into multiple regions 240 (e.g., similar to that illustrated in FIGS. 32-37). In this embodiment, the tunable light source 110 and the diffractive beam deflector 122 may be configured to scan the output beam 125 along the y-axis over a portion of the angular extent of FOR_{V} (e.g., over an angular range α as illustrated in FIGS. 32-37).

The receiver 140 in FIG. 53 is configured to receive the input beam 135 and detect received pulses of light that are part of the input beam. The received pulse of light 410 may include a portion of the emitted pulse of light 400 scattered by a target 130, and a processor 150 may determine the distance to the target based on the time of arrival of the received pulse of light. The receiver 140 may include one or more detectors 340 that each receive a portion of the pulse of light 410 and produce a photocurrent signal corresponding to the received pulse of light. The receiver 140 may also include one or more electronic amplifiers 350 and a pulse-detection circuit 365 (e.g., as illustrated in FIGS. 6-8).

In FIG. 53, the input beam 135, which may include multiple received pulses of light 410 having multiple different wavelengths, travels through the scanner 120 prior to being directed to the receiver 140. The received pulses of light 410 travel through the diffractive beam deflector 122 and then reflect from a reflective surface 320 of the polygon scan mirror 301. Since the diffractive beam deflector 122 angularly deflects each emitted pulse of light 400 according to wavelength, each received pulse of light 410 may also be angularly deflected according to wavelength by the beam deflector. The diffractive beam deflector 122 may angularly deflect each received pulse of light 410 according to wavelength so that upon exiting the scanner 120, the received pulses of light are directed to the receiver 140 along a common propagation axis. For example, two emitted pulses of light 400 with wavelengths 1540 nm and 1545 nm may be deflected by 2° and 4°, respectively, and two corresponding received pulses of light 410 (with approximately the same respective wavelengths as the emitted pulses of light) may also be deflected by 2° and 4°, respectively, so that after the beam deflector 122, the two received pulses propagate along approximately the same axis. In FIG. 53, the common propagation axis is indicated by the portion of the dashed line of the input beam 135 located between the scanner 120 and the receiver 140. Each received pulse of light 410 from the pixels 210a-210e in FIG. 54 may be incident on the beam deflector 122 in FIG. 53 at a different angle, and each received pulse of light may be angularly deflected by the beam deflector so that they propagate along a common propagation axis as represented by the input beam 135 located between the scanner 120 and the receiver 140. Since the received pulses of light 410 enter the receiver 140 directed along the same propagation axis, the receiver 140 may include a detector 340 configured to detect at least a portion of each of the received pulses of light regardless of wavelength.

A lidar system 100 with a wavelength-tunable light source 110 and a diffractive beam deflector 122 may include a receiver 140 with a one-dimensional detector array 342. For example, the lidar system 100 in any of FIGS. 9, 16-19, and 30, in which the receiver 140 includes a one-dimensional detector array 342, may include a wavelength-tunable light source 110 and a diffractive beam deflector 122. A received pulse of light 410 may be incident on one or more detector elements 340 of the detector array 342, and each of the one or more detector elements may produce a photocurrent signal corresponding to the received pulse of light. Photocurrent signals produced by the detector elements 340 of a detector array 342 may be coupled to an amplifier 350, which in turn may be coupled to a pulse-detection circuit 365. For example, each detector element 340 of a detector array 342 may be coupled to a TIA 352 of an amplifier 350. A detector array 342 with N detector elements 340 may be coupled to an amplifier 350 with N TIAs 352, where each detector element is coupled to one of the TIAs. Alternatively, the detector elements 340 of a detector array 342 may be coupled to an amplifier 350 through a switch or multiplexer 344 (e.g., as illustrated in FIG. 14). The multiplexer 344 may be reconfigured in synch with the wavelengths of the emitted pulses of light 400. For example, the multiplexer 344 may be reconfigured to couple particular detector elements 340 to an amplifier 350 based on the wavelength of an emitted pulse of light 400 (which may correspond to the wavelength of a received pulse of light 410 that is expected to be detected by the receiver 140). As pulses of light 400 with different wavelengths are emitted and the output beam 125 is scanned to different locations along the y-axis, the multiplexer 344 may dynamically change the selected detector elements 340 accordingly based on the wavelengths of the emitted pulses of light.

A lidar system 100 with a wavelength-tunable light source 110 and a diffractive beam deflector 122 may be configured so that an input beam 135, prior to being directed to a receiver 140, bypasses the beam deflector. For example, the lidar system 100 in any of FIGS. 16-19 and 30, in which the input beam 135 bypasses the beam deflector 122, may include a wavelength-tunable light source 110, and the beam deflector 122 may be a diffractive beam deflector. As another example, the scanner 120 in any of FIGS. 20-27 in which the input beam 135 bypasses the beam deflector 122 may be part of a lidar system 100 that includes a wavelength-tunable light source 110, and the diffractive beam deflector 122 may be a diffractive beam deflector. A lidar system 100 in which the input beam 135 bypasses the diffractive beam deflector 122 may include a one-dimensional detector array 342. Each detector element 340 of the detector array 342 may be configured to detect received pulses of light 410 that have a particular wavelength of the multiple wavelengths of light produced by the wavelength-tunable light source 110.

The lidar system 100 in FIGS. 16-17 includes a one-dimensional detector array 342, and the input beam 135, prior to being directed to the receiver 140, is reflected by the polygon scan mirror 301 and bypasses the beam deflector 122. The light source 110 in FIGS. 16-17 may be a wavelength-tunable light source, and the beam deflector 122 may be a diffractive beam deflector that angularly deflects each emitted pulse of light 400 along the y-axis according to the wavelength of the pulse of light. The input beam 135 bypasses the beam deflector 122 and is directed to the receiver 140, which includes a one-dimensional detector array 342 with detector elements 340 arranged along a direction corresponding to the y-axis. The wavelength-tunable light source 110 may emit pulses of light 400 having multiple different wavelengths, and each detector element 340 may be configured to detect received pulses of light 410 having a particular wavelength of the multiple different wavelengths. For example, in FIG. 17, the emitted pulses of light 400a, 400b, and 400c may have wavelengths 1545 nm, 1550 nm, and 1555 nm, respectively, and the received pulses of light 410a, 410b, and 410c may have approximately the same wavelengths (1545 nm, 1550 nm, and 1555 nm, respectively) as the corresponding emitted pulses of light. Since the received pulses of light 410 bypass the diffractive beam deflector, the input beams 135 may not have a common propagation axis, and each received pulse of light may enter the receiver at a particular angle corresponding to the wavelength of the pulse of light. As a result, each received pulse of light 410 may be directed to one or more particular detector elements 340 according to the wavelength of the pulse of light. For example, in FIG. 17, detector elements 340a, 340b, and 340c are configured to detect the received pulses of light 410a, 410b, and 410c, respectively. This corresponds to detector element 340a being configured to detect received pulses of light with wavelength 1545 nm. Any received pulse of light 410 with a wavelength of approximately 1545 nm may be directed to and detected by detector element 340a. Similarly, detector element 340b is configured to detect received pulses of light with wavelength 1550 nm, and detector element 340c is configured to detect received pulses of light with wavelength 1555 nm.

The detector array 342 in FIG. 17 may include a variable optical filter 346v that transmits particular wavelengths of light to the detector elements 340, where the particular transmitted wavelengths vary with position along the detector array. For example, at or near detector element 340a, the variable optical filter 346v may have an AR coating that transmits light at 1545 nm, the wavelength of received pulse of light 410a. Additionally, at that location, the variable optical filter 346v may reflect light at the other wavelengths (e.g., the optical filter may have a reflectivity of greater than 80% at 1550 nm and 1555 nm), which may reduce optical cross-talk between the detector elements. Similarly, at or near detector element 340b, the variable optical filter 346v may have an AR coating that transmits light at 1550 nm (the wavelength of received pulse of light 410b) and reflects light at 1545 nm and 1555 nm. Additionally, at or near detector element 340c, the variable optical filter 346v may have an AR coating that transmits light at 1555 nm (the wavelength of received pulse of light 410c) and reflects light at 1545 nm and 1550 nm.

The lidar system 100 in FIG. 17 may include a wavelength-tunable light source 110 and a diffractive beam deflector 122. Additionally, the lidar system 100 may include a diffractive optical element located in the path of the input beams 135 and not in the path of the output beams 125. The diffractive optical element, which may be similar to a diffractive beam deflector, may provide angular deflection to each received pulse of light 410 according to wavelength. In FIG. 17, the receiver 140 may include a diffractive optical element (not illustrated in FIG. 17) that provides additional angular separation of the received pulses of light 410a, 410b, and 410c so that they are spaced farther apart along the y-axis when they are incident on the detector array 342. A diffractive optical element may reduce optical cross-talk between the detector elements of the detector array by providing additional spatial separation of the received pulses of light 410.

A lidar system 100 with a wavelength-tunable light source 110 and a diffractive beam deflector 122 may be configured so that an input beam 135 bypasses the scanner 120. Additionally, a lidar system 100 in which the input beam 135 bypasses the scanner 120 may include a receiver 140 with a two-dimensional detector array 342. The lidar system 100 in FIG. 31 includes a two-dimensional detector array 342, and the input beam 135 bypasses the scanner 120. The light source 110 in FIG. 31 may be a wavelength-tunable light source, and the scanner 120 may include a diffractive beam deflector 122 that angularly deflects each emitted pulse of light 400 along the y-axis according to wavelength. The wavelength-tunable light source 110 may emit pulses of light 400 having multiple different wavelengths, and the detector elements 340 in each row of the detector array 342 may be configured to detect received pulses of light 410 having a particular wavelength of the multiple different wavelengths. For example, the light source 110 in FIG. 31 may emit pulses of light 400 with wavelengths from 1530 nm to 1560 nm, and each received pulse of light 410 may be directed to one or more rows of the detector array 342 according to wavelength. The rows of the detector array 342 are arranged along the y-axis, which is the axis along which the emitted pulses of light 400 are deflected according to wavelength. The top row of the detector array 342 may be configured to detect received pulses of light with wavelength 1530 nm, and the bottom row may be configured to detect received pulses of light with wavelength 1560 nm. Each row between the top and bottom rows may be configured to detect light at a particular wavelength between 1530 nm and 1560 nm. Received pulses of light 410 with a wavelength of approximately 1530 nm may be directed to and detected by one or more detector elements 340 located in the top row of the detector array 342, and received pulses of light with a wavelength of approximately 1560 nm may be directed to and detected by one or more detector elements located in the bottom row of the detector array. In some embodiments, the detector elements 342 in each row of a two-dimensional detector array 342 may be configured to detect received pulses of light 410 having one particular wavelength (e.g., the top row in FIG. 31 may be configured to detect light at 1530 nm) or two or more particular wavelengths (e.g., the top row in FIG. 31 may be configured to detect light at 1530 nm and 1535 nm). In some embodiments, the detector elements 342 in two or more rows of a two-dimensional detector array 342 may be configured to detect received pulses of light 410 having one particular wavelength (e.g., the top two rows in FIG. 31 may both be configured to detect light at 1530 nm). The detector array 342 in FIG. 31 may include a variable optical filter 346v that transmits particular wavelengths of light to the detector elements 340 in each row, where the particular transmitted wavelengths vary with position along the y-axis. For example, along the top row, the variable optical filter 346v may have an AR coating that transmits light at 1530 nm and reflects light at 1535-1560 nm. Similarly, along the bottom row, the variable optical filter 346v may have an AR coating that transmits light at 1560 nm and reflects light at 1530-1555 nm.

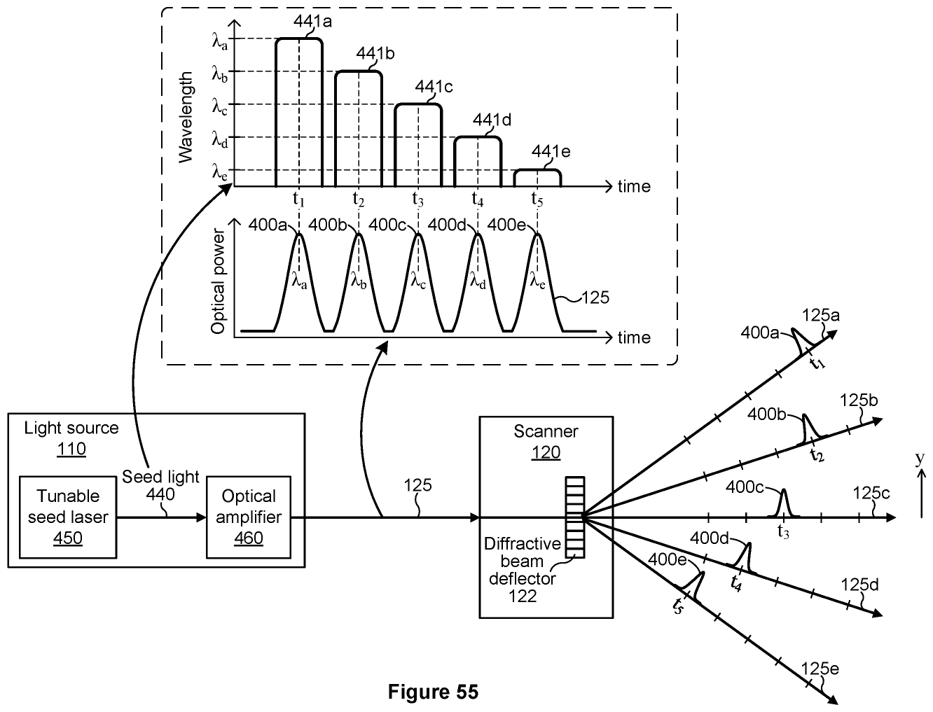

FIGS. 55-59 each illustrate an example light source 110 and scanner 120 that produces pulses of light 400 with different wavelengths that are directed in different directions along the y-axis. The light source 110 in each of FIGS. 55-59 is a wavelength-tunable light source that includes a wavelength-tunable seed laser diode 450 and an optical amplifier 460. For example, the light source 110 may include a SG-DBR laser 450 and a SOA 460a and may be similar to the wavelength-tunable light source 110 illustrated in FIG. 52. The tunable seed laser diode 450 in FIGS. 55-59 produces seed light 440 at multiple different wavelengths, and the optical amplifier 460 amplifies the seed light to produce an output beam 125 that includes pulses of light 400 having multiple different wavelengths. The emitted pulses of light 400a, 400b, 400c, 400d, and 400e have respective wavelengths λₐ, λ_{b}, λ_{c}, λ_{d}, and λₑ. For example, the emitted pulses of light 400a, 400b, 400c, 400d, and 400e may have respective wavelengths 1560 nm, 1555 nm, 1550 nm, 1545 nm, and 1540 nm. The scanner 120 includes a diffractive beam deflector 122 that angularly deflects each emitted pulse of light 400 along the y-axis according to the wavelength of the pulse of light. The five emitted pulses of light 400a-400e (along with their associated output beams 125a-125e) are distributed spatially along the y-axis, and the five emitted pulses of light are distributed temporally at times t₁, t₂, t₃, t₄, and t₅. The scanner 120 may also include a scan mirror 301 (not illustrated in FIGS. 55-59) that scans the output beam 125 along an x-axis. The light source 110 and scanner 120 in each of FIGS. 55-59 may be part of a lidar system 100 that includes a receiver 140 configured to detect received pulses of light 410.

The dashed-line inset in each of FIGS. 55-59 includes two graphs: the upper graph illustrates the wavelength of the seed light 440 versus time, and the lower graph illustrates the optical power of the corresponding output beam 125 versus time, including the pulses of light 400 associated with the output beam. The output beam 125 includes five emitted pulses of light 400a-400e, and after the output beam 125 passes through the diffractive beam deflector 125, the pulses of light are angularly deflected along the y-axis according to wavelength. For example, emitted pulse of light 400a may be directed to an upper part of a FOR, emitted pulse of light 400b may be directed to an upper-middle part of the FOR, and emitted pulse of light 400c may be directed to a middle part of the FOR. Additionally, emitted pulse of light 400d may be directed to a lower-middle part of the FOR, and emitted pulse of light 400e may be directed to a lower part of the FOR.

In FIG. 55, the wavelength-tunable seed laser 450 produces seed light 440 as individual seed pulses of light 441a-441e with wavelengths λₐ to λₑ. The optical amplifier 460 amplifies each of the seed pulses of light 441a-441e to produce the emitted pulses of light 400a-400e having the respective wavelengths λₐ to λₑ. At time t₁, the seed laser 450 produces a seed pulse of light 441a with wavelength λₐ, and the optical amplifier 460 amplifies the seed pulse of light to produce the emitted pulse of light 400a with approximately the same wavelength λₐ. At times t₂, t₃, t₄, and t₅, the seed laser 450 produces seed pulses of light 441b, 441c, 441d, and 441e with the respective wavelengths λ_{b}, λ_{c}, λ_{d}, and λₑ, and the optical amplifier 460 amplifies the seed pulses of light to produce the respective emitted pulses of light 400b, 400c, 400d, and 400e. The tunable seed laser 450 may be a SG-DBR laser, and an electronic driver 480 may provide pulses of current I_{g} to the gain section 486, where each pulse of current produces one of the seed pulses of light 441. Between successive pulses of light 400, the electronic driver 480 may provide little or no current I_{g} to the gain section 486, and the currents I_{b}, Iₚ, and I_{f} supplied to the other sections may be adjusted to configure the SG-DBR laser to emit a seed pulse of light 441 at the next desired wavelength. The optical amplifier 460 may include a SOA 460a, and the electronic driver 480 may supply pulses of current I₂ to the SOA in synch with the pulses of current I_{g} supplied to the SG-DBR laser. Each pulse of current I₂ supplied to the SOA 460a may cause the SOA to optically amplify one of the seed pulses of light 441 to produce one of the emitted pulses of light 400. Each emitted pulse of light 400 may have a wavelength that matches or is approximately equal to the wavelength of a corresponding seed pulse of light 441. For example, the seed pulse of light 441a may have a wavelength λₐ, and the corresponding emitted pulse of light 400a may have approximately the same wavelength.

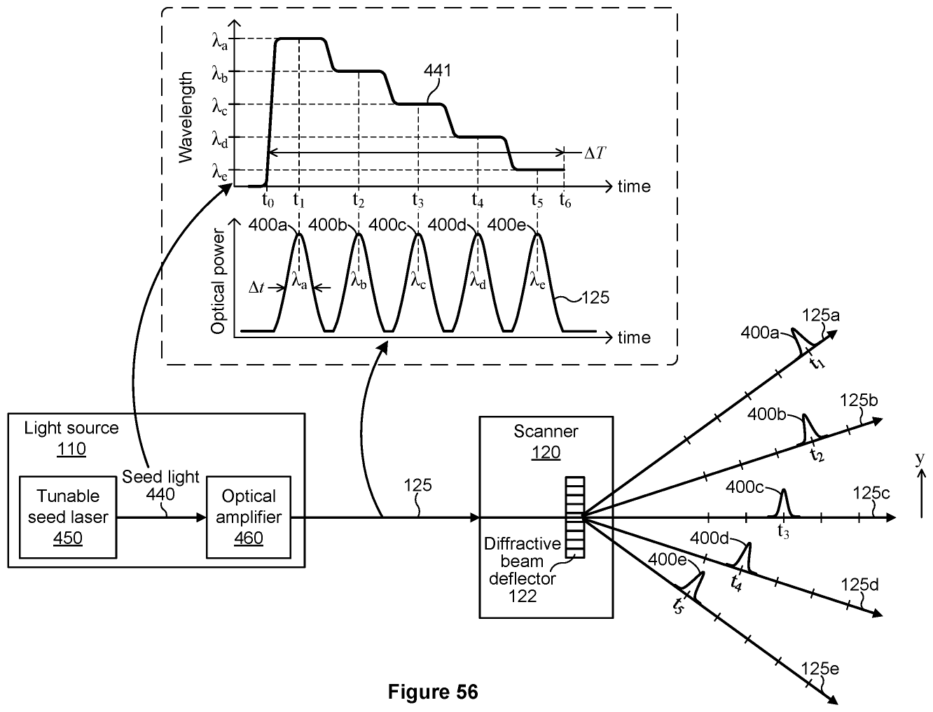

In FIG. 56, the wavelength-tunable seed laser 450 produces seed light 440 that includes a single seed pulse of light 441. The seed pulse of light 441, which may be referred to as a wavelength-varying seed pulse of light, has a duration of ΔT and a time-varying wavelength that includes each of the five wavelengths from λₐ to λₑ. The seed laser 450 may be a SG-DBR laser, and an electronic driver 480 may supply a single pulse of current I_{g} to the gain section 486 to produce the seed pulse of light 441. The seed-laser current I_{g} may be substantially constant between times t₀ and t₆, and the seed pulse of light 441 may have a substantially constant optical power over that time period. The currents I_{b}, Iₚ, and I_{f} supplied to the other sections of the SG-DBR laser 450 may cause the seed pulse of light 441 to have a time-varying wavelength that includes each of the five wavelengths from λₐ to λₑ. In FIG. 56, the wavelength of the seed pulse of light 441 is changed monotonically from wavelength λₐ to wavelength λₑ in a stepped sequence having a wavelength plateau at each of the times t₁-t₅. The electronic driver 480 may supply pulses of current I₂ to the SOA 460a, where each pulse of current supplied to the SOA causes the SOA to optically amplify a temporal portion of the seed pulse of light 441 to produce one of the emitted pulses of light 400, where the emitted pulse of light has a wavelength that is approximately equal to the wavelength of the temporal portion of the seed pulse of light 441. For example, the electronic driver 480 may supply P pulses of current I₂ to the SOA 460a while a single pulse of current I_{g} is supplied to the gain section 486 so that the SOA optically amplifies P temporal portions of the seed pulse of light 441 to produce P emitted pulses of light 400, where P is an integer greater than or equal to 2. In FIG. 56, the parameter P is 5, and the optical amplifier 460 amplifies five temporal portions of the seed pulse of light 441 to produce five emitted pulses of light 400a-400e having the respective wavelengths λₐ to λₑ. The duration ΔT of the single seed pulse of light 441 may be greater than or equal to the sum of the durations of each of the P emitted pulses of light 400. For example, if the average duration of the P emitted pulses of light 400 is Δt, then the wavelength-varying seed pulse of light may have a duration ΔT that is greater than or equal to P×Δt.

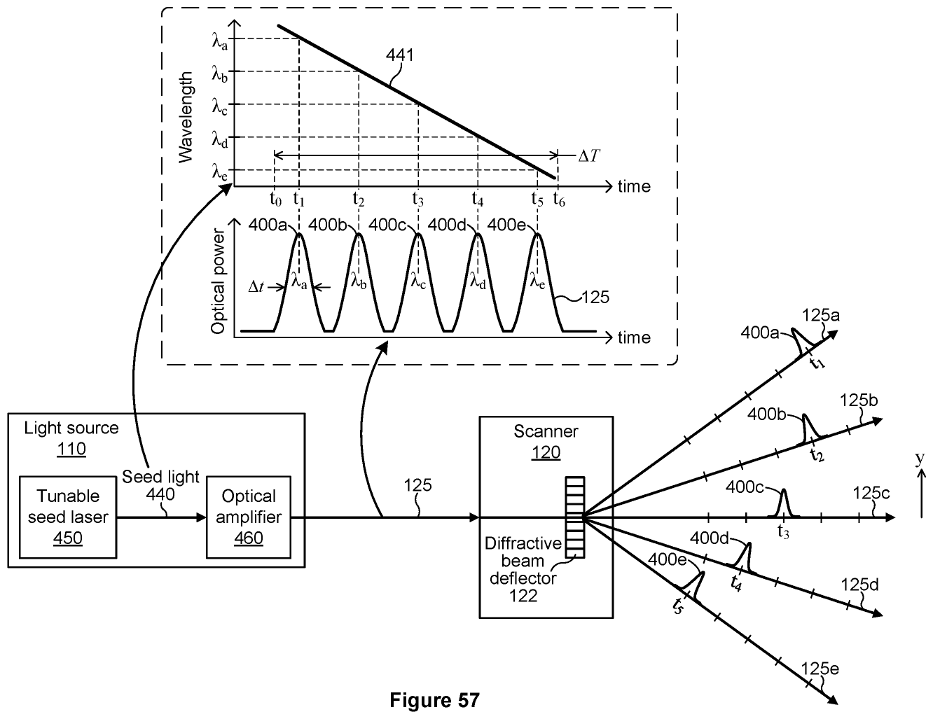

In FIG. 57, the wavelength-tunable seed laser 450 produces a single wavelength-varying seed pulse of light 441 that includes each of the five wavelengths from λₐ to λₑ. The optical amplifier 460 amplifies five temporal portions of the seed pulse of light to produce five corresponding emitted pulses of light 400a-400e. The example embodiment in FIG. 57 is similar to that in FIG. 56, except instead of changing the wavelength of the seed pulse of light 441 in a stepped-wavelength sequence (as in FIG. 56), the wavelength of the seed pulse of light 441 is changed in a substantially continuous manner. In FIG. 57, from time t₀ to time t₆, the wavelength of the seed pulse of light 441 is changed approximately linearly and monotonically from wavelength λₐ to wavelength λₑ. In FIG. 56, one or more of the currents I_{b}, Iₚ, and I_{f} supplied to a SG-DBR laser 450 may be adjusted between successive pulses of light 400 to configure the SG-DBR laser to emit seed light at the next desired wavelength. In FIG. 57, one or more of the currents I_{b}, Iₚ, and I_{f} may be adjusted substantially continuously from time t₀ to time t₆ to cause the seed-light wavelength to change substantially linearly with time.

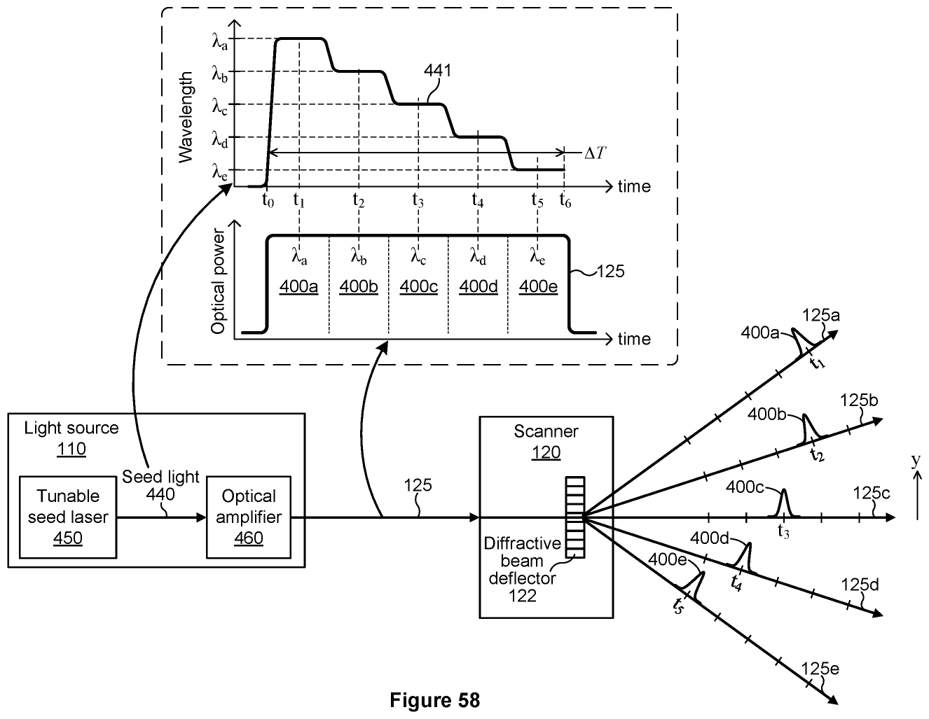

In FIG. 58, the wavelength-tunable seed laser 450 produces a single wavelength-varying seed pulse of light 441 that includes five wavelengths from λₐ to λₑ. For example, the seed laser 450 may be a SG-DBR laser, and an electronic driver 480 may supply currents I_{b}, Iₚ, and I_{f} to the SG-DBR laser so that the seed pulse of light 441 has a time-varying wavelength that includes each of the five wavelengths from λₐ to λₑ. Additionally, the electronic driver 480 may supply a single pulse of current I₂ to a SOA 460a to optically amplify the wavelength-varying seed pulse of light 441 to produce an amplified pulse of light that includes each of the five wavelengths. The duration of the seed pulse of light 441 (ΔT), the duration of the single pulse of current supplied to the SOA 460a, and the duration of the amplified pulse of light emitted by the SOA may be approximately equal. Rather than apply five pulses of current to a SOA 460a to produce five distinct pulses of light 400 (e.g., as in FIGS. 55-57), the light source 110 in FIG. 58 may produce a single amplified pulse of light that includes the five wavelengths λₐ to λₑ together. In FIG. 58, the wavelength of the amplified pulse of light changes from λₐ at the front of the pulse to λₑ at the back of the pulse. The diffractive beam deflector 122 then angularly deflects the wavelength components of the amplified pulse of light to produce five emitted pulses of light 400a-400e having the respective wavelengths λₐ to λₑ.

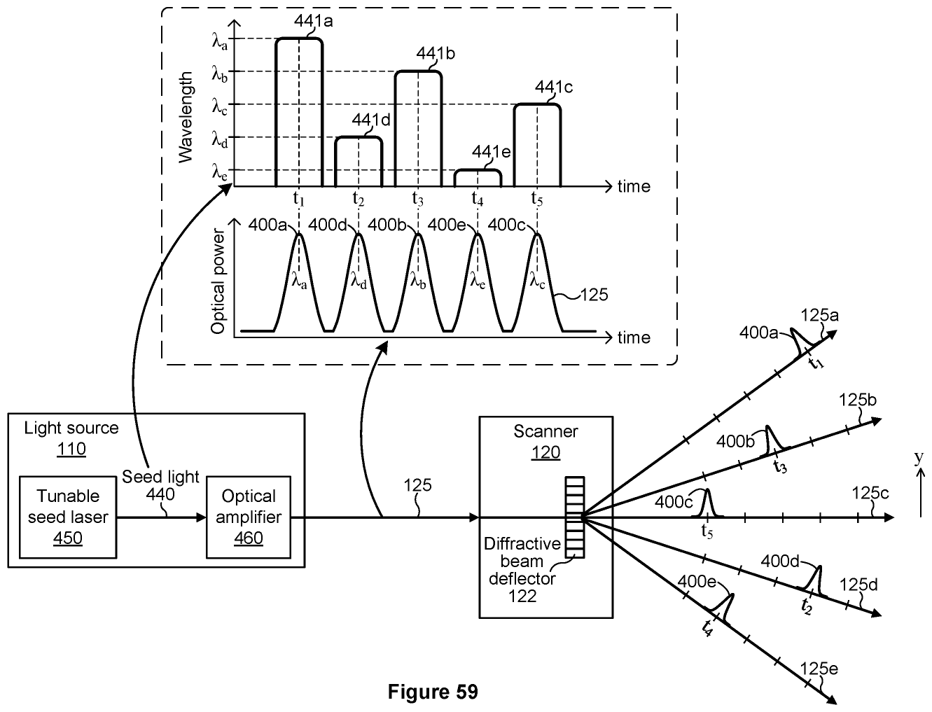

A wavelength-tunable light source 110 may emit a series of pulses of light 400 in a sequential wavelength order or in a non-sequential wavelength order. In each of FIGS. 55-58, the five emitted pulses of light 400a-400e are emitted in a sequential wavelength order from the longest wavelength pulse 400a with wavelength λₐ at time t₁ to the shortest wavelength pulse 400e with wavelength λₑ at time t₅. In FIG. 59, the light source 110 emits five pulses of light 400 in a non-sequential wavelength order as follows: pulse 400a, pulse 400d, pulse 400b, pulse 400e, and pulse 400c. The seed laser 450 may be a SG-DBR laser, and an electronic driver 480 may supply the currents I_{b}, Iₚ, and I_{f} to the SG-DBR laser so that the pulses of light are emitted in a non-sequential wavelength order. Emitting pulses of light 400 in a non-sequential wavelength order may allow for a lidar system 100 to perform dynamic or arbitrary scanning along the y-axis. Additionally, scanning along the y-axis with pulses emitted in a non-sequential wavelength order may provide a reduced amount of optical cross-talk between detector elements 340 in a detector array 342.

A wavelength-tunable light source 110 that emits a series of pulses of light 400 in a non-sequential wavelength order may emit pulses of light having W different wavelengths, where W is an integer greater than or equal to 4. To determine whether a series of pulses of light 400 emitted by a light source 110 are emitted in a non-sequential wavelength order, the pulses of light 400 may be grouped into multiple pairs of pulses of light. Each pair of pulses includes a first emitted pulse of light with a wavelength of λ₂ and a second emitted pulse of light, where the second pulse of light is emitted immediately after the first pulse of light with no intervening pulses of light between the pair of pulses. The W different wavelengths may include three adjacent wavelengths λ₁, λ₂, and λ₃, where λ₁>μ₂>λ₃, and λ₂ is the only wavelength of the W different wavelengths located between λ₁ and λ₃. For the emitted pulses of light 400 to be emitted in a non-sequential wavelength order, the second emitted pulse of light may have any of the W different wavelengths except for wavelengths λ₁, λ₂, and λ₃. If a pair of pulses is found to not satisfy the above relationship, then the series of emitted pulses of light 400 may not be considered to be emitted in a non-sequential wavelength order. Otherwise, if each pair of temporally adjacent pulses of light satisfies the above relationship, then the series of emitted pulses of light 400 may be considered to be emitted in a sequential wavelength order.

In FIGS. 55-59, the parameter W is 5 (corresponding to five different wavelengths), and wavelengths λₐ, λ_{b}, and λ_{c} represent three adjacent wavelengths where λₐ>λ_{b}>λ_{c}. In FIG. 55, pulses of light 400b and 400c represent a pair of pulses where pulse 400c is emitted immediately after pulse 400b. Since pulse of light 400c has wavelength kc, which is adjacent to wavelength kb of pulse 400b, the emitted pulses of light 400 in FIG. 55 may not be considered to be emitted in a non-sequential wavelength order. In FIG. 59, the pulses of light 400 may be considered to be emitted in a non-sequential wavelength order, since for each pair of temporally adjacent pulses of light, the second emitted pulse of light has a wavelength that is different from the wavelengths that correspond to λ₁, λ₂, and λ₃. For example, pulses of light 400b and 400e represent a pair of pulses where pulse 400e is emitted immediately after pulse 400b. The wavelengths λₐ, λ_{b}, and λ_{c} associated with pulse 400b are three adjacent wavelengths where λₐ>λ_{b}>λ_{c}. Since pulse of light 400e has wavelength λₑ, which is different from wavelengths λₐ, λ_{b}, and λ_{c}, the pair of pulses 400b and 400e satisfy the criteria for pulses of light emitted in a non-sequential wavelength order. By continuing this analysis for each pair of pulses of light 400 in the series of five pulses in FIG. 59, it may be determined that the pulses of light in FIG. 59 are emitted in non-sequential wavelength order.

An emitted pulse of light 400 may be referred to as having one wavelength or as having a particular wavelength. For example, a wavelength-tunable light source 110 may emit pulses of light 400 having multiple different wavelengths, where each emitted pulse of light has a particular wavelength of the multiple different wavelengths. The particular wavelength of an emitted pulse of light 400 may refer to a peak, center, or average wavelength of the pulse of light. For example, emitted pulse of light 400c in FIG. 55 may have peak wavelength λ_{c} of 1550 nm. Additionally, the emitted pulse of light 400c may have a wavelength that extends over a particular wavelength range around the peak wavelength, such as for example from 1549.95 nm to 1550.05 nm, which may be referred to as a spectral linewidth of 0.1 nm. In FIG. 57, the emitted pulse of light 400c may also have peak wavelength λ_{c} of 1550 nm. Since the wavelength of the temporal portion of the seed pulse of light 441 that is amplified to produce the emitted pulse of light 400c in FIG. 57 varies with time, the emitted pulse of light 400c in FIG. 57 may have a broader spectral linewidth than the emitted pulse of light 400c in FIG. 55. For example, the emitted pulse of light 400c in FIG. 57 may have a wavelength that extends from 1548 nm to 1552 nm, which corresponds to a 4-nm spectral linewidth. An emitted pulse of light 400 that is referred to as having one wavelength or as having a particular wavelength may have (i) a particular peak, center, or average wavelength and (ii) any suitable spectral linewidth, such as for example a spectral linewidth of less than or equal to 0.01 nm, 0.1 nm, 0.5 nm, 1 nm, 2 nm, 5 nm, or 10 nm.

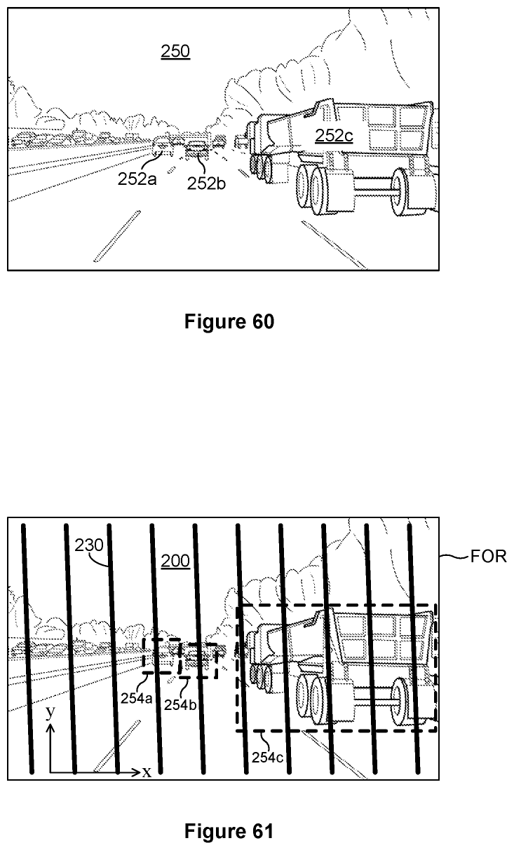

FIG. 60 illustrates an example scene 250 of a road. The scene includes vehicles 252a, 252b, and 252c.

FIG. 61 illustrates an example lidar-system scan of the road scene 250 of FIG. 60. The scan of the road scene includes a scan pattern 200 with multiple scan lines 230, where each scan line extends from the top to the bottom of the FOR. The three vehicles 252a, 252b, and 252c are identified in the lidar-system scan by the respective bounding boxes 254a, 254b, 254c.

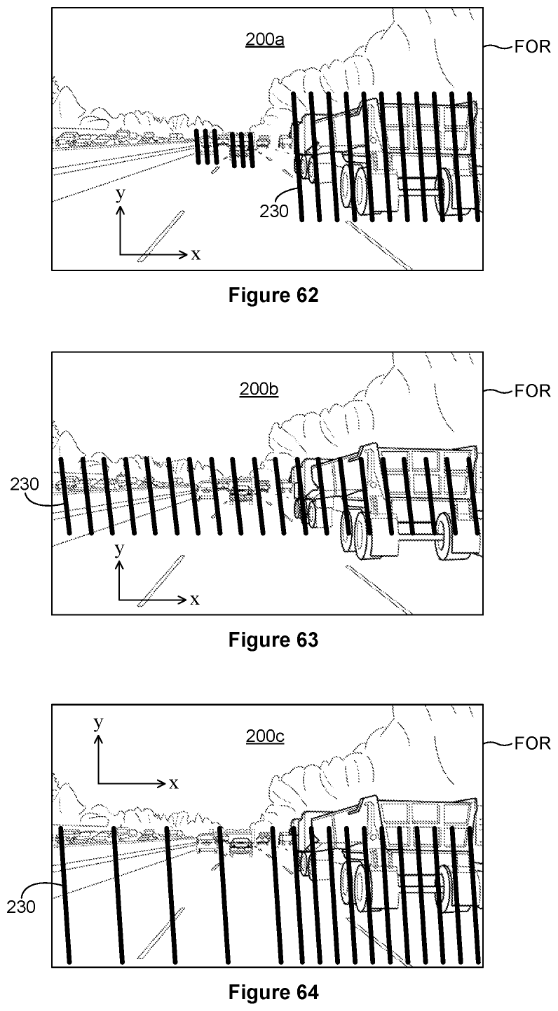

FIGS. 62-64 each illustrate an example focused lidar-system scan of the road scene of FIG. 60. Scan pattern 200a in FIG. 62 includes scans of each of the three vehicles 252a, 252b, and 252c. Scan pattern 200b in FIG. 63 includes a scan centered on the middle of the FOR including the three vehicles 252a, 252b, and 252c. Scan pattern 200c in FIG. 64 includes a scan of the lower part of the FOR with a varying density of the scan lines 230. The focused scan patterns 200a-200c may be produced by a lidar system 100 with adjustable focus. A lidar system 100 with adjustable focus may include a scanner 120 with a beam deflector 122, and the beam deflector may be configured to direct each emitted pulse of light 400 in a particular direction along one of the scan axes (e.g., the y-axis in FIGS. 62-64).

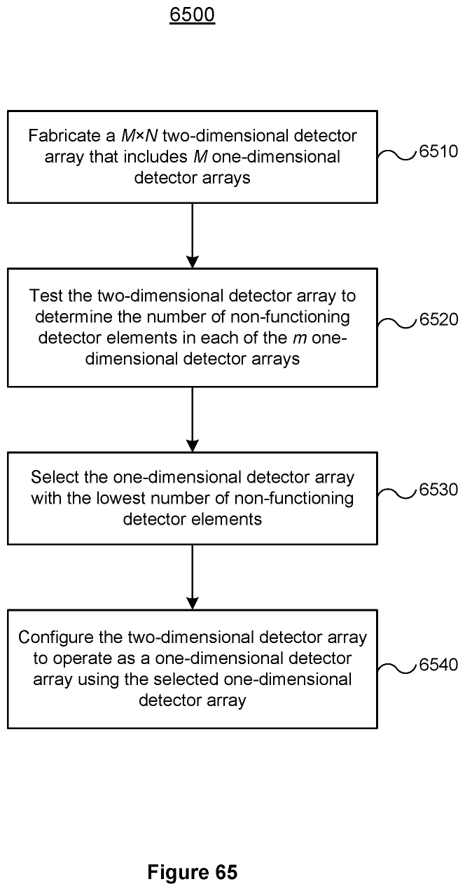

FIG. 65 illustrates an example method 6500 for manufacturing a one-dimensional detector array. The method 6500 may begin at step 6510, where a M×N two-dimensional detector array 342 is fabricated. The two-dimensional detector array 342 may include M one-dimensional detector arrays, where each one-dimensional detector array includes N detector elements. The parameter M is an integer greater than or equal to 2, and the parameter N is an integer greater than or equal to 4. In the example of FIG. 15, the parameter M equals 4, and the two-dimensional detector array 342 includes four one-dimensional detector arrays (342-1, 342-2, 342-3, and 342-4). At step 6520, the two-dimensional detector array is tested to determine the number of non-functioning detector elements 340 in each of the M one-dimensional detector arrays. A non-functioning detector element may have one or more of the following characteristics: an optical responsivity below a particular threshold responsivity value; a reverse-bias current above a particular threshold current value; an electrical short circuit; an electrical bandwidth below a threshold value; a physical defect; and an electrical-noise value above a particular noise threshold value. At step 6530, the one-dimensional detector array with the lowest number of non-functioning detector elements is selected. At step 6540, the two-dimensional detector array is configured to operate as a one-dimensional detector array using the selected one-dimensional detector array, at which point the method may end.

Various example aspects described below are directed to (i) a method for manufacturing a one-dimensional detector array 342 and (ii) a lidar system 100 with a one-dimensional detector array 342.

Aspect 1. A method for manufacturing a one-dimensional detector array, comprising: fabricating a M×N two-dimensional detector array comprising M one-dimensional detector arrays, each one-dimensional detector array comprising N detector elements, wherein M is an integer greater than or equal to 2, and N is an integer greater than or equal to 4; testing the two-dimensional detector array to determine a number of non-functioning detector elements in each of the M one-dimensional detector arrays; selecting one of the M one-dimensional detector arrays, the selected one-dimensional detector array having a lowest number of non-functioning detector elements; and configuring the two-dimensional detector array to operate as a one-dimensional detector array, the one-dimensional detector array comprising the selected one-dimensional detector array.

Aspect 2. The method of Aspect 1, wherein the two-dimensional detector array comprises silicon-germanium (SiGe) detector elements, silicon-germanium-tin (SiGeSn) detector elements, silicon (Si) detector elements, or indium-gallium-arsenide (InGaAs) detector elements.

Aspect 3. The method of Aspect 1, further comprising rejecting the two-dimensional detector array if the number of non-function detector elements in each of the M one-dimensional detector arrays exceeds a predetermine threshold amount or threshold percentage.

Aspect 4. The method of Aspect 1, wherein a non-functioning detector element has an optical responsivity below a particular threshold responsivity value.

Aspect 5. The method of Aspect 1, wherein a non-functioning detector element has a reverse-bias current above a particular threshold current value.

Aspect 6. The method of Aspect 1, wherein a non-functioning detector element has an electrical short circuit.

Aspect 7. The method of Aspect 1, wherein a non-functioning detector element has an electrical bandwidth below a threshold value.

Aspect 8. The method of Aspect 1, wherein a non-functioning detector element has a physical defect.

Aspect 9. The method of Aspect 1, wherein a non-functioning detector element has an electrical-noise value above a particular noise threshold value.

Aspect 10. The method of Aspect 1, further comprising depositing an optical filter onto the two-dimensional detector array, wherein the optical filter is configured to transmit particular wavelengths of light to the detector elements.

Aspect 11. The method of Aspect 1, further comprising depositing a variable optical filter onto the two-dimensional detector array, wherein the variable optical filter is configured to transmit particular wavelengths of light to the detector elements, wherein the particular transmitted wavelengths vary with position along a direction of the one-dimensional detector arrays.

Aspect 12. The method of Aspect 1, wherein each detector element of the selected one-dimensional detector array comprises an anode and a cathode, wherein the anodes of the one-dimensional detector array are electrically isolated from one another, and the cathodes of the one-dimensional detector array are electrically isolated from one another.

Aspect 13. The method of Aspect 1, wherein: the selected one-dimensional detector array is a first selected one-dimensional detector array; and the method further comprises selecting a second one-dimensional detector array and configuring the two-dimensional detector array to operate as a detector array comprising the first and second selected one-dimensional detector arrays.

Aspect 14. The method of Aspect 13, wherein the second one-dimensional detector array is adjacent to the first selected one-dimensional detector array.

Aspect 15. The method of Aspect 13, wherein the second one-dimensional detector array is selected based on having a next lowest number of non-functioning detector elements compared to the first selected one-dimensional detector array.

Aspect 16. A lidar system comprising: a light source configured to emit pulses of light; a scanner configured to scan the emitted pulses of light across a field of regard of the lidar system, the scanner comprising: a beam deflector configured to direct each emitted pulse of light along a first scan axis; and a scan mirror configured to scan the emitted pulses of light along a second scan axis different from the first scan axis; a receiver comprising a one-dimensional detector array comprising N detector elements arranged along a direction corresponding to the first scan axis, wherein N is an integer greater than or equal to 4, and wherein the receiver is configured to: detect a received pulse of light, the received pulse of light comprising a portion of one of the emitted pulses of light scattered by a target located a distance from the lidar system; and determine a time of arrival of the received pulse of light, wherein the one-dimensional detector array is manufactured by: fabricating a M×N two-dimensional detector array comprising M one-dimensional detector arrays, each one-dimensional detector array comprising N detector elements, wherein M is an integer greater than or equal to 2; testing the two-dimensional detector array to determine a number of non-functioning detector elements in each of the M one-dimensional detector arrays; selecting one of the M one-dimensional detector arrays, the selected one-dimensional detector array having a lowest number of non-functioning detector elements; and configuring the two-dimensional detector array to operate as the one-dimensional detector array, the one-dimensional detector array comprising the selected one-dimensional detector array; and a processor configured to determine the distance from the lidar system to the target based on the time of arrival of the received pulse of light.

Aspect 17. A lidar system comprising: a wavelength-tunable light source configured to emit pulses of light, each emitted pulse of light having a particular wavelength of a plurality of different wavelengths; a scanner configured to scan the emitted pulses of light across a field of regard of the lidar system, the scanner comprising: a beam deflector configured to angularly deflect each emitted pulse of light along a first scan axis according to the particular wavelength of the emitted pulse of light; and a scan mirror configured to scan the emitted pulses of light along a second scan axis different from the first scan axis; a receiver comprising a one-dimensional detector array comprising N detector elements arranged along a direction corresponding to the first scan axis, wherein N is an integer greater than or equal to 4, and wherein the receiver is configured to: detect a received pulse of light, the received pulse of light comprising a portion of one of the emitted pulses of light scattered by a target located a distance from the lidar system; and determine a time of arrival of the received pulse of light, wherein the one-dimensional detector array is manufactured by: fabricating a M×N two-dimensional detector array comprising M one-dimensional detector arrays, each one-dimensional detector array comprising N detector elements, wherein M is an integer greater than or equal to 2; testing the two-dimensional detector array to determine a number of non-functioning detector elements in each of the M one-dimensional detector arrays; selecting one of the M one-dimensional detector arrays, the selected one-dimensional detector array having a lowest number of non-functioning detector elements; and configuring the two-dimensional detector array to operate as the one-dimensional detector array, the one-dimensional detector array comprising the selected one-dimensional detector array; and a processor configured to determine the distance from the lidar system to the target based on the time of arrival of the received pulse of light.

Various example aspects described below are directed to a lidar system 100 with adjustable focus.

Aspect 1. A lidar system comprising: a light source configured to emit pulses of light; a scanner configured the emitted pulses of light across a field of regard of the lidar system, the scanner comprising: a beam deflector configured to direct each emitted pulse of light along a first scan axis; and a scan mirror configured to scan the emitted pulses of light along a second scan axis different from the first scan axis; a receiver configured to: detect a received pulse of light, the received pulse of light comprising a portion of one of the emitted pulses of light scattered by a target located a distance from the lidar system; and determine a time of arrival of the received pulse of light; and a processor configured to determine the distance from the lidar system to the target based on the time of arrival of the received pulse of light.

Aspect 2. The lidar system of Aspect 1, wherein the beam deflector is configured to direct each emitted pulse of light in a particular direction along the first scan axis.

Aspect 3. The lidar system of Aspect 1, wherein: for an initial scan across the field of regard, the beam deflector is configured to direct the emitted pulses of light along the first scan axis over a total angular range of Θ_{T} from a minimum angle Θ_{MIN} to a maximum angle Θ_{MAX}, wherein Θ_{T}=Θ_{MAX}−Θ_{MIN}; and for a subsequent scan across at least a portion of the field of regard, the beam deflector is configured to direct subsequently emitted pulses of light along the first scan axis over a reduced angular range of less than Θ_{T}.

Aspect 4. The lidar system of Aspect 1, wherein the lidar system is part of a vehicle, and the processor is further configured to: determine a region of interest within the field of regard of the lidar system; and configure the scanner to scan the region of interest, wherein the beam deflector directs the emitted pulses of light along the first scan axis over a reduced angular range, wherein the reduced angular range encompasses the region of interest.

Aspect 5. The lidar system of Aspect 4, wherein the region of interest comprises a horizon located ahead of the vehicle.

Aspect 6. The lidar system of Aspect 4, wherein the region of interest comprises another vehicle located ahead of the vehicle.

Aspect 7. The lidar system of Aspect 4, wherein the region of interest comprises an area into which the vehicle is preparing to move.

Aspect 8. The lidar system of Aspect 1, wherein the receiver comprises a one-dimensional detector array comprising a plurality of detector elements arranged along a direction corresponding to the first scan axis.

Aspect 9. The lidar system of Aspect 1, wherein: the light source is a wavelength-tunable light source, wherein each emitted pulse of light has a particular wavelength of a plurality of different wavelengths; and the beam deflector is configured to direct each emitted pulse of light along the first scan axis by angularly deflecting each emitted pulse of light along the first scan axis according to the particular wavelength of the emitted pulse of light.

Aspect 10. The lidar system of Aspect 9, wherein the plurality of different wavelengths comprises a maximum wavelength and a minimum wavelength, wherein when the light source emits pulses of light over a range of wavelengths that includes the maximum and minimum wavelengths, the beam deflector deflects the emitted pulses of light over a maximum angular extent along the first scan axis.

Aspect 11. The lidar system of Aspect 10, wherein: for an initial scan across the field of regard, the light source is configured to emit pulses of light over the range of wavelengths that includes the maximum and minimum wavelengths; and for a subsequent scan across at least a portion of the field of regard, the light source is configured to emit pulses of light over one or more wavelengths between the maximum and minimum wavelengths.

Various example aspects described below are directed to a lidar system 100 with a two-dimensional detector array 342.

Aspect 1. A lidar system comprising: a light source configured to emit pulses of light; a scanner configured to scan the emitted pulses of light across a field of regard of the lidar system, the scanner comprising: a beam deflector configured to direct each emitted pulse of light along a first scan axis; and a scan mirror configured to scan the emitted pulses of light along a second scan axis different from the first scan axis; a receiver configured to detect a received pulse of light comprising a portion of one of the emitted pulses of light scattered by a target located a distance from the lidar system, wherein: the received pulse of light is part of an input beam of light that bypasses the scanner, wherein the input beam of light is directed to the receiver without passing through the scanner; the receiver comprises a two-dimensional detector array comprising a plurality of detector elements arranged in a two-dimensional configuration; each detector element is configured to detect received pulses of light originating from a particular portion of the field of regard of the lidar system; the received pulse of light is incident on one or more detector elements of the detector array; each of the one or more detector elements is configured to produce a photocurrent signal corresponding to the received pulse of light; and the receiver is configured to determine a time of arrival of the received pulse of light based on the one or more photocurrent signals produced by the one or more respective detector elements; and a processor configured to determine the distance from the lidar system to the target based on the time of arrival of the received pulse of light.

Aspect 2. The lidar system of Aspect 1, wherein the detector elements are arranged in rows along a first direction corresponding to the first scan axis and in columns along a second direction corresponding to the second scan axis.

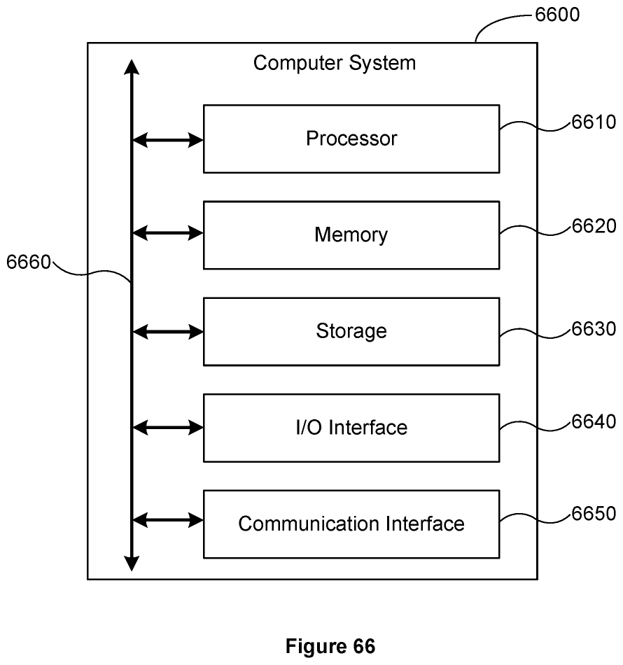

FIG. 66 illustrates an example computer system 6600. One or more computer systems 6600 may perform one or more steps of one or more methods described or illustrated herein. One or more computer systems 6600 may provide functionality described or illustrated herein. Software running on one or more computer systems 6600 may perform one or more steps of one or more methods described or illustrated herein or may provide functionality described or illustrated herein. A computer system may be referred to as a processor, a controller, a computing device, a computing system, a computer, a general-purpose computer, or a data-processing apparatus. For example, controller 150 in FIG. 1 may be referred to or may include a computer system. Herein, reference to a computer system may encompass one or more computer systems, where appropriate.

Computer system 6600 may take any suitable physical form. As an example, computer system 6600 may be an embedded computer system, a system-on-chip (SOC), an application-specific integrated circuit (ASIC), a field-programmable gate array (FPGA), a single-board computer system (SBC), a desktop computer system, a laptop or notebook computer system, a mainframe, a mesh of computer systems, a server, a tablet computer system, or any suitable combination of two or more of these. As another example, all or part of computer system 6600 may be combined with, coupled to, or integrated into a variety of devices, including, but not limited to, a camera, camcorder, personal digital assistant (PDA), mobile telephone, smartphone, electronic reading device (e.g., an e-reader), game console, smart watch, clock, calculator, television monitor, flat-panel display, computer monitor, vehicle display (e.g., odometer display or dashboard display), vehicle navigation system, lidar system, ADAS, autonomous vehicle, autonomous-vehicle driving system, cockpit control, camera view display (e.g., display of a rear-view camera in a vehicle), eyewear, or head-mounted display. Where appropriate, computer system 6600 may include one or more computer systems 6600; be unitary or distributed; span multiple locations; span multiple machines; span multiple data centers; or reside in a cloud, which may include one or more cloud components in one or more networks. Where appropriate, one or more computer systems 6600 may perform without substantial spatial or temporal limitation one or more steps of one or more methods described or illustrated herein. As an example, one or more computer systems 6600 may perform in real time or in batch mode one or more steps of one or more methods described or illustrated herein. One or more computer systems 6600 may perform at different times or at different locations one or more steps of one or more methods described or illustrated herein, where appropriate.

As illustrated in the example of FIG. 66, computer system 6600 may include a processor 6610, memory 6620, storage 6630, an input/output (I/O) interface 6640, a communication interface 6650, or a bus 6660. Computer system 6600 may include any suitable number of any suitable components in any suitable arrangement.

Processor 6610 may include hardware for executing instructions, such as those making up a computer program. As an example, to execute instructions, processor 6610 may retrieve (or fetch) the instructions from an internal register, an internal cache, memory 6620, or storage 6630; decode and execute them; and then write one or more results to an internal register, an internal cache, memory 6620, or storage 6630. A processor 6610 may include one or more internal caches for data, instructions, or addresses. Processor 6610 may include any suitable number of any suitable internal caches, where appropriate. As an example, processor 6610 may include one or more instruction caches, one or more data caches, or one or more translation lookaside buffers (TLBs). Instructions in the instruction caches may be copies of instructions in memory 6620 or storage 6630, and the instruction caches may speed up retrieval of those instructions by processor 6610. Data in the data caches may be copies of data in memory 6620 or storage 6630 for instructions executing at processor 6610 to operate on; the results of previous instructions executed at processor 6610 for access by subsequent instructions executing at processor 6610 or for writing to memory 6620 or storage 6630; or other suitable data. The data caches may speed up read or write operations by processor 6610. The TLBs may speed up virtual-address translation for processor 6610. Processor 6610 may include one or more internal registers for data, instructions, or addresses. Processor 6610 may include any suitable number of any suitable internal registers, where appropriate. Where appropriate, processor 6610 may include one or more arithmetic logic units (ALUs); may be a multi-core processor; or may include one or more processors 6610.

Memory 6620 may include main memory for storing instructions for processor 6610 to execute or data for processor 6610 to operate on. As an example, computer system 6600 may load instructions from storage 6630 or another source (such as, for example, another computer system 6600) to memory 6620. Processor 6610 may then load the instructions from memory 6620 to an internal register or internal cache. To execute the instructions, processor 6610 may retrieve the instructions from the internal register or internal cache and decode them. During or after execution of the instructions, processor 6610 may write one or more results (which may be intermediate or final results) to the internal register or internal cache. Processor 6610 may then write one or more of those results to memory 6620. One or more memory buses (which may each include an address bus and a data bus) may couple processor 6610 to memory 6620. Bus 6660 may include one or more memory buses. One or more memory management units (MMUs) may reside between processor 6610 and memory 6620 and facilitate accesses to memory 6620 requested by processor 6610. Memory 6620 may include random access memory (RAM). This RAM may be volatile memory, where appropriate. Where appropriate, this RAM may be dynamic RAM (DRAM) or static RAM (SRAM). Memory 6620 may include one or more memories 6620, where appropriate.

Storage 6630 may include mass storage for data or instructions. As an example, storage 6630 may include a hard disk drive (HDD), a floppy disk drive, flash memory, an optical disc, a magneto-optical disc, magnetic tape, or a Universal Serial Bus (USB) drive or a combination of two or more of these. Storage 6630 may include removable or non-removable (or fixed) media, where appropriate. Storage 6630 may be internal or external to computer system 6600, where appropriate. Storage 6630 may be non-volatile, solid-state memory. Storage 6630 may include read-only memory (ROM). Where appropriate, this ROM may be mask ROM (MROM), programmable ROM (PROM), erasable PROM (EPROM), electrically erasable PROM (EEPROM), flash memory, or a combination of two or more of these. Storage 6630 may include one or more storage control units facilitating communication between processor 6610 and storage 6630, where appropriate. Where appropriate, storage 6630 may include one or more storages 6630.

I/O interface 6640 may include hardware, software, or both, providing one or more interfaces for communication between computer system 6600 and one or more I/O devices. Computer system 6600 may include one or more of these I/O devices, where appropriate. One or more of these I/O devices may enable communication between a person and computer system 6600. As an example, an I/O device may include a keyboard, keypad, microphone, monitor, mouse, printer, scanner, speaker, camera, stylus, tablet, touch screen, trackball, another suitable I/O device, or any suitable combination of two or more of these. An I/O device may include one or more sensors. Where appropriate, I/O interface 6640 may include one or more device or software drivers enabling processor 6610 to drive one or more of these I/O devices. I/O interface 6640 may include one or more I/O interfaces 6640, where appropriate.

Communication interface 6650 may include hardware, software, or both providing one or more interfaces for communication (such as, for example, packet-based communication) between computer system 6600 and one or more other computer systems 6600 or one or more networks. As an example, communication interface 6650 may include a network interface controller (NIC) or network adapter for communicating with an Ethernet or other wire-based network or a wireless NIC (WNIC); a wireless adapter for communicating with a wireless network, such as a WI-FI network; or an optical transmitter (e.g., a laser or a light-emitting diode) or an optical receiver (e.g., a photodetector) for communicating using fiber-optic communication or free-space optical communication. Computer system 6600 may communicate with an ad hoc network, a personal area network (PAN), an in-vehicle network (IVN), a local area network (LAN), a wide area network (WAN), a metropolitan area network (MAN), or one or more portions of the Internet or a combination of two or more of these. One or more portions of one or more of these networks may be wired or wireless. As an example, computer system 6600 may communicate with a wireless PAN (WPAN) (such as, for example, a BLUETOOTH WPAN), a WI-FI network, a Worldwide Interoperability for Microwave Access (WiMAX) network, a cellular telephone network (such as, for example, a Global System for Mobile Communications (GSM) network), or other suitable wireless network or a combination of two or more of these. As another example, computer system 6600 may communicate using fiber-optic communication based on 100 Gigabit Ethernet (100 GbE), 10 Gigabit Ethernet (10 GbE), or Synchronous Optical Networking (SONET). Computer system 6600 may include any suitable communication interface 6650 for any of these networks, where appropriate. Communication interface 6650 may include one or more communication interfaces 6650, where appropriate.

Bus 6660 may include hardware, software, or both coupling components of computer system 6600 to each other. As an example, bus 6660 may include an Accelerated Graphics Port (AGP) or other graphics bus, a controller area network (CAN) bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local bus (VLB), or another suitable bus or a combination of two or more of these. Bus 6660 may include one or more buses 6660, where appropriate.

Various modules, circuits, systems, methods, or algorithm steps described in connection with the implementations disclosed herein may be implemented as electronic hardware, computer software, or any suitable combination of hardware and software. Computer software (which may be referred to as software, computer-executable code, computer code, a computer program, computer instructions, or instructions) may be used to perform various functions described or illustrated herein, and computer software may be configured to be executed by or to control the operation of computer system 6600. As an example, computer software may include instructions configured to be executed by processor 6610. Owing to the interchangeability of hardware and software, the various illustrative logical blocks, modules, circuits, or algorithm steps have been described generally in terms of functionality. Whether such functionality is implemented in hardware, software, or a combination of hardware and software may depend upon the particular application or design constraints imposed on the overall system.

A computing device may be used to implement various modules, circuits, systems, methods, or algorithm steps disclosed herein. As an example, all or part of a module, circuit, system, method, or algorithm disclosed herein may be implemented or performed by a general-purpose single- or multi-chip processor, a digital signal processor (DSP), an ASIC, a FPGA, any other suitable programmable-logic device, discrete gate or transistor logic, discrete hardware components, or any suitable combination thereof. A general-purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

One or more implementations of the subject matter described herein may be implemented as one or more computer programs (e.g., one or more modules of computer-program instructions encoded or stored on a computer-readable non-transitory storage medium). As an example, the steps of a method or algorithm disclosed herein may be implemented in a processor-executable software module which may reside on a computer-readable non-transitory storage medium. A computer-readable non-transitory storage medium may include any suitable storage medium that may be used to store or transfer computer software and that may be accessed by a computer system. Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs (e.g., compact discs (CDs), CD-ROM, digital versatile discs (DVDs), Blu-ray discs, or laser discs), optical disc drives (ODDs), magneto-optical discs, magneto-optical drives, floppy diskettes, floppy disk drives (FDDs), magnetic tapes, flash memories, solid-state drives (SSDs), RAM, RAM-drives, ROM, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Certain features described herein in the context of separate implementations may also be combined and implemented in a single implementation. Conversely, various features that are described in the context of a single implementation may also be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

While operations may be depicted in the drawings as occurring in a particular order, this should not be understood as requiring that such operations be performed in the particular order shown or in sequential order, or that all operations be performed. Further, the drawings may schematically depict one more example processes or methods in the form of a flow diagram or a sequence diagram. However, other operations that are not depicted may be incorporated in the example processes or methods that are schematically illustrated. For example, one or more additional operations may be performed before, after, simultaneously with, or between any of the illustrated operations. Moreover, one or more operations depicted in a diagram may be repeated, where appropriate. Additionally, operations depicted in a diagram may be performed in any suitable order. Furthermore, although particular components, devices, or systems are described herein as carrying out particular operations, any suitable combination of any suitable components, devices, or systems may be used to carry out any suitable operation or combination of operations. In certain circumstances, multitasking or parallel processing operations may be performed. Moreover, the separation of various system components in the implementations described herein should not be understood as requiring such separation in all implementations, and it should be understood that the described program components and systems may be integrated together in a single software product or packaged into multiple software products.

Various embodiments have been described in connection with the accompanying drawings. However, it should be understood that the figures may not necessarily be drawn to scale. As an example, distances or angles depicted in the figures are illustrative and may not necessarily bear an exact relationship to actual dimensions or layout of the devices illustrated.

One or more of the figures described herein may include example data that is prophetic. For example, one or more of the example graphs illustrated in the figures may include or may be referred to as prophetic examples.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes or illustrates respective embodiments herein as including particular components, elements, functions, operations, or steps, any of these embodiments may include any combination or permutation of any of the components, elements, functions, operations, or steps described or illustrated anywhere herein that a person having ordinary skill in the art would comprehend.

The term “or” as used herein is to be interpreted as an inclusive or meaning any one or any combination, unless expressly indicated otherwise or indicated otherwise by context. Therefore, herein, the expression “A or B” means “A, B, or both A and B.” As another example, herein, “A, B or C” means at least one of the following: A; B; C; A and B; A and C; B and C; A, B and C. An exception to this definition will occur if a combination of elements, devices, steps, or operations is in some way inherently mutually exclusive.

As used herein, words of approximation such as, without limitation, “approximately, “substantially,” or “about” refer to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as having the required characteristics or capabilities of the unmodified feature. In general, but subject to the preceding discussion, a numerical value herein that is modified by a word of approximation such as “approximately” may vary from the stated value by ±0.5%, ±1%, ±2%, ±3%, ±4%, ±5%, ±10%, ±12%, or ±15%. The term “substantially constant” refers to a value that varies by less than a particular amount over any suitable time interval. For example, a value that is substantially constant may vary by less than or equal to 20%, 10%, 1%, 0.5%, or 0.1% over a time interval of approximately 10⁴ s, 10³ s, 10² s, 10 s, 1 s, 100 ms, 10 ms, 1 ms, 100 μs, 10 μs, or 1 μs. The term “substantially constant” may be applied to any suitable value, such as for example, an optical power, a pulse repetition frequency, an electrical current, a wavelength, an optical or electrical frequency, or an optical or electrical phase.

As used herein, the terms “first,” “second,” “third,” etc. may be used as labels for nouns that they precede, and these terms may not necessarily imply a particular ordering (e.g., a particular spatial, temporal, or logical ordering). As an example, a system may be described as determining a “first result” and a “second result,” and the terms “first” and “second” may not necessarily imply that the first result is determined before the second result.

As used herein, the terms “based on” and “based at least in part on” may be used to describe or present one or more factors that affect a determination, and these terms may not exclude additional factors that may affect a determination. A determination may be based solely on those factors which are presented or may be based at least in part on those factors. The phrase “determine A based on B” indicates that B is a factor that affects the determination of A. In some instances, other factors may also contribute to the determination of A. In other instances, A may be determined based solely on B.

What is claimed is:

1. A lidar system comprising:
a light source configured to emit pulses of light;
a scanner configured to scan the emitted pulses of light across a field of regard of the lidar system, the scanner comprising:
a beam deflector configured to direct each emitted pulse of light along a first scan axis; and
a scan mirror configured to scan the emitted pulses of light along a second scan axis different from the first scan axis;
a receiver comprising a one-dimensional detector array comprising a plurality of detector elements arranged along a direction corresponding to the first scan axis, wherein the receiver is configured to:
detect a received pulse of light, the received pulse of light comprising a portion of one of the emitted pulses of light scattered by a target located a distance from the lidar system; and
determine a time of arrival of the received pulse of light; and
a processor configured to determine the distance from the lidar system to the target based on the time of arrival of the received pulse of light.

2. The lidar system of claim 1, wherein the received pulse of light is part of an input beam of light, the input beam comprising a plurality of received pulses of light, wherein the input beam, prior to being detected by the receiver, is reflected by the scan mirror and bypasses the beam deflector.

3. The lidar system of claim 2, wherein the received pulse of light is directed to a portion of the detector array corresponding to a direction along the first scan axis at which the emitted pulse of light was directed by the beam deflector.

4. The lidar system of claim 2, wherein:
the emitted pulses of light are part of an output beam of light, the output beam of light having a beam diameter of d₁;
the input beam of light has a beam diameter of d₂, wherein d₂ is greater than d₁;
an aperture of the beam deflector has a length or diameter of s₁; and
an aperture of the scan mirror has a length or diameter of s₂, wherein:
s₂ is greater than s₁,
s₂ is greater than or equal to d₂,
s₁ is greater than or equal to d₁, and
s₁ is less than d₂.

5. The lidar system of claim 1, wherein a scanning speed of the beam deflector is greater than or equal to four times a scanning speed of the scan mirror.

6. The lidar system of claim 1, wherein the scan mirror comprises a polygon mirror configured to rotate to scan the emitted pulses of light along the second scan axis, wherein the polygon mirror comprises a plurality of reflective surfaces angularly offset from one another along a periphery of the polygon mirror, each reflective surface configured to reflect, in sequence as the polygon mirror rotates, a portion of the emitted pulses of light.

7. The lidar system of claim 6, wherein:
the polygon mirror comprises S reflective surfaces, wherein S is an integer greater than or equal to 2;
the polygon mirror is configured to rotate at a rotation speed of R revolutions per second;
the portion of the emitted pulses of light reflected from each of the reflective surfaces of the polygon mirror are associated with a single scan across at least a portion of the field of regard of the lidar system; and
the lidar system is configured to produce point clouds at a frame rate of F frames per second according to an expression F=S×R.

8. The lidar system of claim 6, wherein:
the polygon mirror is configured to rotate about a rotation axis; and
one or more of the reflective surfaces of the polygon mirror have non-zero angles with respect to the rotation axis of the polygon mirror.

9. The lidar system of claim 8, wherein:
each of the reflective surfaces has one of r different angles with respect to the rotation axis, wherein r is an integer greater than or equal to 2 and less than or equal to a number of reflective surfaces of the polygon mirror;
the field of regard of the lidar system is subdivided into r regions; and
each reflective surface of the polygon mirror is configured to scan one of the portions of the emitted pulses of light along the second scan axis within one of the r regions of the field of regard.

10. The lidar system of claim 9, wherein:
the beam deflector is configured to direct the emitted pulses of light over an angular range of α along the first scan axis; and
the field of regard has an angular extent along the first scan axis of greater than or equal to 80% of r×α and less than or equal to r×α.

11. The lidar system of claim 9, wherein two or more of the reflective surfaces have equal angles with respect to the rotation axis of the polygon mirror, wherein the two or more reflective surfaces are each configured to scan one of the portions of the emitted pulses of light along the second scan axis within a same one of the r regions of the field of regard.

12. The lidar system of claim 9, wherein:
the polygon mirror comprises S reflective surfaces, wherein S is greater than or equal to r;
the polygon mirror is configured to rotate at a rotation speed of R revolutions per second; and
the lidar system is configured to produce point clouds at a frame rate of R frames per second, wherein each point cloud comprises pixels corresponding to pulses of light reflected from each of the S reflective surfaces.

13. The lidar system of claim 1, wherein the scan mirror comprises a galvanometer scanner.

14. The lidar system of claim 1, wherein the beam deflector comprises a microelectromechanical systems (MEMS) device comprising a reflective surface configured to pivot to direct the emitted pulses of light along the first scan axis.

15. The lidar system of claim 1, wherein the beam deflector comprises a polygon mirror configured to rotate to direct the emitted pulses of light along the first scan axis, wherein the polygon mirror comprises a plurality of reflective surfaces angularly offset from one another along a periphery of the polygon mirror, each reflective surface configured to reflect, in sequence as the polygon mirror rotates, a portion of the emitted pulses of light.

16. The lidar system of claim 1, wherein the beam deflector comprises an electro-optic device, an acousto-optic device, a liquid-crystal device, a vibrating optical fiber, a resonant-mirror scanner, or an optical phased array.

17. The lidar system of claim 1, wherein:
the received pulse of light is part of an input beam of light comprising a plurality of received pulses of light; and
the receiver further comprises a lens configured to focus the input beam of light onto the detector array, wherein each received pulse of light is directed to a portion of the detector array corresponding to a direction along the first scan axis at which a corresponding emitted pulse of light was directed by the beam deflector.

18. The lidar system of claim 1, wherein the second scan axis is substantially orthogonal to the first scan axis.

19. The lidar system of claim 1, wherein each detector element is configured to detect received pulses of light originating from a particular direction with respect to the first scan axis.

20. The lidar system of claim 1, wherein the detector array comprises silicon (Si) detector elements, silicon-germanium (SiGe) detector elements, silicon-germanium-tin (SiGeSn) detector elements, or indium-gallium-arsenide (InGaAs) detector elements.

21. The lidar system of claim 1, wherein each detector element is an avalanche photodiode (APD), a PN photodiode, a PIN photodiode, or a quantum dot photodetector.

22. The lidar system of claim 1, wherein the detector array further comprises an optical filter configured to transmit particular wavelengths of light to the detector elements.

23. The method of claim 1, wherein each detector element of the one-dimensional detector array comprises an anode and a cathode wherein the anodes of the one-dimensional detector array are electrically isolated from one another, and the cathodes of the one-dimensional detector array are electrically isolated from one another.

24. The lidar system of claim 1, wherein:
the received pulse of light is incident on one or more detector elements of the detector array;
the one or more detector elements are configured to produce one or more respective photocurrent signals corresponding to the received pulse of light; and
the receiver further comprises an electronic amplifier configured to amplify the one or more photocurrent signals to produce one or more voltage signals, each voltage signal corresponding to one of the photocurrent signals.

25. The lidar system of claim 24, wherein the receiver further comprises a pulse-detection circuit comprising a plurality of comparators coupled to a respective plurality of time-to-digital converters (TDCs), wherein:
each comparator is configured to receive one of the voltage signals and provide an electrical-edge signal to a corresponding TDC when the received voltage signal rises above or falls below a particular threshold voltage; and
the corresponding TDC is configured to produce a time value corresponding to a time when the electrical-edge signal was received, wherein the time of arrival of the received pulse of light is determined based on one or more time values produced by one or more of the TDCs.

26. The lidar system of claim 24, wherein the receiver further comprises a N×n electronic multiplexer disposed between the detector array and the electronic amplifier, wherein:
N is a number of inputs of the multiplexer, and n is a number of outputs of the multiplexer;
the one-dimensional detector array comprises N detector elements, and each input of the multiplexer is coupled to one of the detector elements;
the electronic amplifier comprises n inputs, and each output of the multiplexer is coupled to one of the inputs of the electronic amplifier, wherein n is an integer greater than or equal to 1; and
the multiplexer is configured to couple the one or more photocurrent signals from the one or more detector elements to one or more respective inputs of the electronic amplifier.

27. The lidar system of claim 1, wherein the light source comprises:
a seed laser diode configured to produce seed light; and
an optical amplifier configured to amplify the seed light to produce the emitted pulses of light, wherein the optical amplifier comprises a semiconductor optical amplifier (SOA), a fiber-optic amplifier, or a SOA followed by a fiber-optic amplifier.

28. The lidar system of claim 27, wherein the seed laser diode is a sampled-grating distributed Bragg reflector (SG-DBR) laser configured to produce the seed light at a plurality of different wavelengths, wherein each of the emitted pulses of light has a particular wavelength of the plurality of different wavelengths.

29. The lidar system of claim 28, wherein the beam deflector is configured to direct each emitted pulse of light along the first scan axis by angularly deflecting each emitted pulse of light along the first scan axis according to the particular wavelength of the emitted pulse of light.

30. The lidar system of claim 1, wherein:
the time of arrival of the received pulse of light corresponds to a round-trip time (T) for the portion of the one of the emitted pulses of light to travel to the target and back to the lidar system; and
the distance (D) to the target is determined from an expression D=c·T/2, wherein c is a speed of light.

31. The lidar system of claim 1, wherein the emitted pulses of light have optical characteristics comprising:
one or more wavelengths between 1400 nanometers (nm) and 1600 nm;
a pulse energy between 0.01 μJ and 100 μJ;
a pulse repetition frequency between 80 kHz and 10 MHz; and
a pulse duration between 1 ns and 100 ns.
